(19) United States
(12) Patent Application Publication
(10) Pub. No.: US 2022/0220142 A1
(43) Pub. Date: Jul. 14, 2022

(54) ORGANOMETALLIC COMPOUND, ORGANIC LIGHT-EMITTING DEVICE INCLUDING THE SAME, AND ELECTRONIC APPARATUS INCLUDING THE ORGANIC LIGHT-EMITTING DEVICE

(71) Applicant: Samsung Electronics Co., Ltd., Suwon-si (KR)

(72) Inventors: Jeoungin Yi, Seoul (KR); Byungjoon Kang, Seoul (KR); Seungyeon Kwak, Suwon-si (KR); Sangho Park, Anyang-si (KR); Myungsun Sim, Suwon-si (KR); Kum Hee Lee, Suwon-si (KR); Byoungki Choi, Hwaseong-si (KR)

(21) Appl. No.: 17/573,006

(22) Filed: Jan. 11, 2022

(30) Foreign Application Priority Data
Jan. 11, 2021 (KR) 10-2021-0003568

(51) Int. Cl. C07F 15/00; H01L 51/00

(52) U.S. Cl. CPC C07F 15/0086; H01L 51/5016; H01L 51/0087

(57) ABSTRACT

An organometallic compound represented by Formula 1:

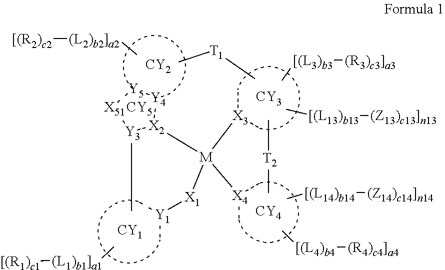

wherein M is beryllium (Be), magnesium (Mg), aluminum (Al), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au); and wherein ring CY₁ to ring CY₅, X₁ to X₄, X₅₁, Y₁ to Y₅, R₁ to R₄, L₁ to L₄, L₇, L₁₃, L₁₄, T₁, T₂, Z₁₃, Z₁₄, b1 to b4, b7, b13, b14, c1 to c4, c7, c13, c14, n13, and n14 are as defined herein.

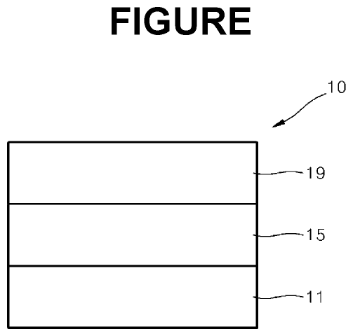

### CROSS-REFERENCE TO RELATED APPLICATION

This application claims priority to and the benefit of Korean Patent Application No. 10-2021-0003568, filed on Jan. 11, 2021, in the Korean Intellectual Property Office, and all the benefits accruing therefrom under 35 U.S.C. § 119, the content of which is incorporated by reference herein in its entirety.

### BACKGROUND

### 1. Field

One or more embodiments described herein relate to an organometallic compound, an organic light-emitting device including the same, and an electronic apparatus including the organic light-emitting device.

### 2. Description of the Related Art

Organic light-emitting devices (OLEDs) are self-emissive devices, which have improved characteristics in terms of viewing angles, response time, brightness, driving voltage, and response speed. In addition, OLEDs can produce full-color images.

In an example, an organic light-emitting device includes an anode, a cathode, and an organic layer located between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons may then recombine in the emission layer to produce excitons. These excitons transition from an excited state to a ground state to thereby generate light, for example visible light.

### SUMMARY

One or more embodiments described herein relate to an organometallic compound, an organic light-emitting device including the same, and an electronic apparatus including the organic light-emitting device.

Additional aspects will be set forth in part in the description, which follows and, in part, will be apparent from the description, or may be learned by practice of the presented embodiments of the disclosure.

According to one or more embodiments, provided is an organometallic compound represented by Formula 1.

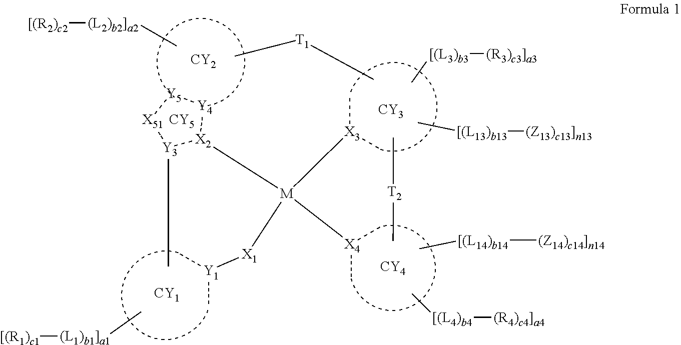

In Formula 1,

M is beryllium (Be), magnesium (Mg), aluminum (AI), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au),

X₁ is a single bond, O, S, N(R′), P(R′), B(R′), C(R′)(R″), or Si(R′)(R″), and when X₁ is a single bond, Y₁ is directly bonded to M,

X₂ to X₄ are each independently C or N,

a bond between X₁ or Y₁ and M is a covalent bond,

one of a bond between X₂ and M, a bond between X₃ and M, a bond between X₄ and M is a covalent bond, and the others of a bond between X₂ and M, a bond between X₃ and M, or a bond between X₄ and M are coordinate bonds,

Y₁ and Y₃ to Y₅ are each independently C or N,

X₂ and Y₃, X₂ and Y₄, Y₄ and Y₅, X₅₁ and Y₃, and X₅₁ and Y₅ are each linked through a chemical bond,

ring CY₁ to ring CY₄ are each independently a C₅-C₃₀ carbocyclic group or a C₁-C₃₀ heterocyclic group, provided that ring CY₁, ring CY₃, and ring CY₄ are not a benzimidazole group,

ring CY₅ is a 5-membered ring condensed with ring CY₂,

a cyclometalated ring group formed by ring CY₅, ring CY₂, ring CY₃, and M is a 6-membered ring,

X₅₁ is O, S, N-[(L₇)_{b7}-(R₇)_{c7}], C(R₇)(R₈), Si(R₇)(R₈), Ge(R₇)(R₈), C(═O), N, C(R₇), Si(R₇), or Ge(R₇),

R₇ and R₈ is optionally linked via a single bond, a double bond, or a first linking group to form a C₅-C₃₀ carbocyclic group unsubstituted or substituted with at least one R₁₀ₐ, or a C₁-C₃₀ heterocyclic group unsubstituted or substituted with at least one R₁₀ₐ,

T₁ and T₂ are each independently a single bond, a double bond, *—N(R₉)—*, *—B(R₉)—*′, *—P(R₉)—*, *—C(R₉ₐ)(R_{9b})—*′, *—Si(R₉ₐ)(R_{9b})—*′, *—Ge(R₉ₐ)(R_{9b})—*′, *—S—*′, *—Se—*′,*—O—*′, *—C(═O)—*′, *—S(═O)—*′, *—S(═O)₂—*, *—C(R₉)═*′, *═C(R₉)—*′, *—C(R₉ₐ)═C(R_{9b})—*, *—C(═S)—*′, or *—C≡C—*′, wherein * and *′ each represent a bond to a neighboring atom,

Z₁₃ and Z₁₄ are each independently a group represented by Formula 2,

n13 and n14 may each independently be an integer from 0 to 20, and the sum of n13 and n14 may be 1 or greater,

L₁ to L₄, L₇, L₁₃, and L₁₄ are each independently a single bond, a C₅-C₃₀ carbocyclic group unsubstituted or substituted with at least one R₁₀ₐ, or a C₁-C₃₀ heterocyclic group unsubstituted or substituted with at least one R₁₀ₐ,

b1 to b4, b7, b13, and b14 are each independently an integer from 1 to 5,

R₁ to R₄, R₇ to R₉, R₉ₐ, R_{9b}, R′, and R″ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

c1 to c4, c7, c13, and c14 are each independently an integer from 1 to 5,

a1 to a4 are each independently an integer from 0 to 20,

two or more of a plurality of R₁(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more of a plurality of R₂(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more of a plurality of R₃(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more of a plurality of R₄(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more groups of R₁ to R₄, R₇ to R₉, R₉ₐ, R_{9b}, R′, and R″ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

R₁₀ₐ is as defined in connection with R₁,

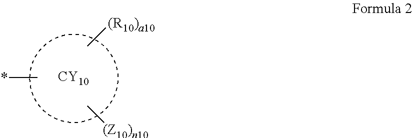

wherein, in Formula 2,

ring CY₁₀ is an unsaturated C₅-C₃₀ carbocyclic group or an unsaturated C₁-C₃₀ heterocyclic group,

R₁₀ is as defined in connection with R₁,

a10 is an integer from 0 to 20,

Z₁₀ is —F or a fluorinated group,

n10 is an integer from 1 to 20,

a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, a monovalent non-aromatic condensed polycyclic group or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof,

wherein Q₁ to Q₉, Q₁₁ to Q₁₉, Q₂₁ to Q₂₉, and Q₃₁ to Q₃₉ may each independently be hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a C₁-C₆₀ heteroaryloxy group; a C₁-C₆₀ heteroarylthio group; a monovalent non-aromatic condensed polycyclic group; or a monovalent non-aromatic condensed heteropolycyclic group.

According to one or more embodiments, provided is an organic light-emitting device including a first electrode, a second electrode, and an organic layer located between the first electrode and the second electrode, wherein the organic layer comprises an emission layer, and wherein the organic layer includes at least one organometallic compound represented by Formula 1.

The organometallic compound may be included in the emission layer of the organic layer, and the organometallic compound included in the emission layer may act as a dopant.

According to one or more embodiments, an electronic apparatus may include the organic light-emitting device.

### BRIEF DESCRIPTION OF THE DRAWING

The above and other aspects, features, and advantages of certain embodiments of the disclosure will be more apparent from the following description taken in conjunction with the accompanying drawing, in which

FIGURE is a schematic cross-sectional view of an organic light-emitting device according to one or more embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

According to an aspect, one or more embodiments describe an organometallic compound represented by Formula 1:

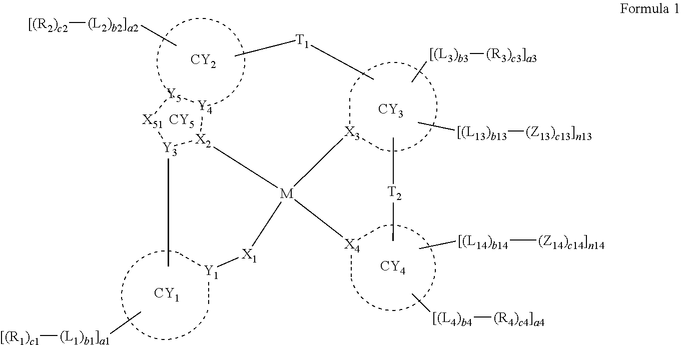

M in Formula 1 is beryllium (Be), magnesium (Mg), aluminum (Al), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au).

For example, M may be Pt, Pd, or Au.

X₁ in Formula 1 is a single bond (for example, a covalent bond), O, S, N(R′), P(R′), B(R′), C(R′)(R″), or Si(R′)(R″). R′ and R″ are each as defined above. When X₁ is a single bond, Y₁ and M are directly linked to each other.

In one or more embodiments, X₁ in Formula 1 may be O or S.

X₂ to X₄ in Formula 1 are each independently C or N.

For example, two of X₂ to X₄ may be N, and one may be C.

In one or more embodiments, in Formula 1, X₂ and X₄ may be N, and X₃ may be C.

A bond between X₁ or Y₁ and M in Formula 1 is a covalent bond. One of a bond between X₂ and M, a bond between X₃ and M, or a bond between X₄ and M is a covalent bond, and others of a bond between X₂ and M, a bond between X₃ and M, and a bond between X₄ and M are coordinate bonds. Thus, the organometallic compound represented by Formula 1 is electrically neutral.

In one or more embodiments, in Formula 1, a bond between X₁ or Y₁ and M and a bond between X₃ and M may each be a covalent bond, and a bond between X₂ and M and a bond between X₄ and M may be a coordinate bond.

In one or more embodiments, in Formula 1,

i) X₂ and X₄ may each be N, X₃ may be C, a bond between X₂ and M and a bond between X₄ and M may each be a coordinate bond, and a bond between X₃ and M may be a covalent bond,

ii) X₂ and X₃ may each be N, X₄ may be C, a bond between X₂ and M and a bond between X₃ and M may each be a coordinate bond, and a bond between X₄ and M may be a covalent bond, or

iii) X₃ and X₄ may be N, X₂ may be C, a bond between X₃ and M and a bond between X₄ and M may be a coordinate bond, and a bond between X₂ and M may be a covalent bond.

In Formula 1, Y₁ and Y₃ to Y₅ are each independently C or N.

For example, in one or more embodiments, in Formula 1, Y₁ and Y₃ to Y₅ may each be C.

In Formula 1, X₂ and Y₃, X₂ and Y₄, Y₄ and Y₅, X₅₁ and Y₃, and X₅₁ and Y₅ are each linked through chemical bonds. Accordingly, ring CY₅ in Formula 1 may be a 5-membered ring condensed with ring CY₂.

In Formula 1, ring CY₁ to ring CY₄ are each independently a C₅-C₃₀ carbocyclic group or a C₁-C₃₀ heterocyclic group, provided that each of ring CY₁, ring CY₃, and ring CY₄ is not a benzimidazole group. In addition, in formula 1, ring CY₂ is not a benzimidazole group. In other words, in Formula 1, each of ring CY₁ to ring CY₄ is not a benzimidazole group.

In one or more embodiments, in Formula 1, ring CY₁ to ring CY₄ may each independently be i) a first ring, ii) a second ring, iii) a condensed ring in which two or more of the first rings are condensed with each other, iv) a condensed ring in which two or more of the second rings are condensed with each other, or v) a condensed ring in which one or more of the first rings and one or more of the second rings are condensed with each other,

wherein the first ring may be a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and

the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In one or more embodiments, in Formula 1, ring CY₁ to ring CY₄ may each independently be a benzene group, a naphthalene group, an anthracene group, a phenanthrene group, a triphenylene group, a pyrene group, a chrysene group, a 1,2,3,4-tetrahydronaphthalene group, a furan group, a thiophene group, a pyrrole group, a cyclopentadiene group, a silole group, a benzofuran group, a benzothiophene group, an indole group, an indene group, a benzosilole group, a dibenzofuran group, a dibenzothiophene group, a carbazole group, a fluorene group, a dibenzosilole group, an azasilole group, an azabenzofuran group, an azabenzothiophene group, an azabenzosilole group, an azadibenzofuran group, an azadibenzothiophene group, an azacarbazole group, an azafluorene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a 5,6,7,8-tetrahydroisoquinoline group, a 5,6,7,8-tetrahydroquinoline group, a benzene group condensed with norbornane, or a pyridine group condensed with norbornane.

A cyclometalated ring formed by ring CY₅, ring CY₂, ring CY₃, and M in Formula 1 is a 6-membered ring.

In Formula 1, X₅₁ is O, S, N-[(L₇)_{b7}-(R₇)_{c7}], C(R₇)(R₈), Si(R₇)(R₈), Ge(R₇)(R₈), C(═O), N, C(R₇), Si(R₇), or Ge(R₇). R₇ and R₈ are optionally linked via a single bond, a double bond, or a first linking group to form a C₅-C₃₀ carbocyclic group unsubstituted or substituted with at least one R₁₀ₐ, or a C₁-C₃₀ heterocyclic group unsubstituted or substituted with at least one R₁₀ₐ. L₇, b7, R₇, R₈, and c7 are as defined herein.

The first linking group may be *—O—*′, *—S—*′, *—C(R₅)(R₆)—*′, *—C(R₅)═*′, *═C(R₆)—*,*—C(R₅)═C(R₆)—*′, *—C(═O)—*′, *—C(═S)—*′, *—C≡C—*′, *—N(R₅)—*′, *—Si(R₅)(R₆)—*′, *—P(R₅)—*′, or a combination thereof, wherein R₅ and R₆ are each as defined in connection with R₁, and each of * and *′ indicates a binding site to a neighboring atom.

For example, in one or more embodiments, X₅₁ in Formula 1 may be O, S, N-[(L₇)_{b7}-(R₇)_{c7}], C(R₇)(R₈), Si(R₇)(R₈), Ge(R₇)(R₈), or C(═O).

In one or more embodiments, X₅₁ in Formula 1 may be N-[(L₇)_{b7}-(R₇)_{c7}].

In one or more embodiments, in Formula 1, X₅₁ may be N-[(L₇)_{b7}-(R₇)_{c7}], L₇ may not be a single bond, c7 may be greater than or equal to 2, one of two or more R₇(s) may be a substituted or unsubstituted C₄-C₂₀ alkyl group (for example, a tert-butyl group, etc.), one of the remaining R₇ may be a substituted or unsubstituted phenyl group (for example, a phenyl group, a deuterated phenyl group, a (C₁-C₂₀ alkyl) phenyl group, etc.) or a substituted or unsubstituted biphenyl group (for example, a biphenyl group, a deuterated biphenyl group, or a (C₁-C₂₀ alkyl) biphenyl group, etc.).

In one or more embodiments, in Formula 1,

i) Y₃ to Y₅ may each be C, a bond between X₅₁ and Y₃ and a bond between X₅₁ and Y₅ may each be a single bond, and X₅₁ may be O, S, N-[(L₇)_{b7}-(R₇)_{c7}], C(R₇)(R₈), Si(R₇)(R₈), Ge(R₇)(R₈), or C(═O),

ii) Y₃ and Y₄ may each be C, Y₅ may be N, a bond between X₅₁ and Y₃ may be a double bond, a bond between X₅₁ and Y₅ may be a single bond, and X₅₁ may be N, C(R₇), Si(R₇), or Ge(R₇),

iii) Y₃ and Y₅ may each be C, Y₄ may be N, a bond between X₅₁ and Y₃ may be a single bond, a bond between X₅₁ and Y₅ may be a double bond, and X₅₁ may be N, C(R₇), Si(R₇), or Ge(R₇),

iv) Y₃ may be N, Y₄ and Y₅ may each be C, a bond between X₅₁ and Y₃ may be a single bond, a bond between X₅₁ and Y₅ may be a double bond, and X₅₁ may be N, C(R₇), Si(R₇), or Ge(R₇), or

v) Y₃ to Y₅ may be C, a bond between X₅₁ and Y₃ may be a double bond, a bond between X₅₁ and Y₅ may be a single bond, and X₅₁ may be N, C(R₇), Si(R₇), or Ge(R₇).

In one or more embodiments, in Formula 1, Y₃ to Y₅ may be C; a bond between X₅₁ and Y₃ and a bond between X₅₁ and Y₅ each may be a single bond; and X₅₁ may be O, S, N-[(L₇)_{b7}-(R₇)_{c7}], C(R₇)(R₈), Si(R₇)(R₈), Ge(R₇)(R₈), or C(═O).

T₁ and T₂ in Formula 1 are each independently a single bond, a double bond, *—N(R₉)—*′, *—B(R₉)—*′, *—P(R₉)—*′, *—C(R₉ₐ)(R_{9b})—*′, *—Si(R₉ₐ)(R_{9b})—*′, *—Ge(R₉ₐ)(R_{9b})—*′, *—S—*, *—Se—*′, *—O—*′, *—C(═O)—*′, *—S(═O)—*′, *—S(═O)₂—*′, *—C(R₉)═*′, *═C(R₉)—*′, *—C(R₉ₐ)═C(R_{9b})—*′, *—C(═S)—*′, or *—C≡C—*′, wherein * and *′ each represent a bond to a neighboring atom. R₉ₐ and R_{9b} are optionally linked via a single bond, a double bond, or a second linking group to form a C₅-C₃₀ carbocyclic group unsubstituted or substituted with at least one R₁₀ₐ or a C₁-C₃₀ heterocyclic group unsubstituted or substituted with at least one R₁₀ₐ. The second linking group is as defined in connection with the first linking group.

In one or more embodiments, T₁ and T₂ in Formula 1 may be a single bond.

In Formula 1, Z₁₃ and Z₁₄ are each independently a group represented by Formula 2:

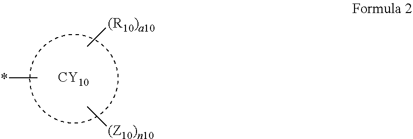

Ring CY₁₀ in Formula 2 is an unsaturated C₅-C₃₀ carbocyclic group or an unsaturated C₁-C₃₀ heterocyclic group.

In one or more embodiments, ring CY₁₀ in Formula 2 may be a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an isoindole group, an indole group, an indazole group, a purine group, a quinoline group, an isoquinoline group, a benzoquinoline group, a quinoxaline group, a quinazoline group, a cinnoline group, a carbazole group, a phenanthroline group, a benzimidazole group, a benzofuran group, a benzothiophene group, a benzisothiazole group, a benzoxazole group, a benzoisoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azacarbazole group, an azadibenzofuran group, or an azadibenzothiophene group.

In one or more embodiments, ring CY₁₀ in Formula 2 may be a benzene group, a naphthalene group, a dibenzofuran group, or a dibenzothiophene group.

R₁₀ in Formula 2 is as defined in connection with R₁.

For example, in Formula 2, R₁₀ may be:

deuterium, —CN, —Si(Q₃)(Q₄)(Q₅), or —Ge(Q₃)(Q₄)(Q₅); or

a C₁-C₂₀ alkyl group or C₃-C₁₀ cycloalkyl group, each unsubstituted or substituted with deuterium, —CN, a C₁-C₂₀ alkyl group, a deuterated C₁-C₂₀ alkyl group, a C₃-C₁₀ cycloalkyl group, a deuterated C₃-C₁₀ cycloalkyl group, a (C₁-C₂₀ alkyl) C₃-C₁₀ cycloalkyl group, or a combination thereof.

In Formula 2, a10 indicates the number of R₁₀(s) and is an integer from 0 to 20. When a10 is 2 or greater, two or more of R₁₀(s) are identical to or different from each other. For example, a10 may be an integer from 0 to 5.

Z₁₀ in Formula 2 is a fluoro group (—F) or a fluorinated group. As used herein, the “fluorinated group” refers to a group that is substituted with at least one fluoro group (—F).

For example, in Formula 2, Z₁₀ may be

—F; or

a fluorinated C₁-C₂₀ alkyl group, a fluorinated phenyl group, or a fluorinated biphenyl group, each unsubstituted or substituted with deuterium, a C₁-C₂₀ alkyl group, a deuterated C₁-C₂₀ alkyl group, a phenyl group, a deuterated phenyl group, a (C₁-C₂₀ alkyl) phenyl group, a biphenyl group, a deuterated biphenyl group, a (C₁-C₂₀ alkyl) biphenyl group, or a combination thereof.

In Formula 2, n10 indicates the number of Z₁₀(s) and is an integer from 1 to 20. Thus, a group represented by Formula 2 may include at least one Z₁₀ as defined herein. When n10 is 2 or greater, two or more of Z₁₀(s) are identical to or different from each other. For example, n10 may be an integer from 1 to 5.

In one or more embodiments, a group represented by Formula 2 may be a group represented by one of Formulae 2-1 to 2-42:

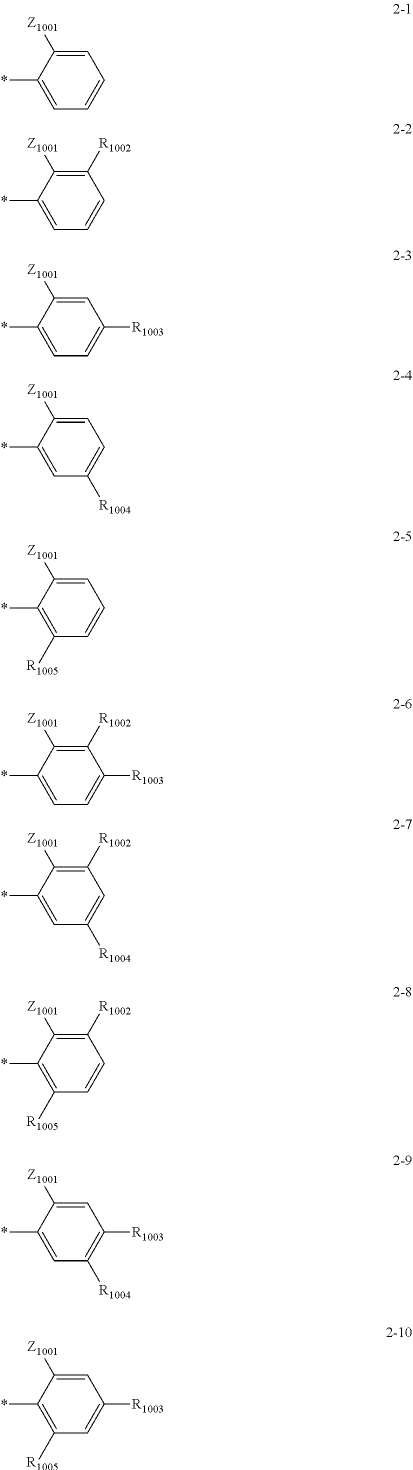

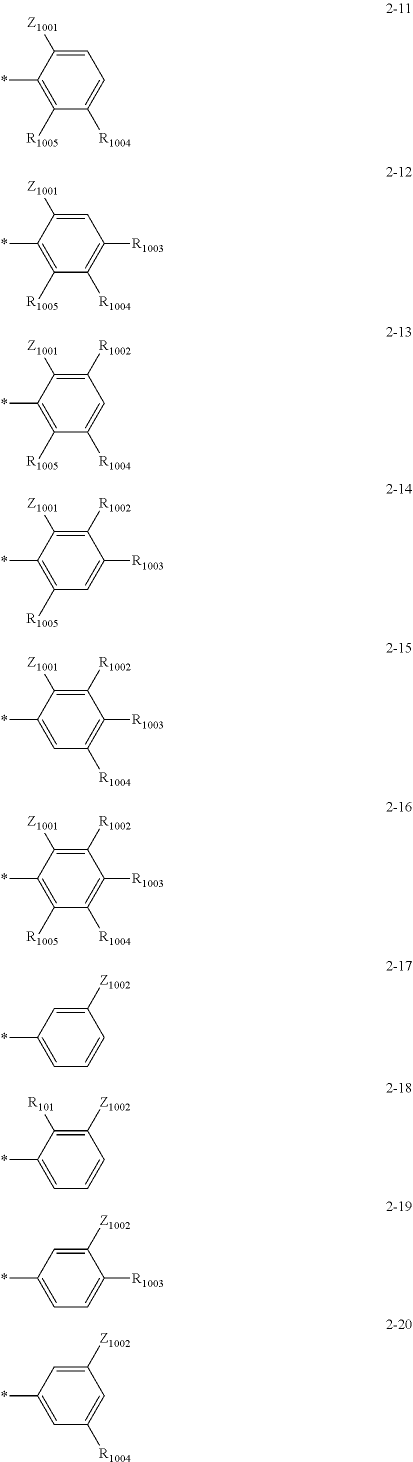

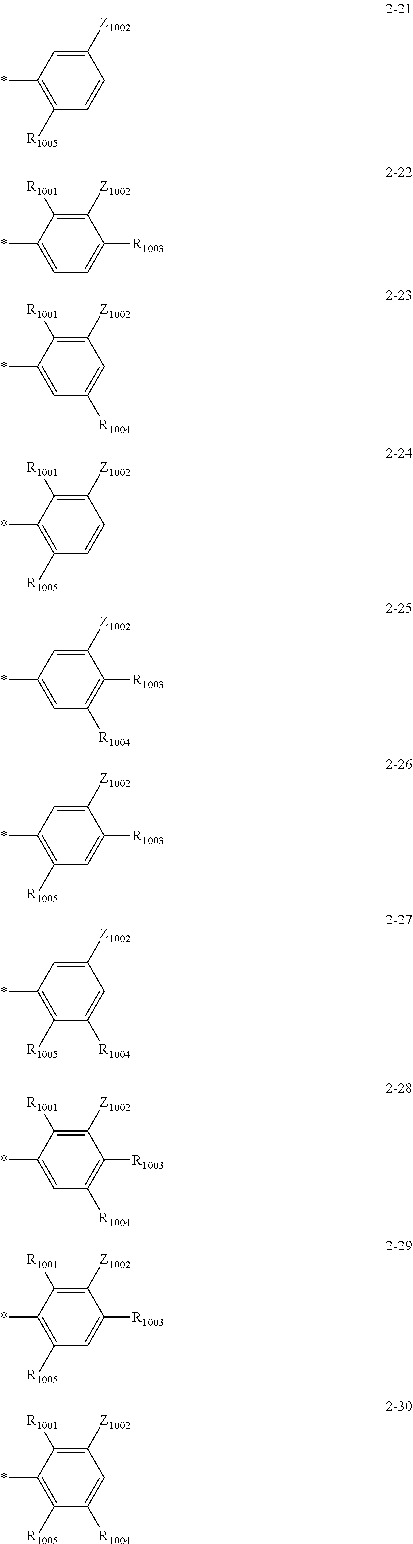

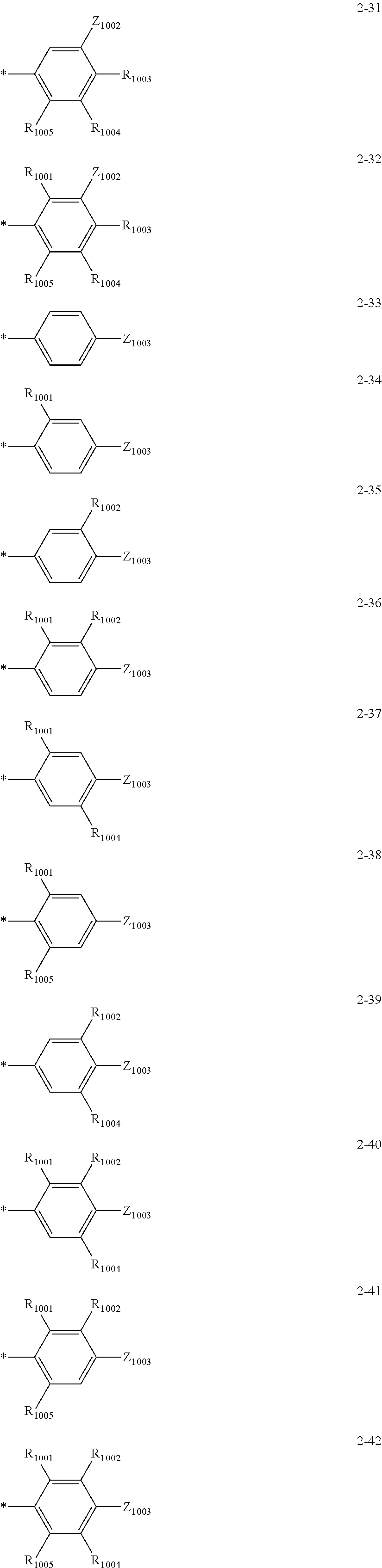

In Formulae 2-1 to 2-42,

R₁₀₀₁ to R₁₀₀₅ are each as defined in connection with R₁₀, provided that each of R₁₀₀₁ to R₁₀₀₅ is not hydrogen,

Z₁₀₀₁ to Z₁₀₀₃ are each as defined in connection with Z₁₀, and

* indicates a binding site to a neighboring atom.

In Formula 1, n13 and n14 are each independently an integer from 0 to 20, and the sum of n13 and n14 is 1 or greater. Thus, Formula 1 may include at least one of Z₁₃ and Z₁₄ as defined herein.

In one or more embodiments, in Formula 1, n13 and n14 may each independently be an integer from 0 to 5, and the sum of n13 and n14 may be 1 to 5.

In one or more embodiments, an organometallic compound represented by Formula 1 may satisfy at least one of Condition 3 and Condition 4:

Condition 3

n13 in Formula 1 is 1 or 2

Condition 4

n14 in Formula 1 is 1 or 2

L₁ to L₄, L₇, L₁₃, and L₁₄ in Formula 1 are each independently a single bond, a C₅-C₃₀ carbocyclic group unsubstituted or substituted with at least one R₁₀ₐ, or a C₁-C₃₀ heterocyclic group unsubstituted or substituted with at least one R₁₀ₐ.

For example, L₁ to L₄, L₇, L₁₃ and L₁₄ in Formula 1 may each independently be:

a single bond; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with at least one R₁₀ₐ.

In one or more embodiments, L₁ to L₄, L₇, L₁₃, and L₁₄ in Formula 1 may each independently be:

a single bond; or

a benzene group unsubstituted or substituted with at least one R₁₀ₐ.

In Formula 1, b1 to b4, b7, b13, and b14 each indicate the number of L₁ to L₄, L₇, L₁₃, and L₁₄ and are each independently an integer from 1 to 5. When b1 is 2 or greater, two or more of L₁(s) are identical to or different from each other, when b2 is 2 or greater, two or more of L₂(s) are identical to or different from each other, when b3 is 2 or greater, two or more of L₃(s) are identical to or different from each other, when b4 is 2 or greater, two or more of L₄(s) are identical to or different from each other, when b7 is 2 or greater, two or more of L₇(s) are identical to or different from each other, when b13 is 2 or greater, two or more of L₁₃(s) are identical to or different from each other, and when b14 is 2 or greater, two or more of L₁₄(s) are identical to or different from each other.

In one or more embodiments, b1 to b4, b7, b13, and b14 in Formula 1 may each independently be 1, 2, or, 3.

In Formula 1, R₁ to R₄, R₇ to R₉, R₉ₐ, R_{9b}, R′, and R″ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ are each as defined herein.

For example, R¹ to R₄, R₇ to R₉, R₉ₐ, R_{9b}, R′, and R″ may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₂₀ alkylthio group,

a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof,

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl) phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof, or

—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

wherein Q₁ to Q₉ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂, or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

In Formula 1, c1 to c4, c7, c13, and c14 each indicate the number of R₁ to R₄, R₇, Z₁₃, and Z₁₄, and are each independently an integer from 1 to 5. When c1 is 2 or greater, two or more of R₁(s) are identical to or different from each other, when c2 is 2 or greater, two or more of R₂(s) are identical to or different from each other, when c3 is 2 or greater, two or more of R₃(s) are identical to or different from each other, when c4 is 2 or greater, two or more of R₄(s) are identical to or different from each other, when c7 is 2 or greater, two or more of R₇(s) are identical to or different from each other, when c13 is 2 or greater, two or more of Z₁₃(s) are identical to or different from each other, and when c14 is 2 or greater, two or more of Z₁₄(s) are identical to or different from each other.

In one or more embodiments, c1 to c4, c7, c13 and c14 in Formula 1 may each independently be 1 or 2.

a1 to a4 in Formula 1 each indicate the number of *-[(L₁)_{b1}-(R₁)_{c1}], *-[(L₂)_{b2}-(R₂)_{c2}], *-[(L₃)_{b3}-(R₃)_{c3}], and *-[(L₄)_{b4}-(R₄)_{c4}], respectively, and are each independently an integer from 0 to 20. When a1 is 2 or greater, two or more of *-[(L₁)_{b1}-(R₁)_{c1}] are identical to or different from each other, when a2 is 2 or greater, two or more of *-[(L₂)_{b2}-(R₂)_{c2}] are identical to or different from each other, when a3 is 2 or greater, two or more of *-[(L₃)_{b3}-(R₃)_{c3}] are identical to or different from each other, and when a4 is 2 or greater, two or more of *-[(L₄)_{b4}-(R₄)_{c4}] are identical to or different from each other.

In one or more embodiments, R₁ to R₄, R₇ to R₉, R₉ₐ, R_{9b}, R′ and R″ in Formula 1 may each independently be hydrogen, deuterium, —F, a cyano group, a nitro group, —SF₅, —CH₃, —CD₃, —CD₂H, —CDH₂, —CF₃, —CF₂H, —CFH₂, —OCH₃, —OCDH₂, —OCD₂H, —OCD₃, —SCH₃, —SCDH₂, —SCD₂H, —SCD₃, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-233, a group represented by one of Formulae 9-201 to 9-233 in which at least one hydrogen is substituted with deuterium, a group represented by one of Formulae 9-201 to 9-233 in which at least one hydrogen is substituted with —F, a group represented by one of Formulae 10-1 to 10-132, a group represented by one of Formulae 10-1 to 10-132 in which at least one hydrogen is substituted with deuterium, a group represented by one of Formulae 10-1 to 10-132 in which at least one hydrogen is substituted with —F, a group represented by one of Formulae 10-201 to 10-353, a group represented by one of Formulae 10-201 to 10-353 in which at least one hydrogen is substituted with deuterium, a group represented by one of Formulae 10-201 to 10-353 in which at least one hydrogen is substituted with —F, —Si(Q₃)(Q₄)(Q₅), or —Ge(Q₃)(Q₄)(Q₅) (Q₃ to Q₅ are each the same as defined herein).

In one or more embodiments, Z₁₀ in Formula 2 may be —F, —CF₃, —CF₂H, —CFH₂, a group represented by one of Formulae 9-1 to 9-39 wherein at least one hydrogen is substituted with —F, a group represented by one of Formulae 9-201 to 9-233 wherein at least one hydrogen is substituted with —F, a group represented by one of Formulae 10-1 to 10-132 wherein at least one hydrogen is substituted with —F, or a group represented by one of Formulae 10-201 to 10-353 wherein at least one hydrogen is substituted with —F.

In one or more embodiments, a group represented by Formula 2 may be a group represented by one of Formulae 10-12 to 10-132 wherein at least one hydrogen is substituted with —F, or a group represented by one of Formulae 10-201 to 10-353 wherein at least one hydrogen is substituted with —F:

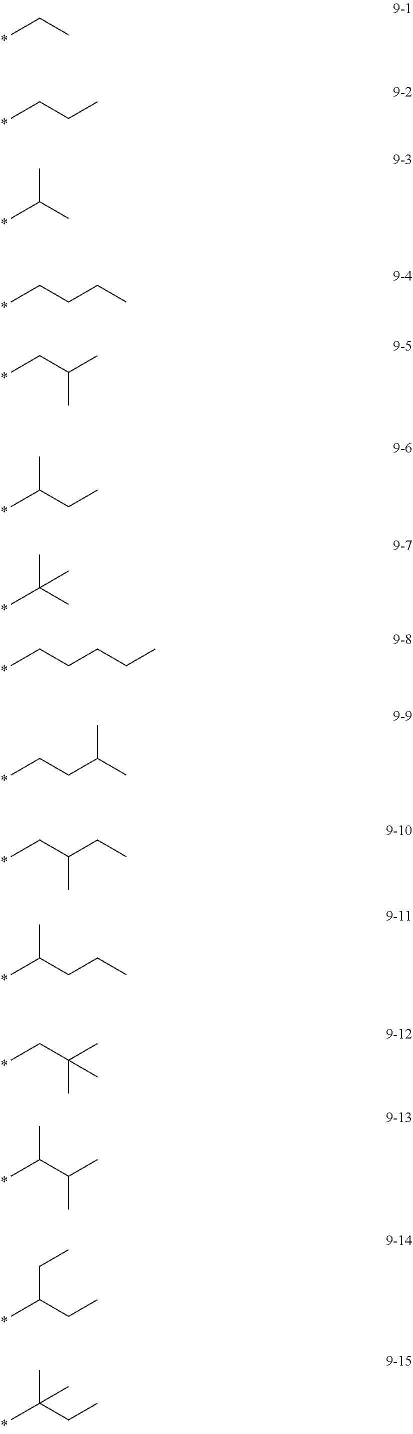

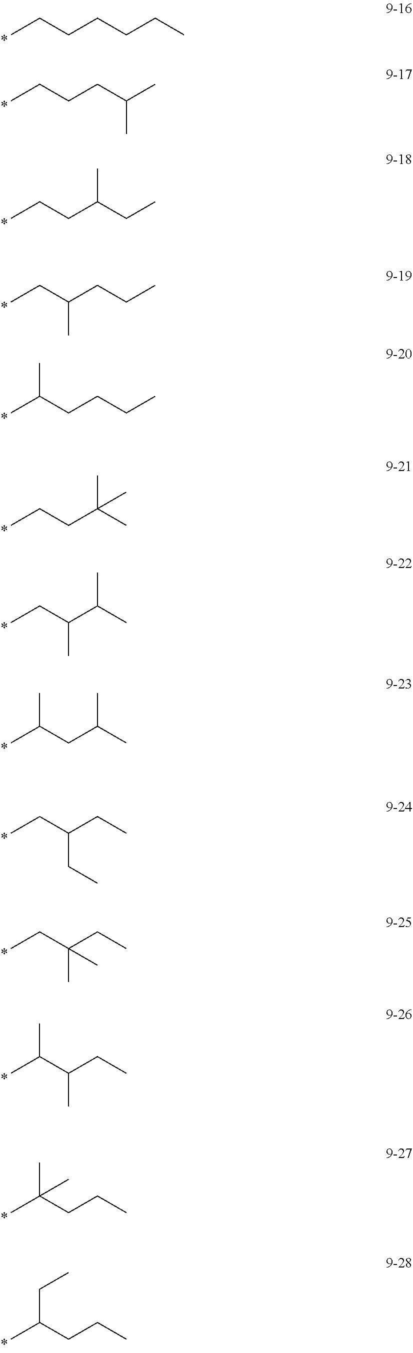

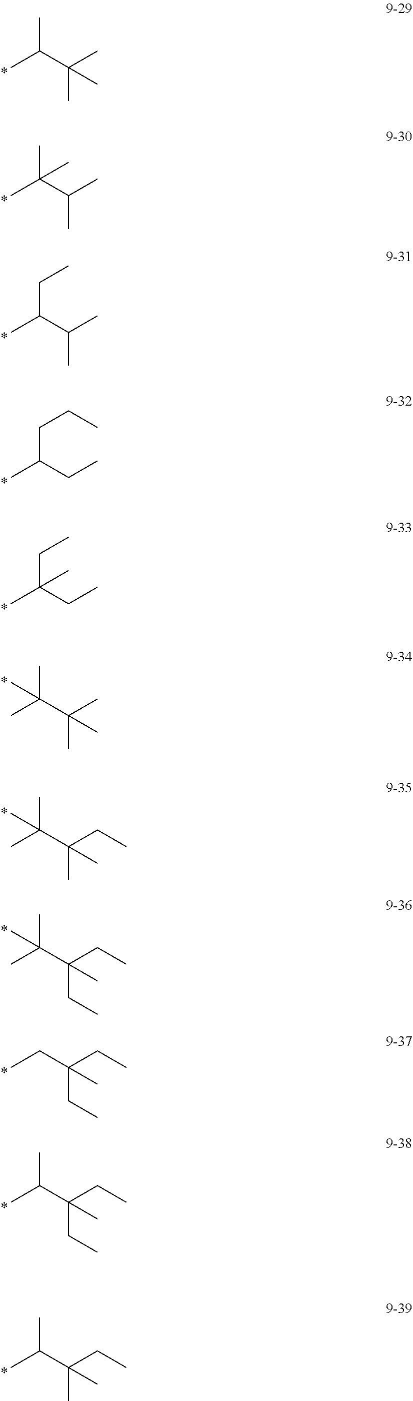

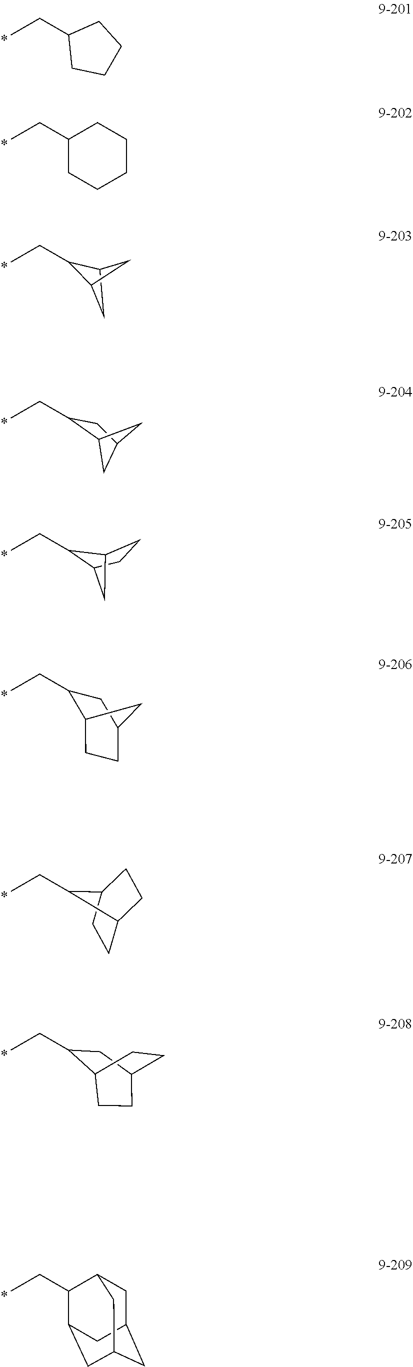

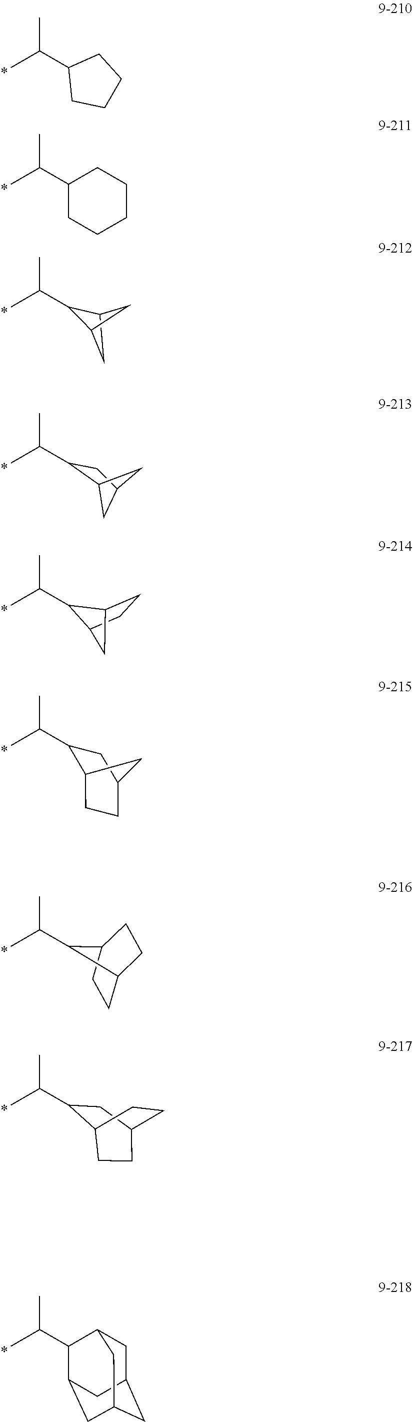

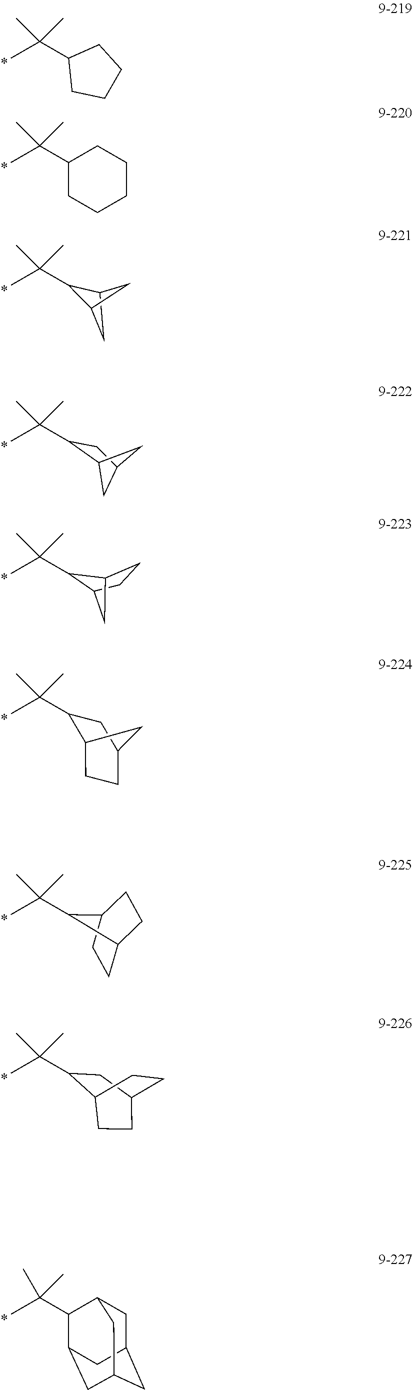

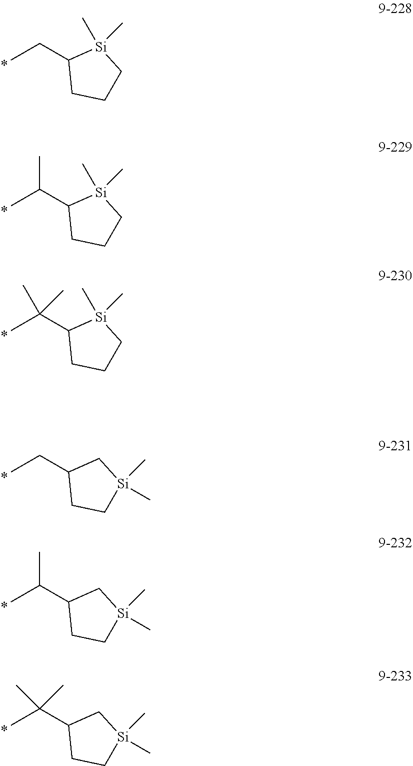

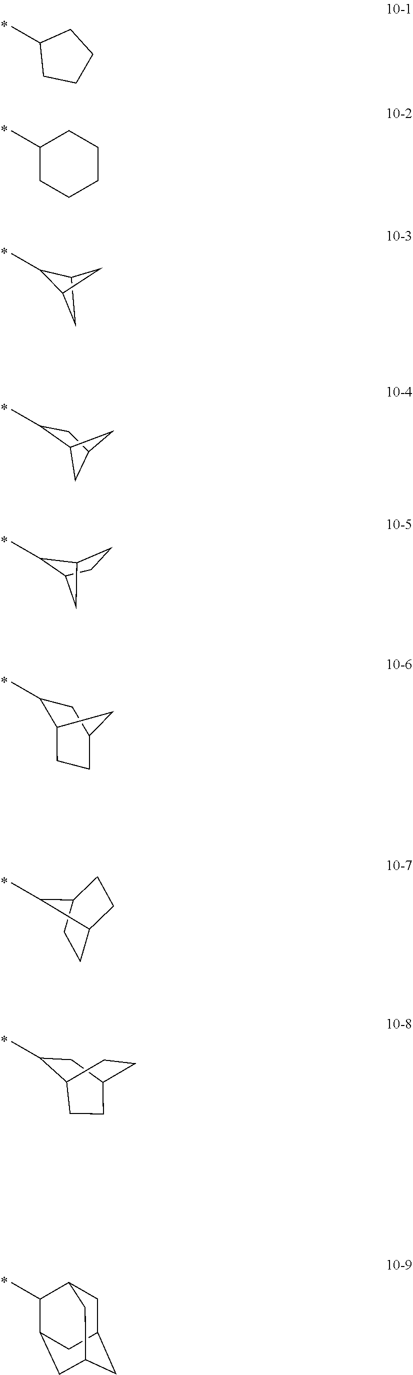

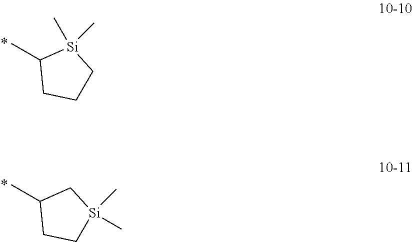

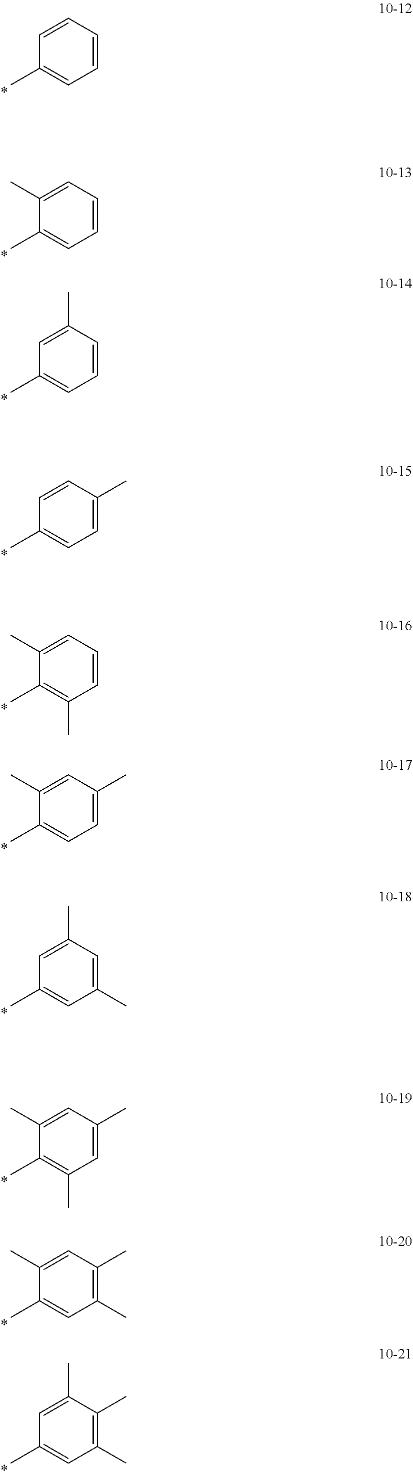

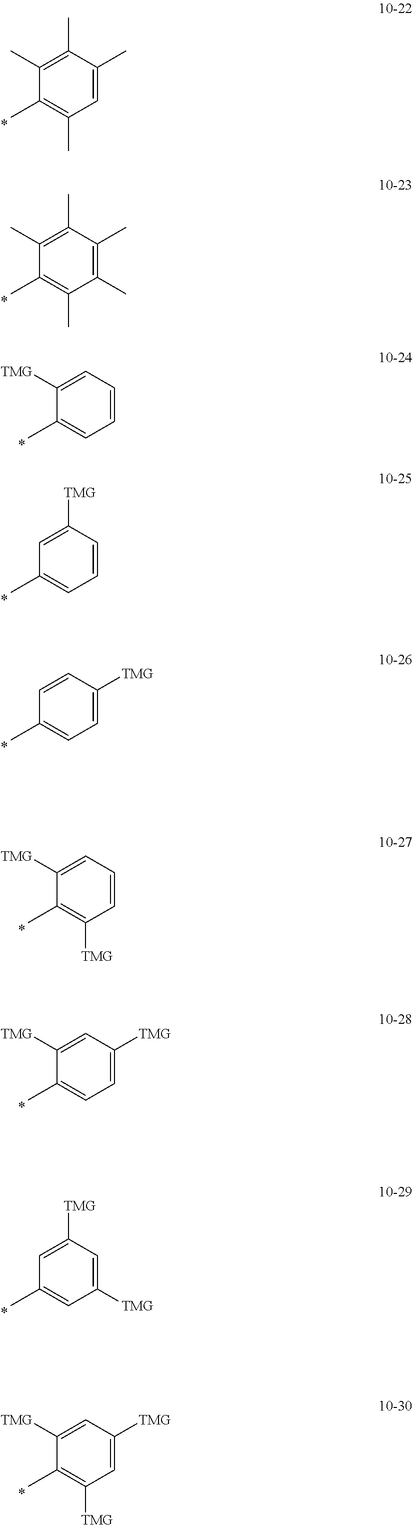

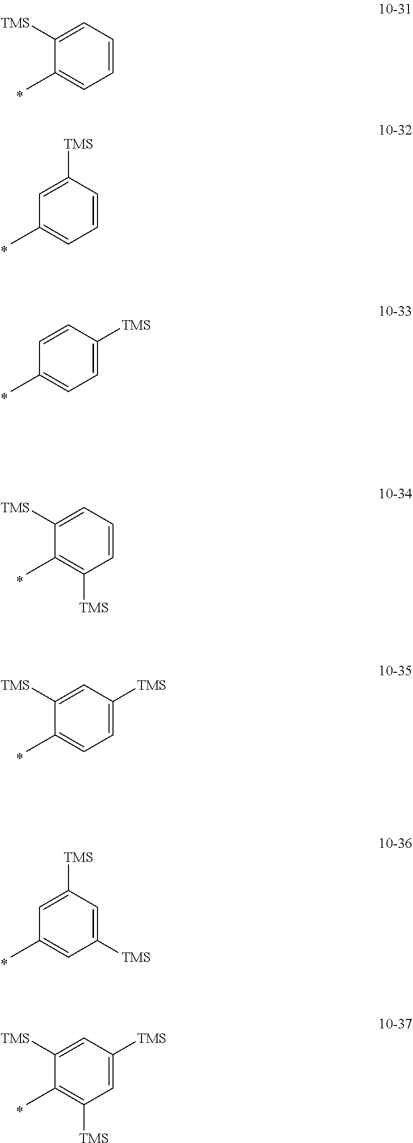

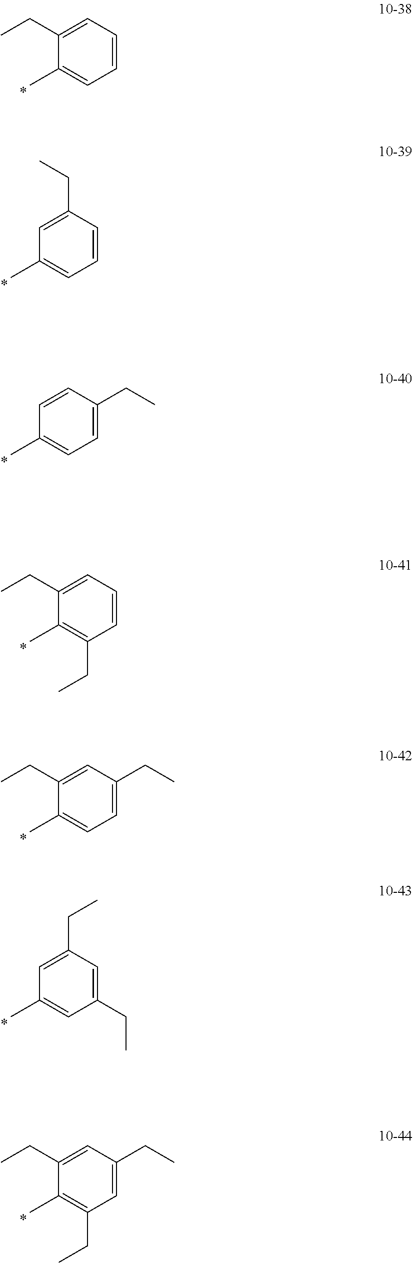

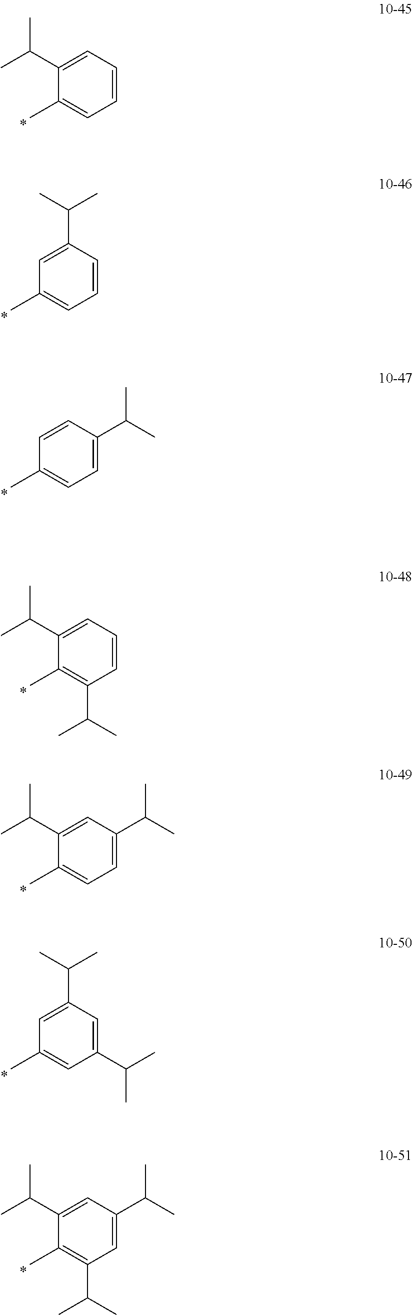

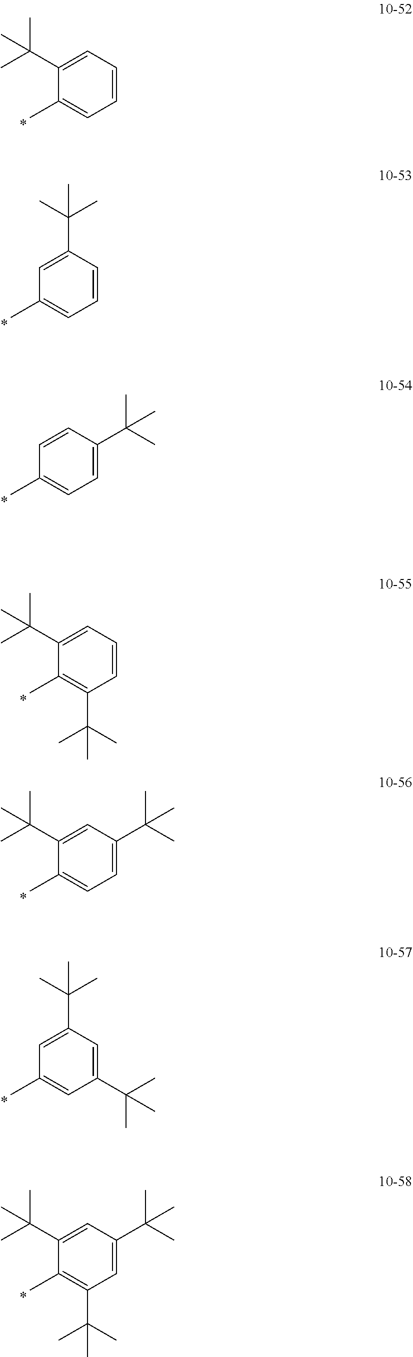

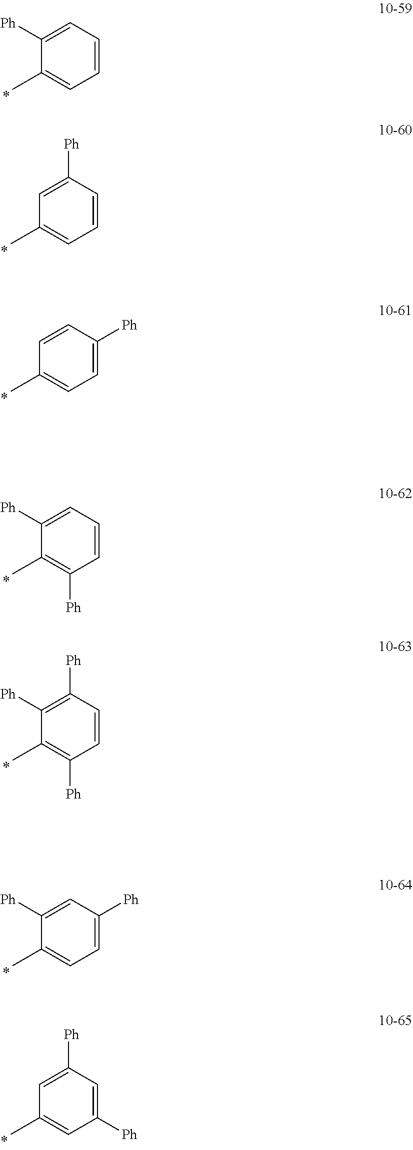

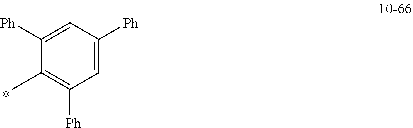 [SMILES: Cc1c(-c2ccccc2)cc(-c2ccccc2)cc1-c1ccccc1]

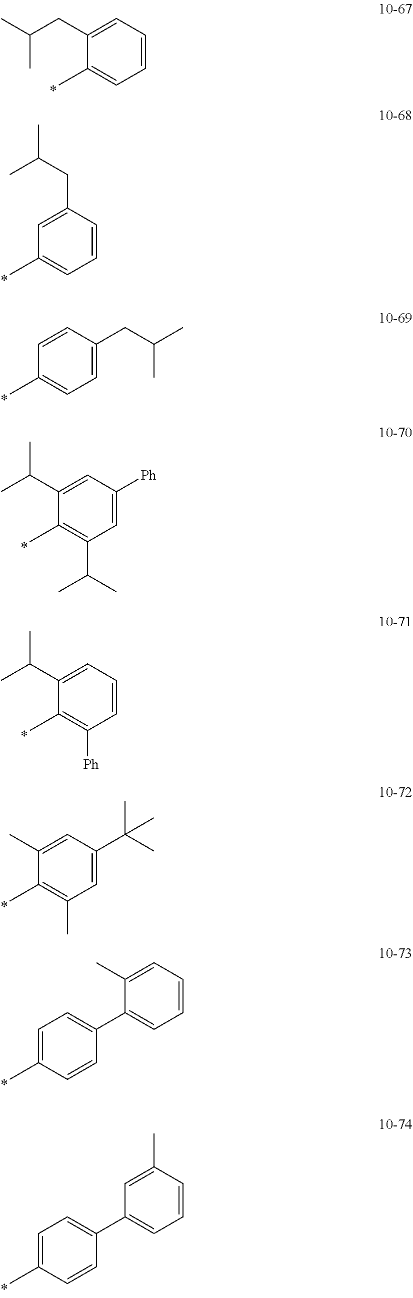

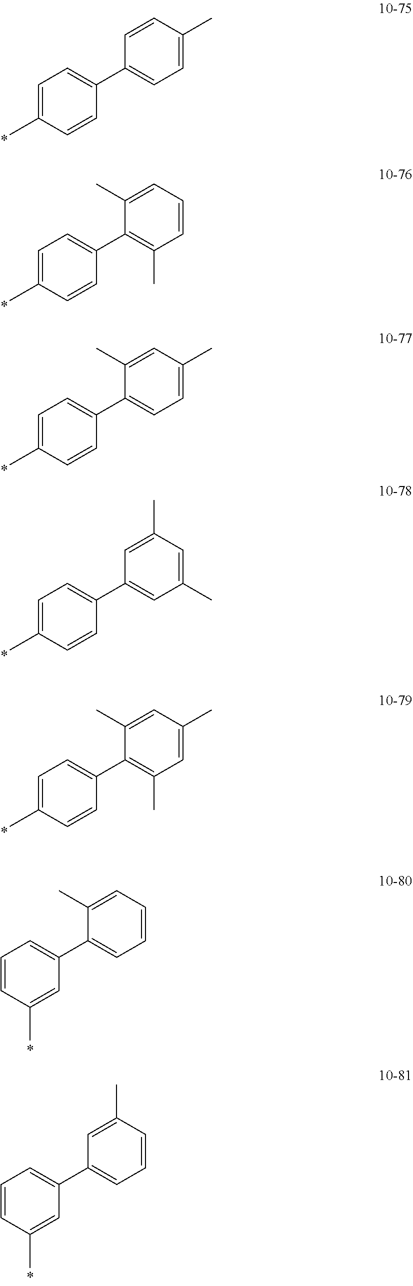

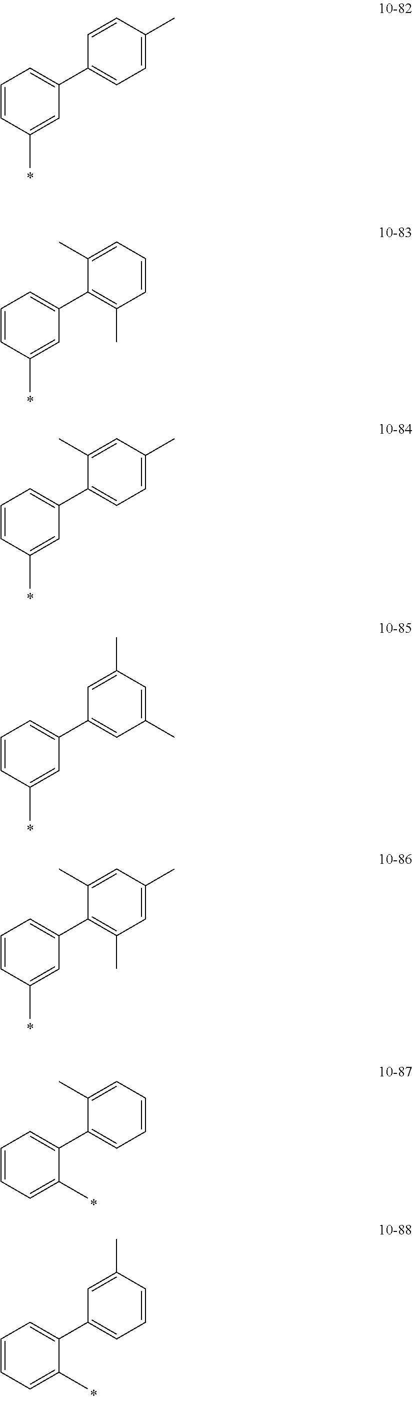

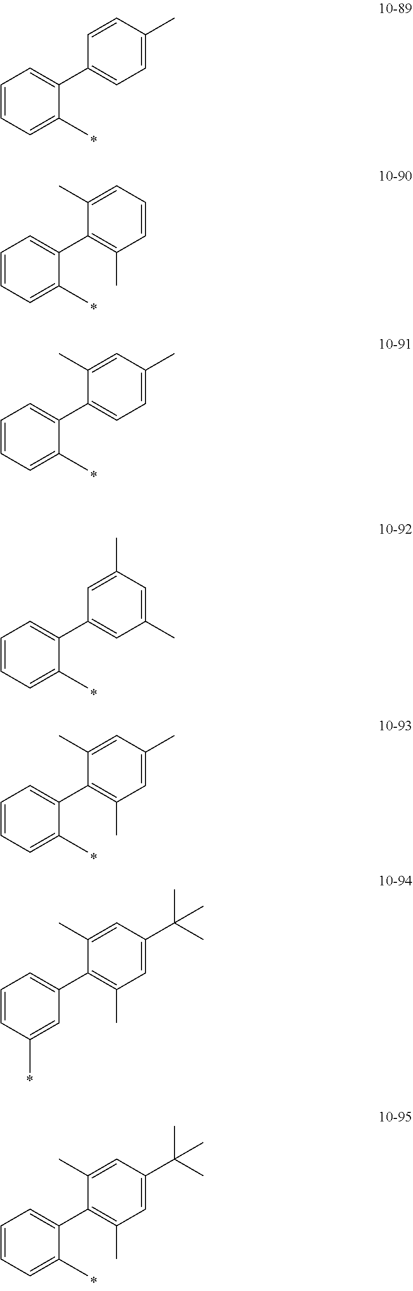

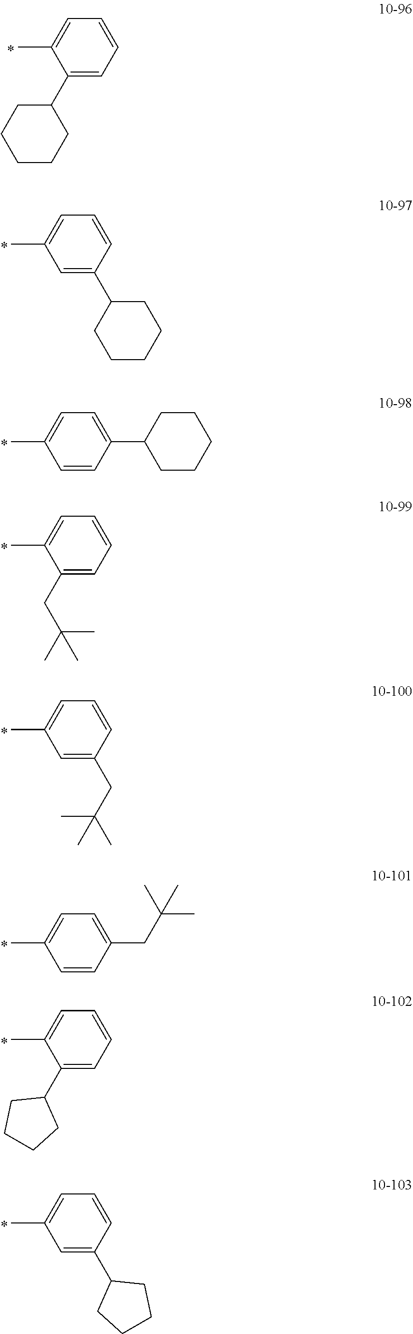

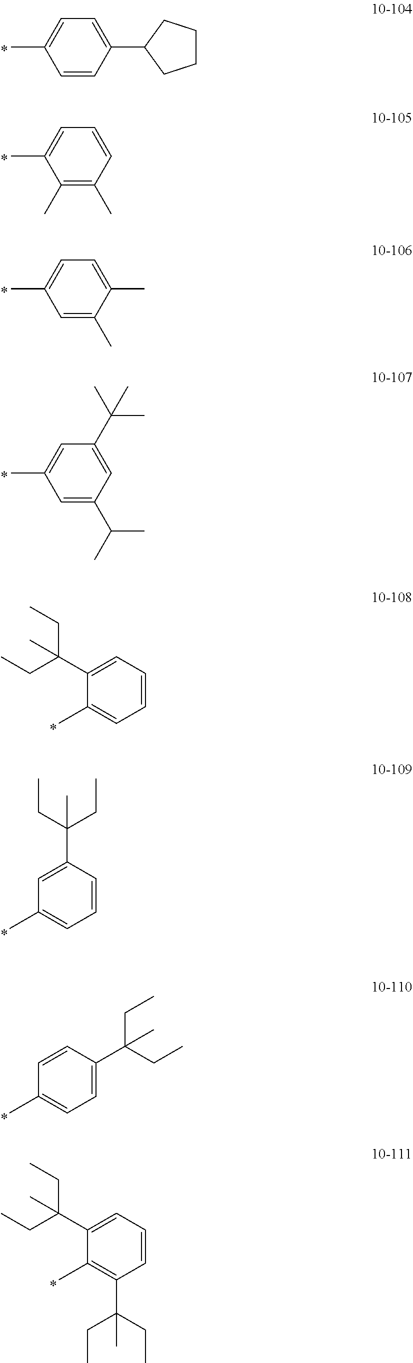

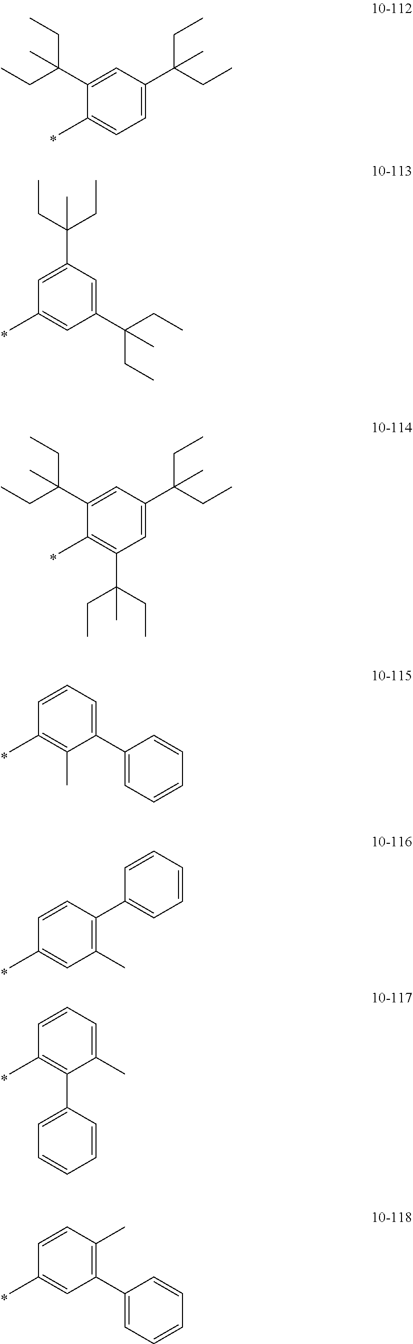

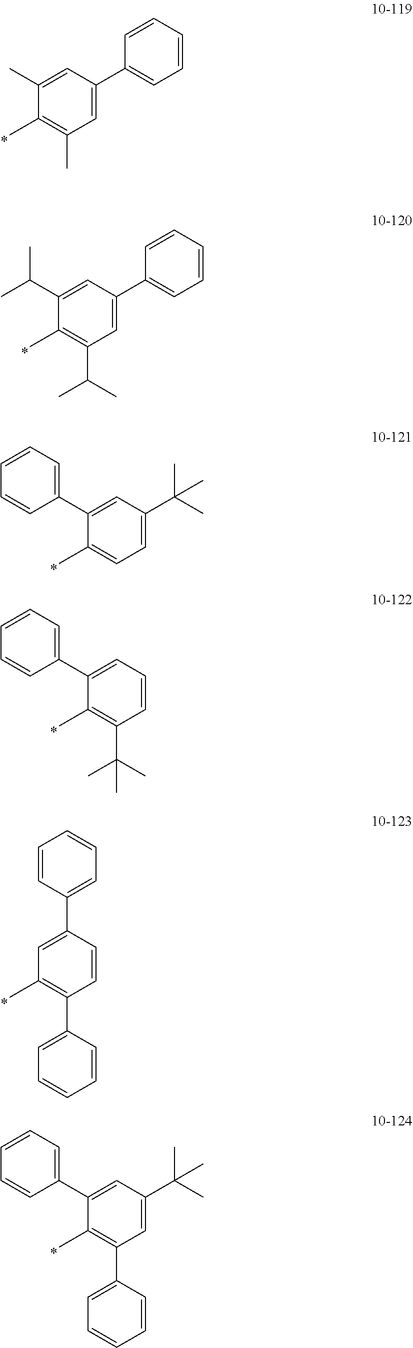

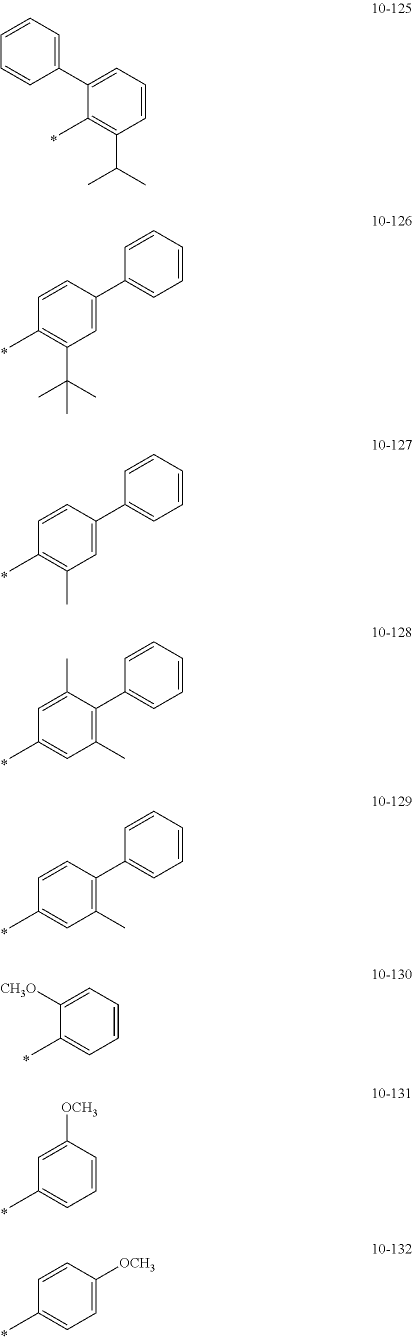

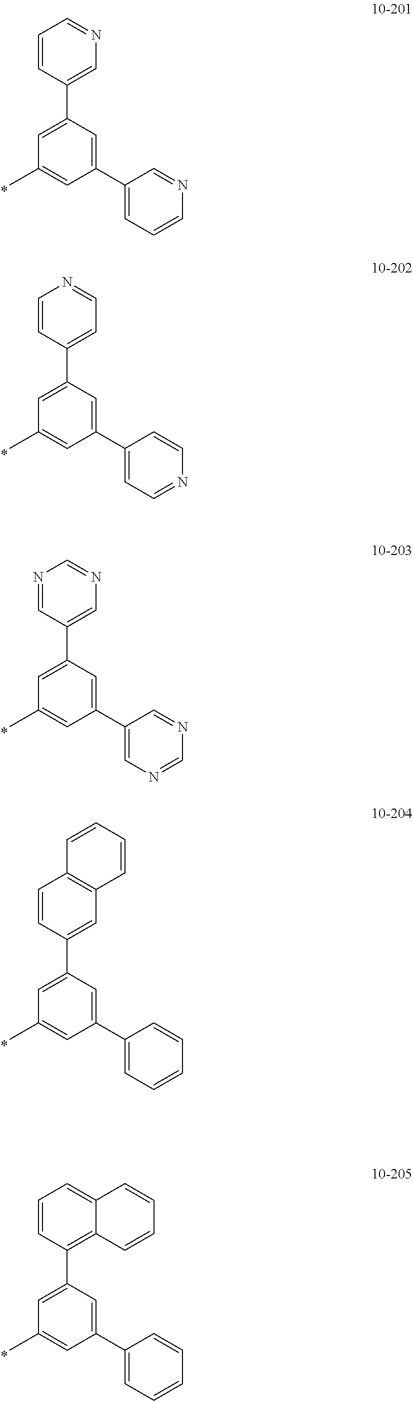

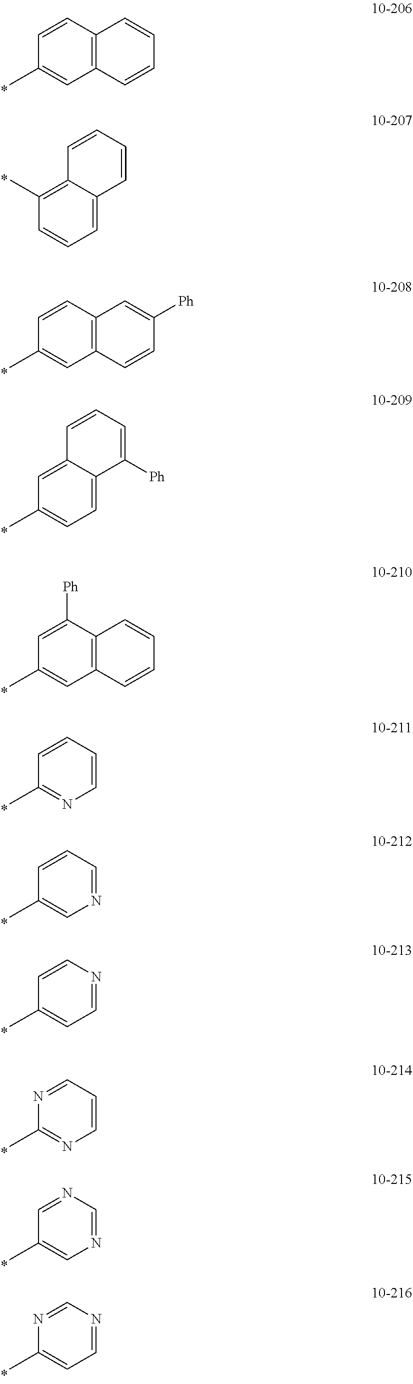

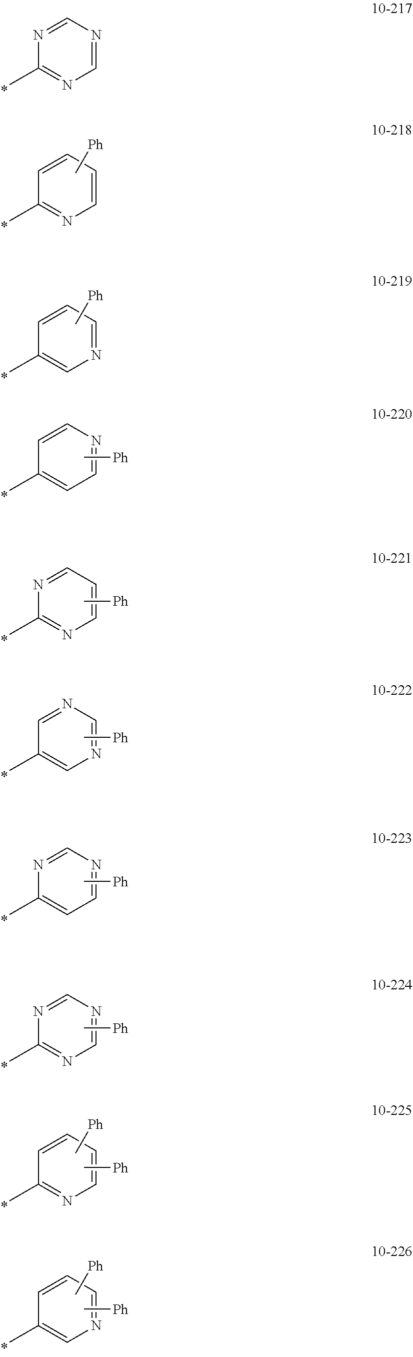

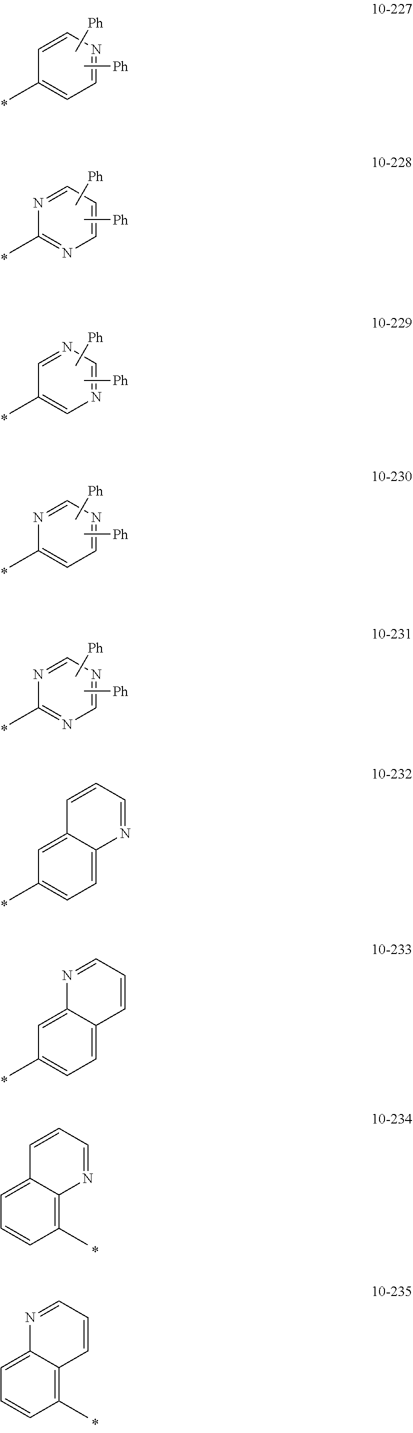

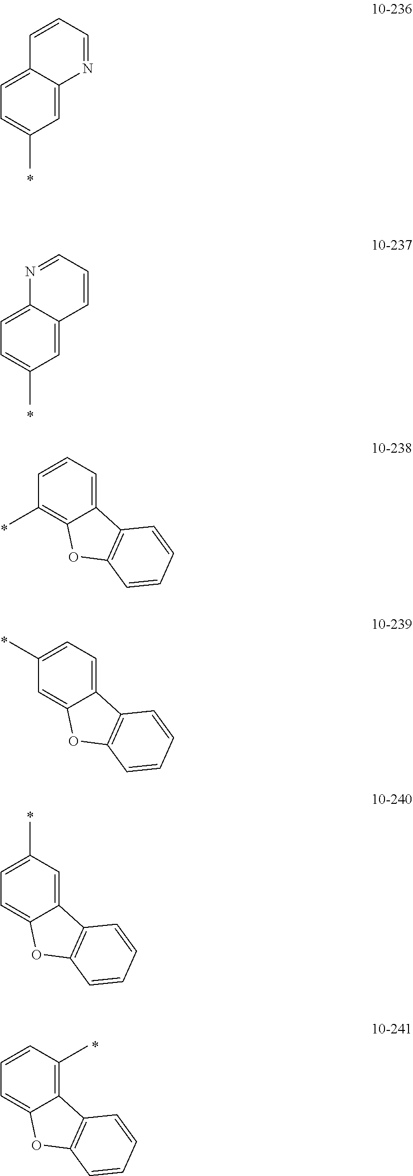

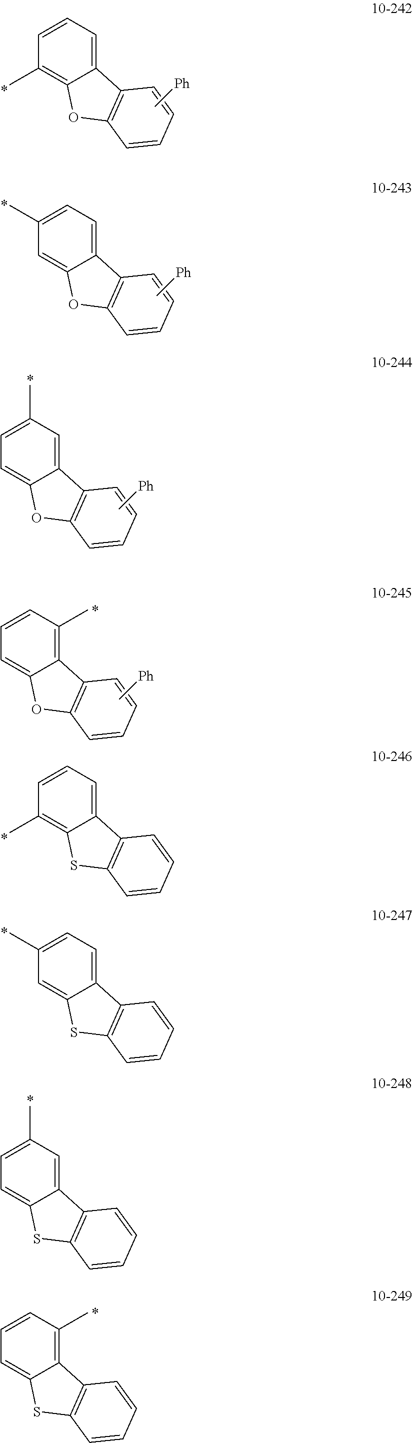

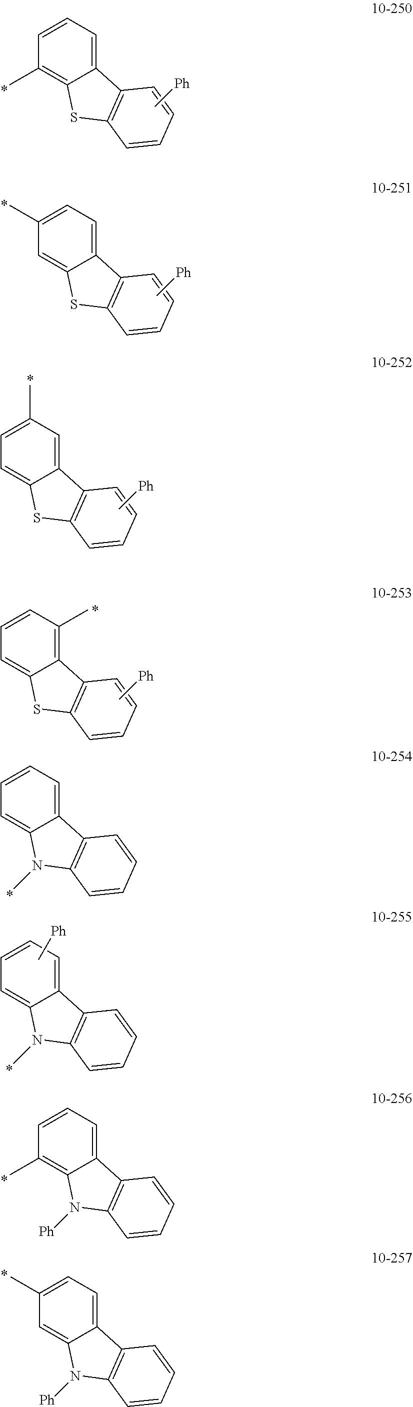

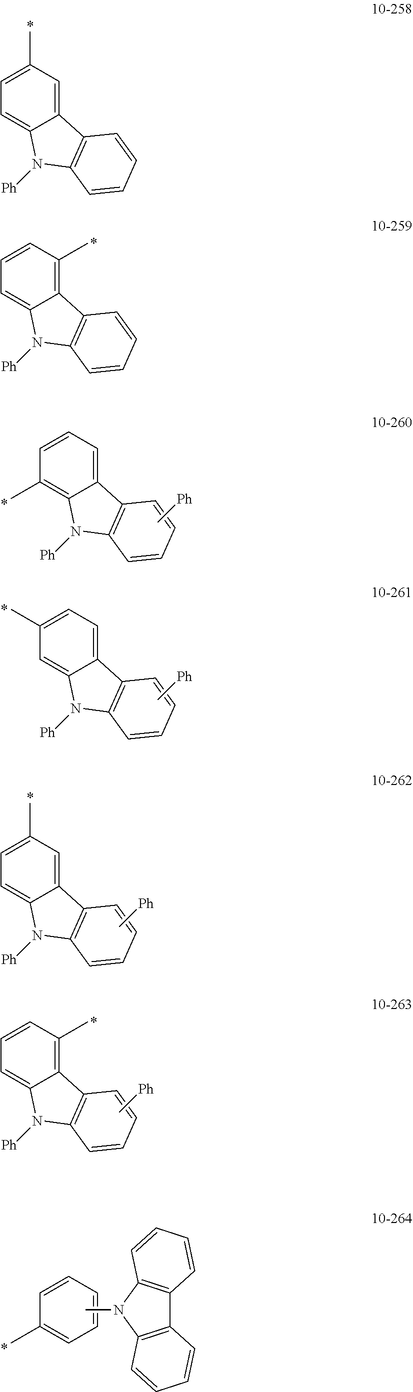

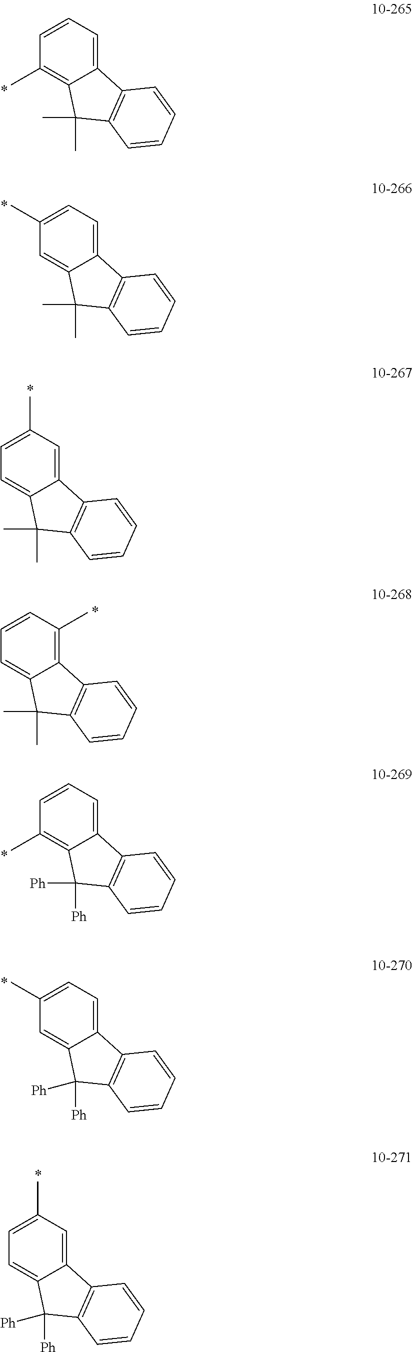

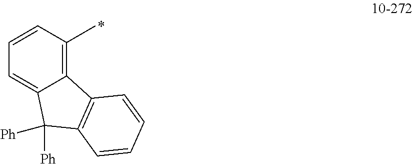 [SMILES: Cc1cccc2c1-c1ccccc1C2(c1ccccc1)c1ccccc1]

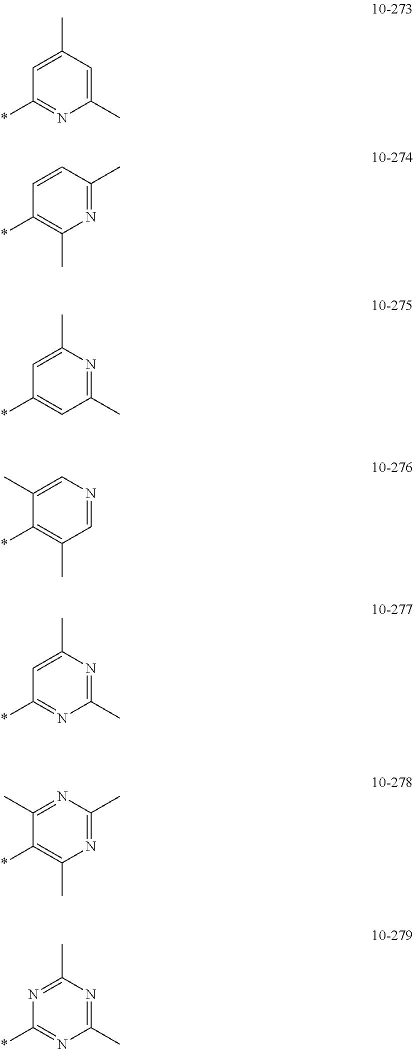

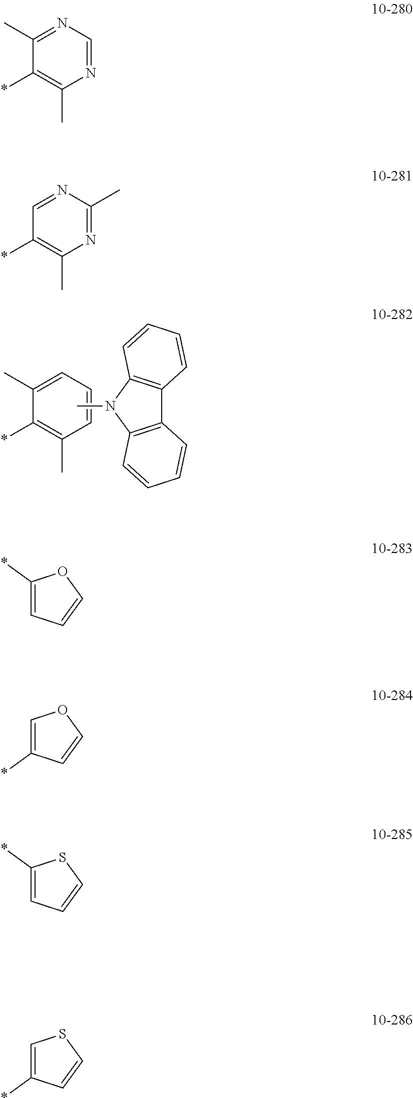

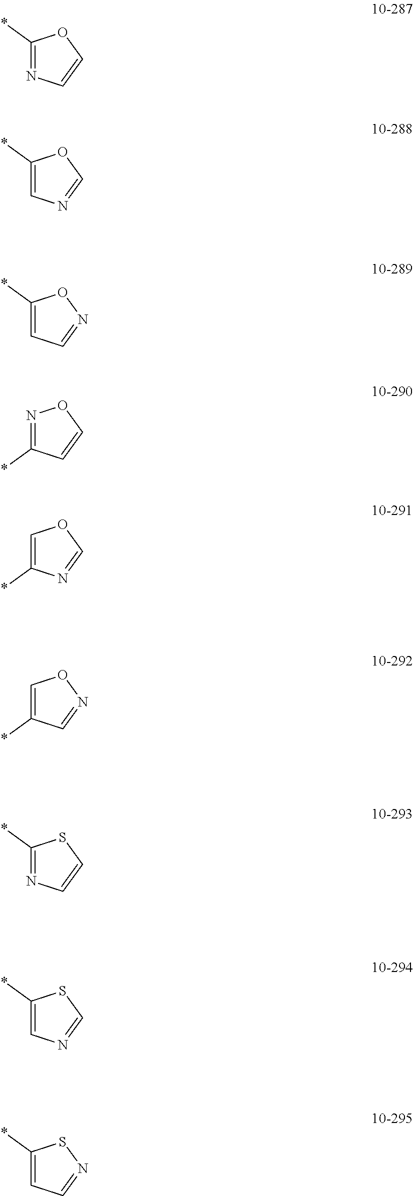

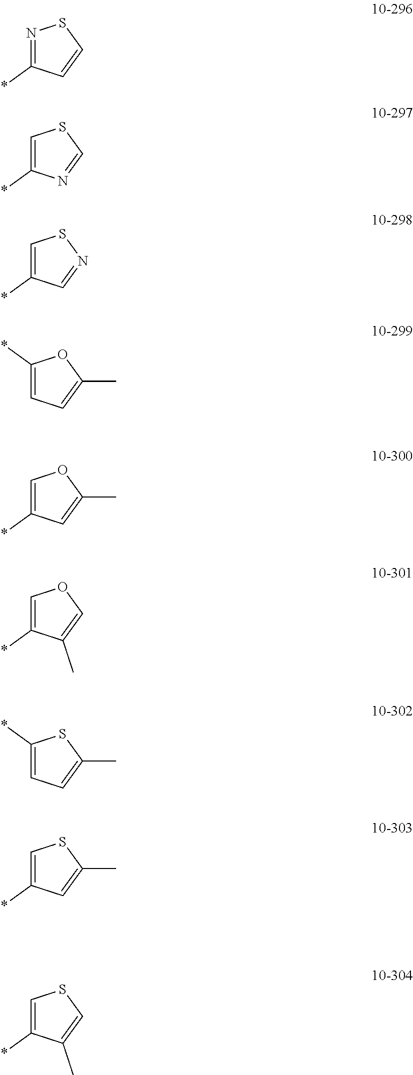

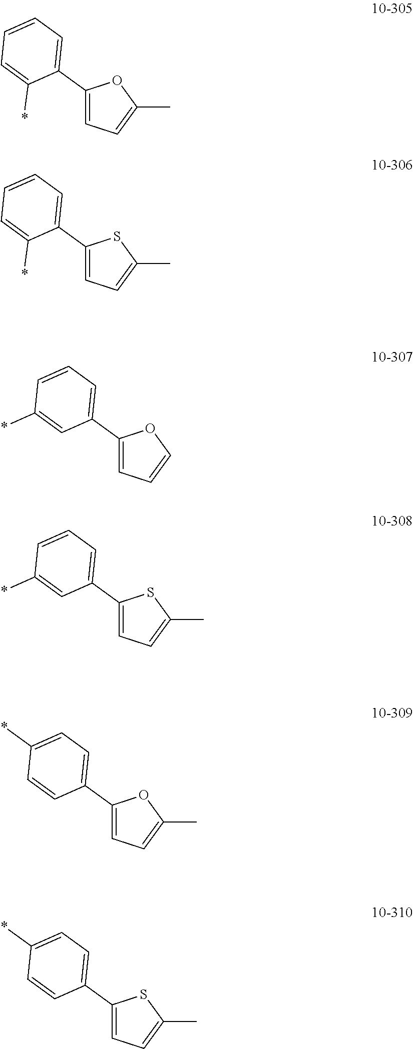 [SMILES: *c1ccccc1-c1ccc(C)o1 ; *c1ccccc1-c1ccc(C)s1 ; *c1cccc(-c2ccco2)c1 ; *c1cccc(-c2ccc(C)s2)c1 ; *c1ccc(-c2ccc(C)o2)cc1 ; *c1ccc(-c2ccc(C)s2)cc1]

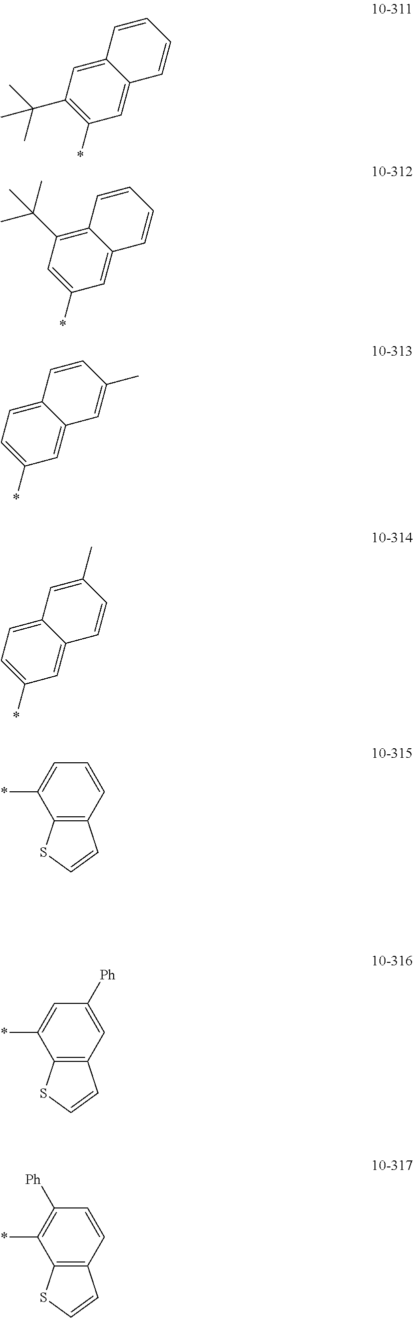

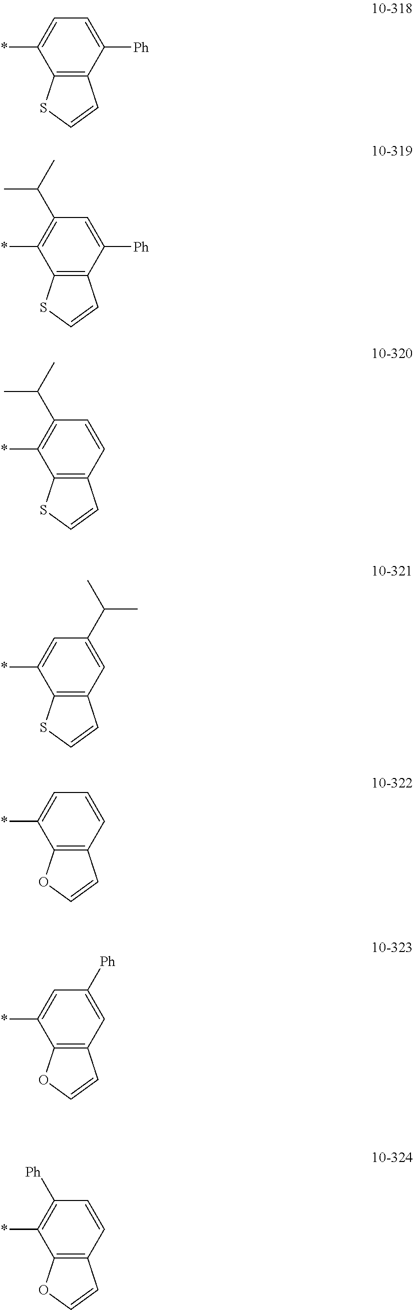

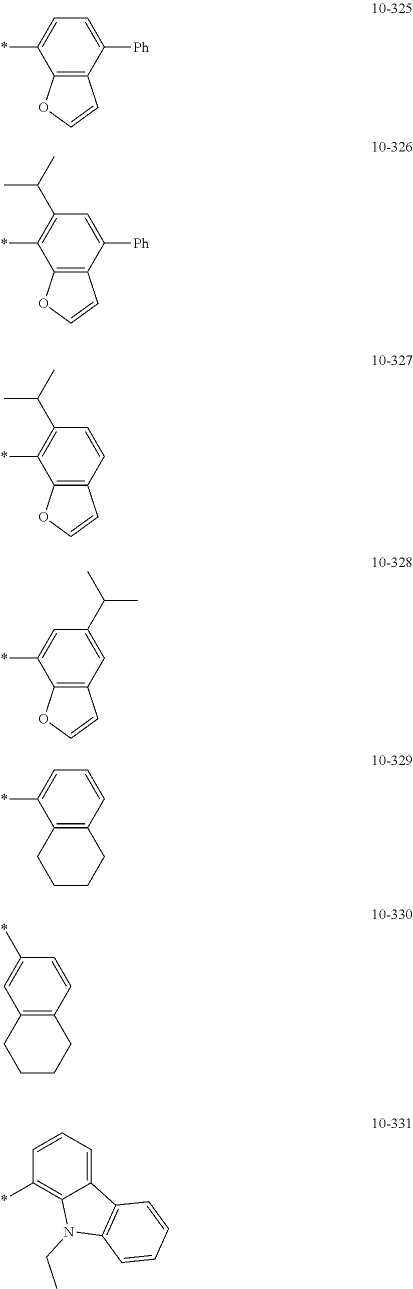

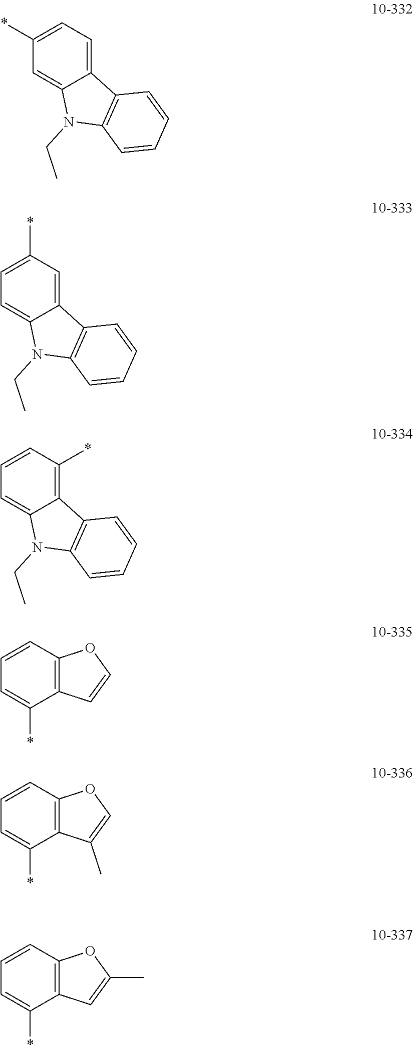

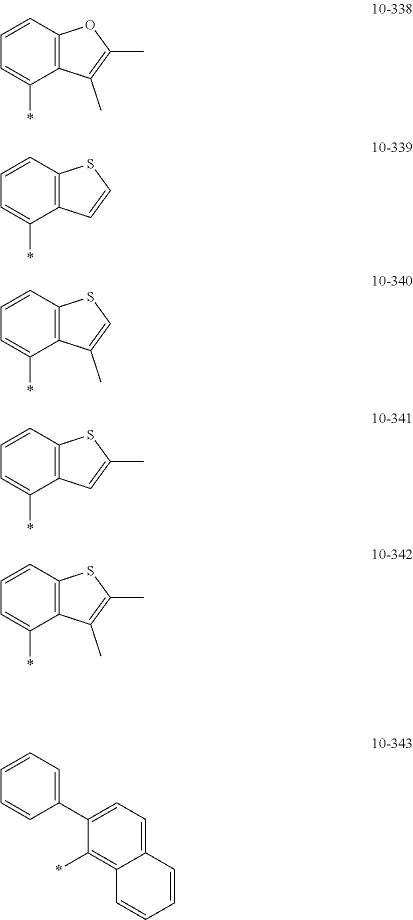

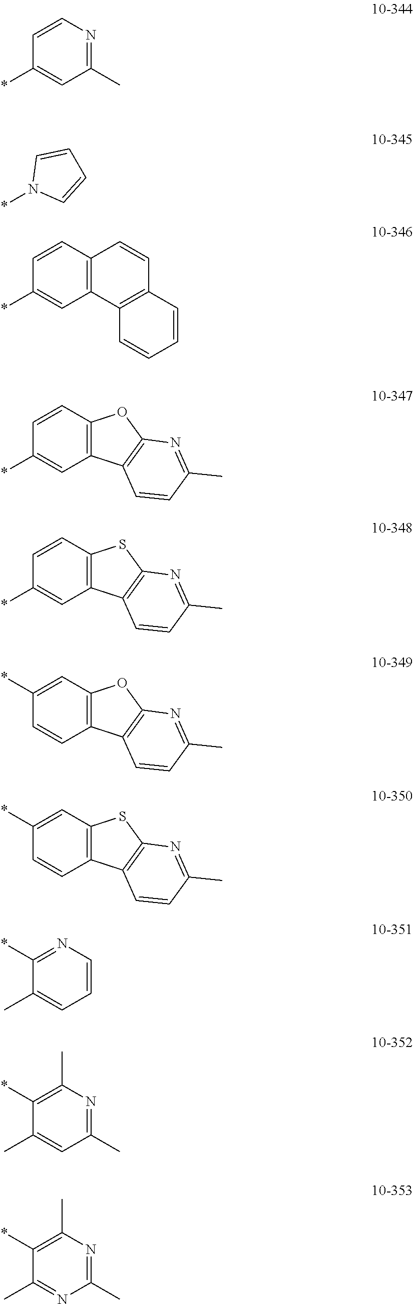

In Formulae 9-1 to 9-39, 9-201 to 9-233, 10-1 to 10-132, and 10-201 to 10-353, * indicates a binding site to a neighboring atom, Ph is a phenyl group, TMS is a trimethylsilyl group, TMG is a trimethylgermyl group, and OMe is a methoxy group.

As used herein, the “group represented by one of Formulae 9-1 to 9-39 in which at least one hydrogen is substituted with deuterium” and the “group represented by one of Formulae 9-201 to 9-233 in which at least one hydrogen is substituted with deuterium” may be, for example, a group represented by one of Formulae 9-501 to 9-514 and 9-601 to 9-635:

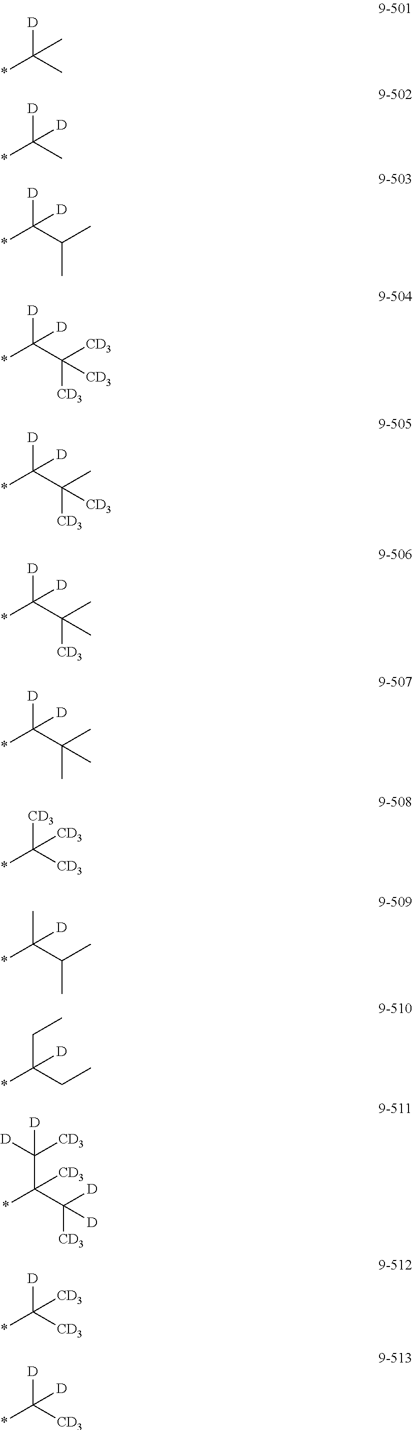

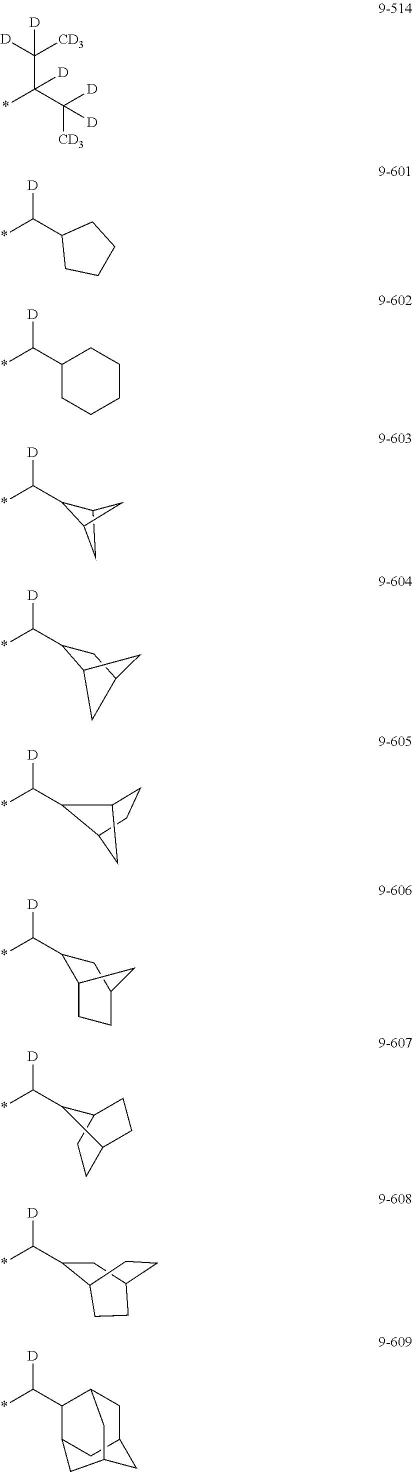

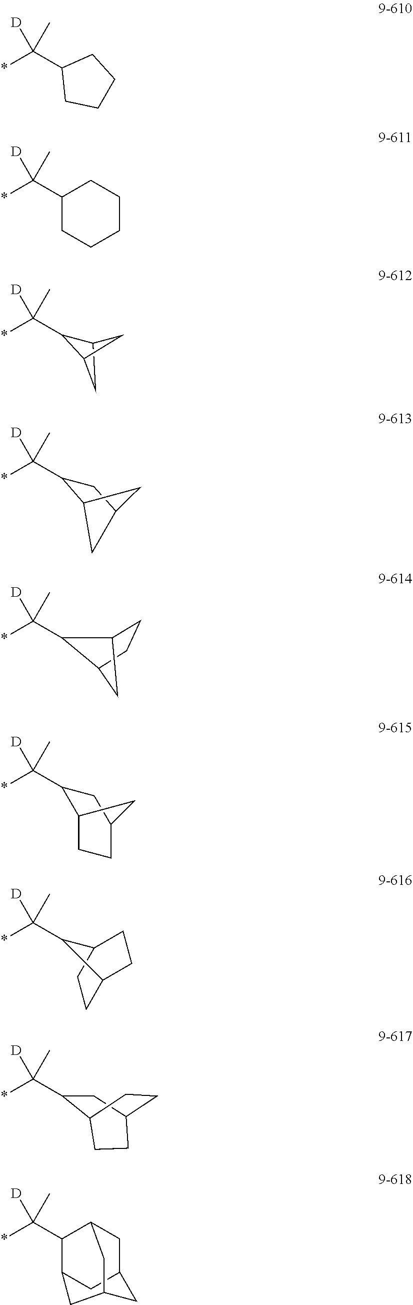

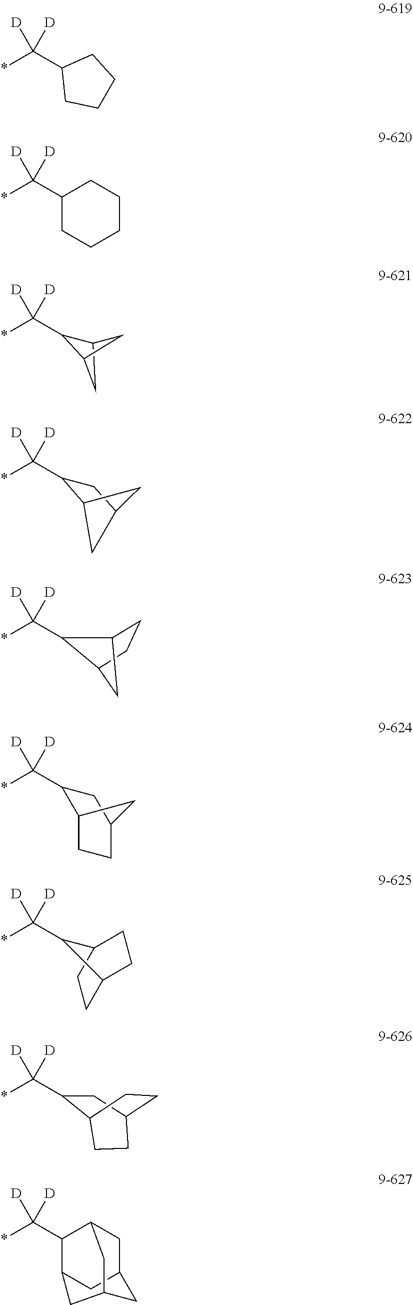

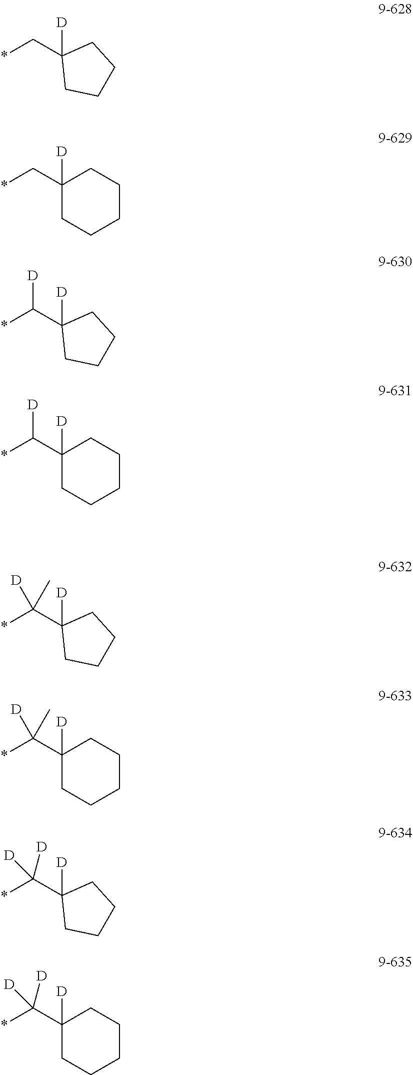

As used herein, the “group represented by one of Formulae 9-1 to 9-39 in which at least one hydrogen is substituted with —F” and the “group represented by one of Formulae 9-201 to 9-233 in which at least one hydrogen is substituted with —F” may be, for example, a group represented by one of Formulae 9-701 to 9-710:

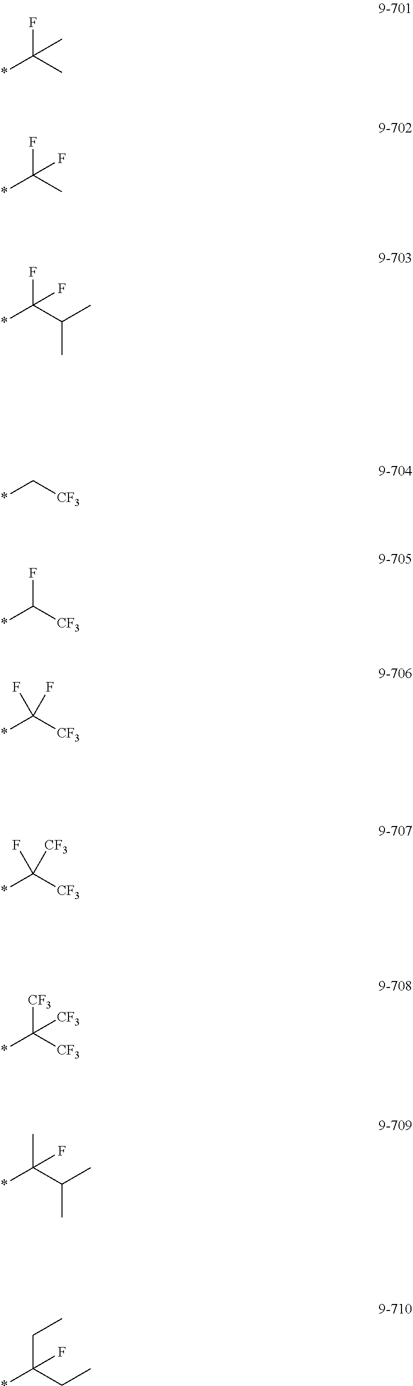

As used herein, the “group represented by one of Formulae 10-1 to 10-132 in which at least one hydrogen is substituted with deuterium” and the “group represented by one of Formulae 10-201 to 10-353 in which at least one hydrogen is substituted with deuterium” may be, for example, a group represented by one of Formulae 10-501 to 10-553:

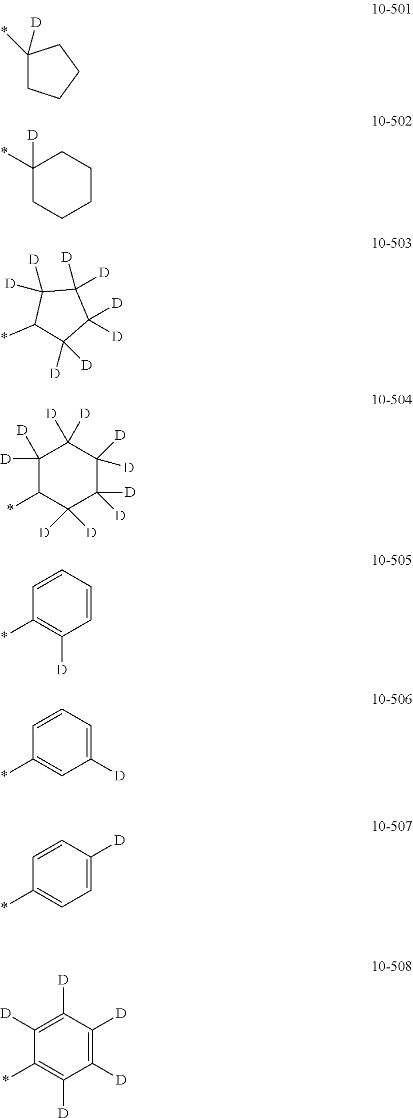

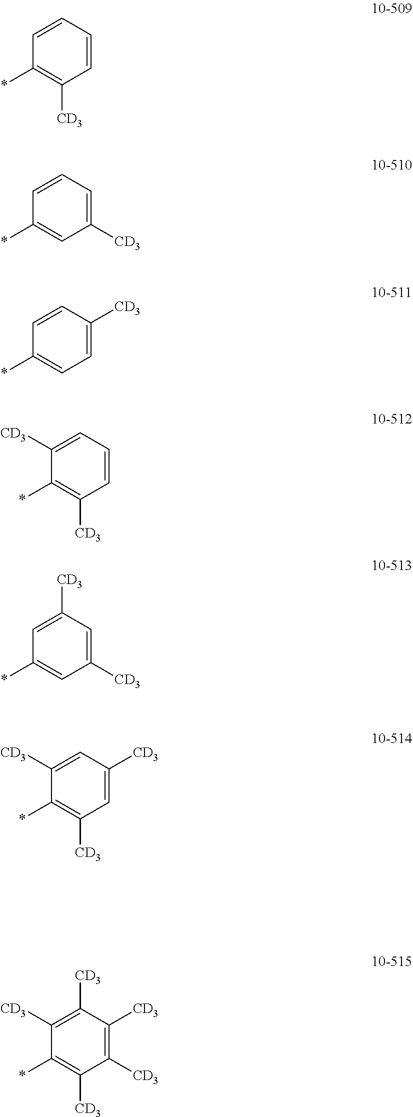

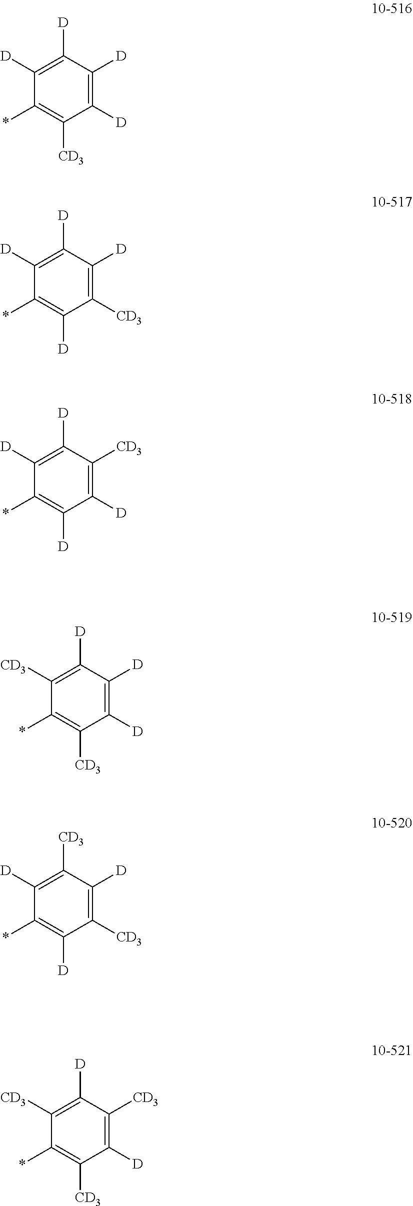 [SMILES: *c1c([2H])c([2H])c([2H])c([2H])c1C([2H])([2H])[2H] ; *c1c([2H])c([2H])c([2H])c(C([2H])([2H])[2H])c1[2H] ; *c1c([2H])c([2H])c(C([2H])([2H])[2H])c([2H])c1[2H] ; *c1c(C([2H])([2H])[2H])c([2H])c([2H])c([2H])c1C([2H])([2H])[2H] ; *c1c([2H])c(C([2H])([2H])[2H])c([2H])c(C([2H])([2H])[2H])c1[2H] ; *c1c(C([2H])([2H])[2H])c([2H])c(C([2H])([2H])[2H])c([2H])c1C([2H])([2H])[2H]]

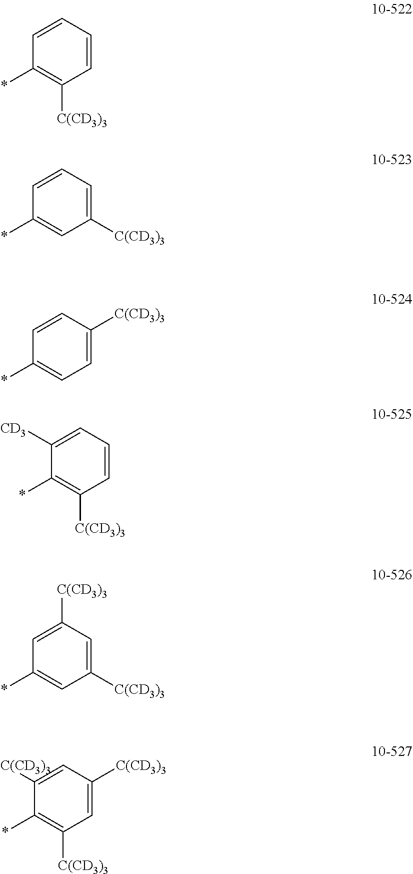

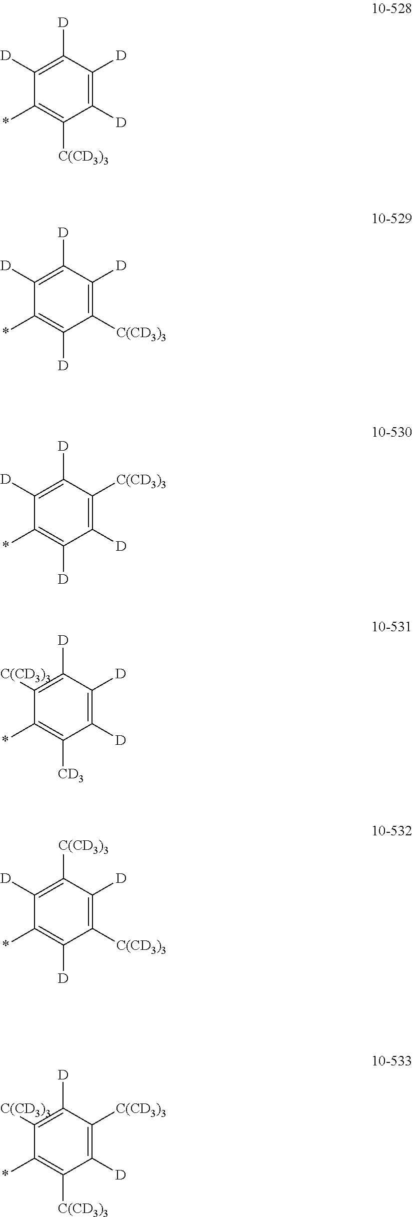

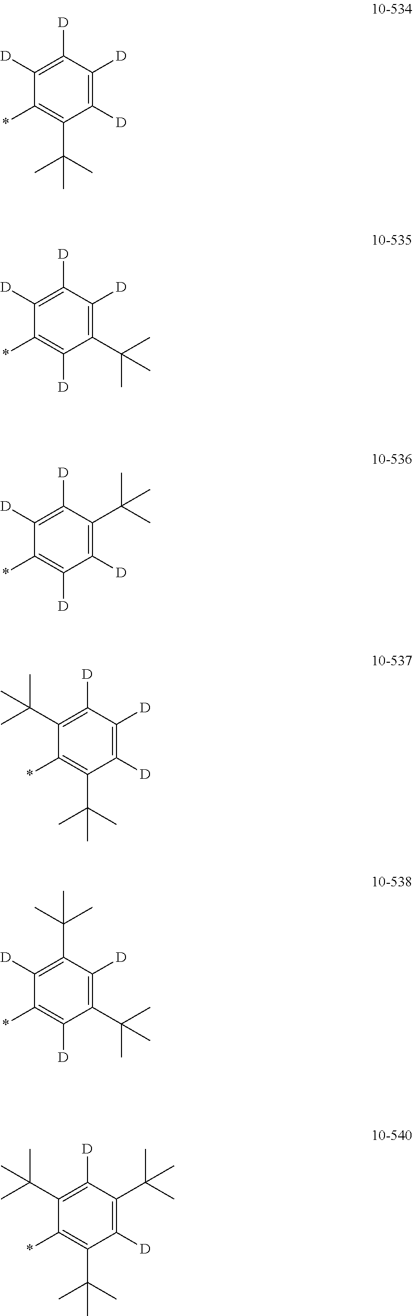

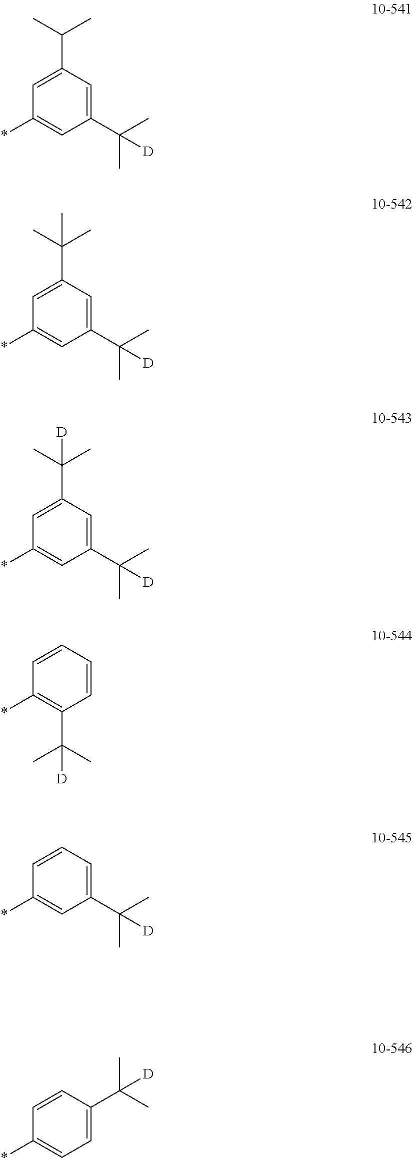 [SMILES: *c1cc(C(C)C)cc(C([2H])(C)C)c1 ; *c1cc(C([2H])(C)C)cc(C(C)(C)C)c1 ; *c1cc(C([2H])(C)C)cc(C([2H])(C)C)c1 ; *c1ccccc1C([2H])(C)C ; *c1cccc(C([2H])(C)C)c1 ; *c1ccc(C([2H])(C)C)cc1]

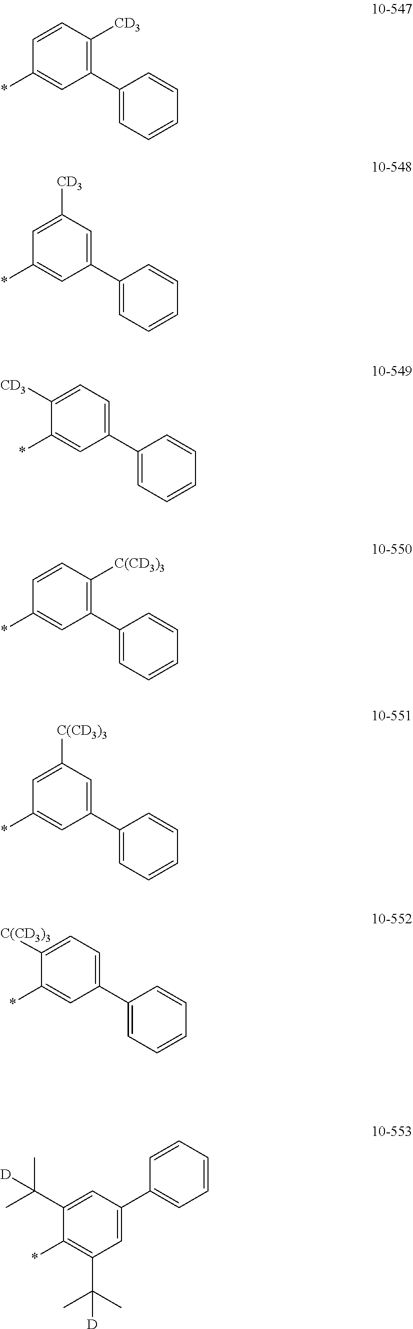

As used herein, the “group represented by one of Formulae 10-1 to 10-132 in which at least one hydrogen is substituted with —F” and the “group represented by one of Formulae 10-201 to 10-353 in which at least one hydrogen is substituted with —F” may be, for example, a group represented by one of Formulae 10-601 to 10-620:

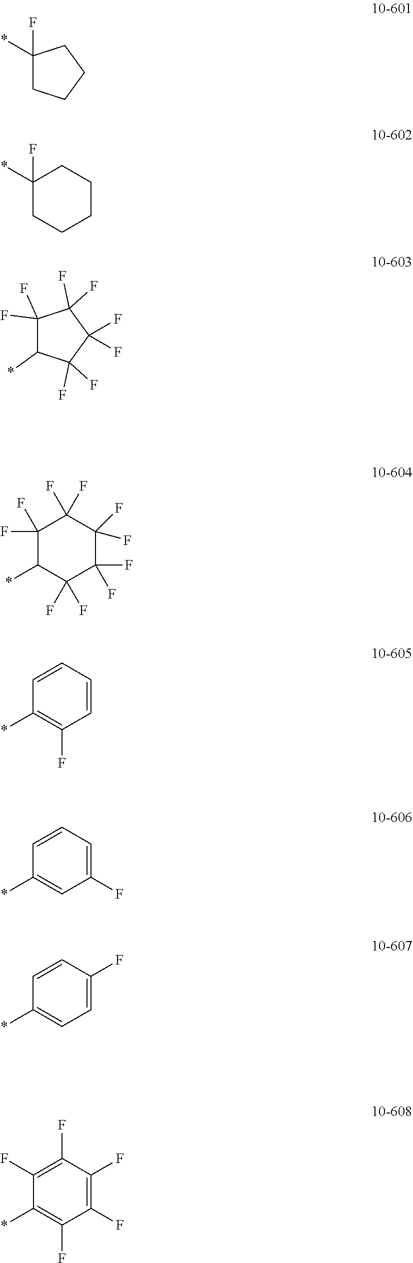

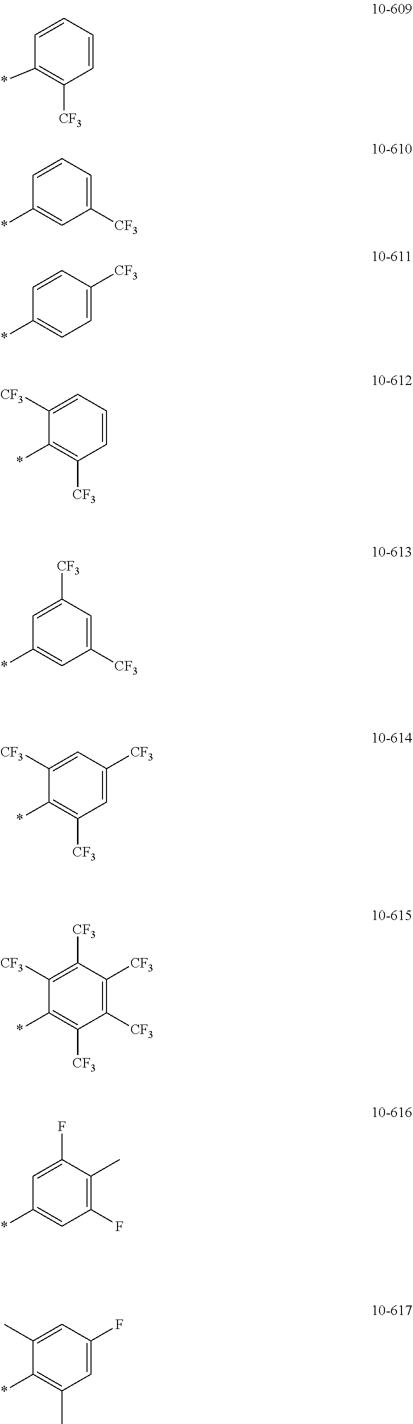

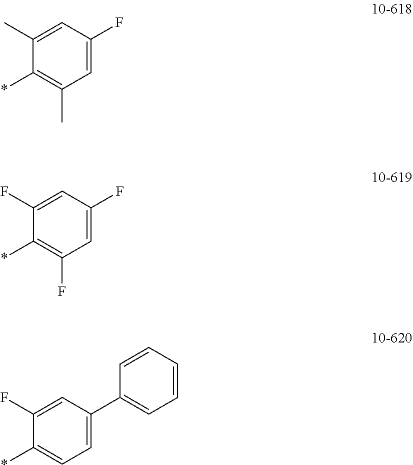

In Formula 1, i) two or more of a plurality of R₁(s) are optionally linked to form a C₅-C₃₀ carbocyclic group unsubstituted or substituted with at least one R₁₀ₐ or a C₁-C₃₀ heterocyclic group unsubstituted or substituted with at least one R₁₀ₐ, ii) two or more of a plurality of R₂(s) are optionally linked to form a C₅-C₃₀ carbocyclic group unsubstituted or substituted with at least one R₁₀ₐ or a C₁-C₃₀ heterocyclic group unsubstituted or substituted with at least one R₁₀ₐ, iii) two or more of a plurality of R₃(s) are optionally linked to form a C₅-C₃₀ carbocyclic group unsubstituted or substituted with at least one R₁₀ₐ or a C₁-C₃₀ heterocyclic group unsubstituted or substituted with at least one R₁₀ₐ, iv) two or more of a plurality of R₄(s) are optionally linked to form a C₅-C₃₀ carbocyclic group unsubstituted or substituted with at least one R₁₀ₐ or a C₁-C₃₀ heterocyclic group unsubstituted or substituted with at least one R₁₀ₐ, v) two or more of R₁ to R₄, R₇ to R₉, R₉ₐ, R_{9b}, R′, and R″ are optionally linked to form a C₅-C₃₀ carbocyclic group unsubstituted or substituted with at least one R₁₀ₐ or a C₁-C₃₀ heterocyclic group unsubstituted or substituted with at least one R₁₀ₐ.

R₁₀ₐ is as defined in connection with R₁.

In one or more embodiments, the group represented by

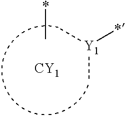

in Formula 1 may be a group represented by one of Formulae CY1-1 to CY1-40:

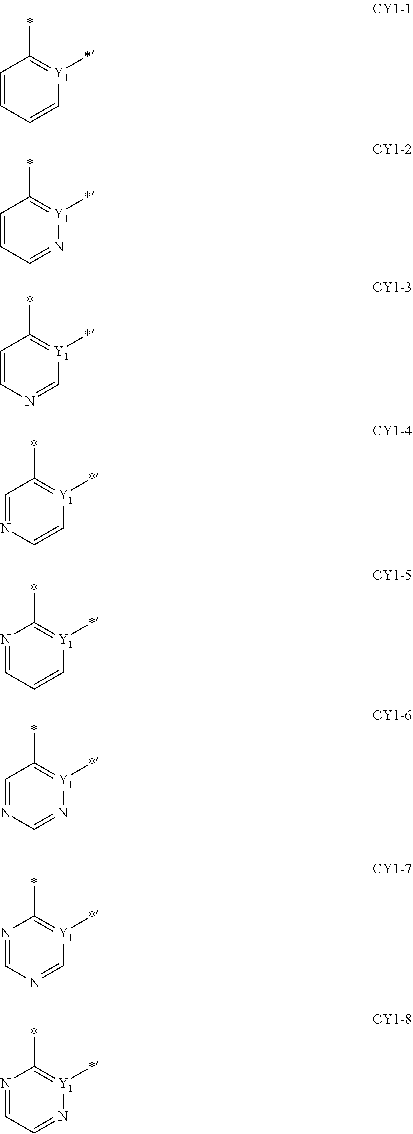

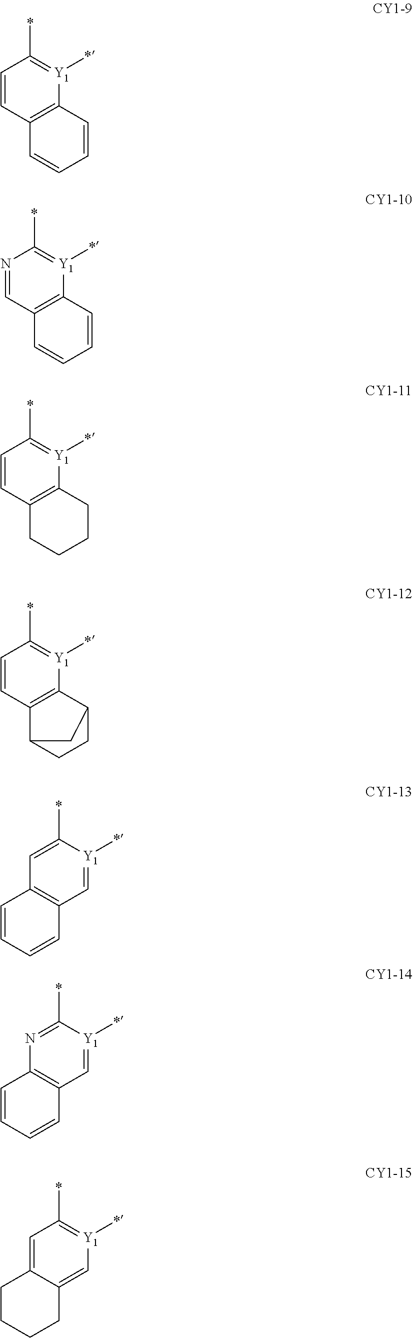

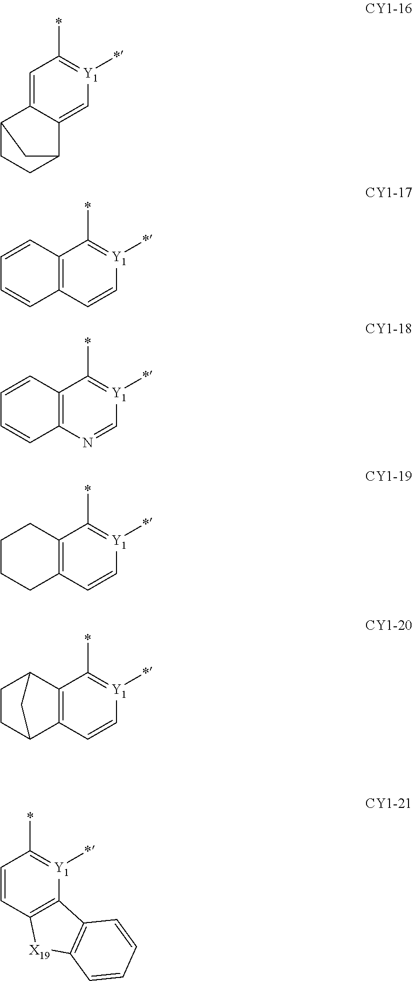

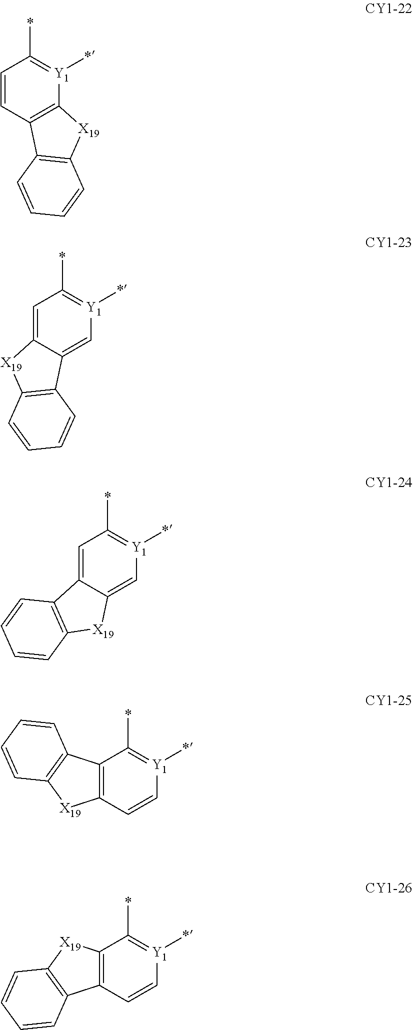

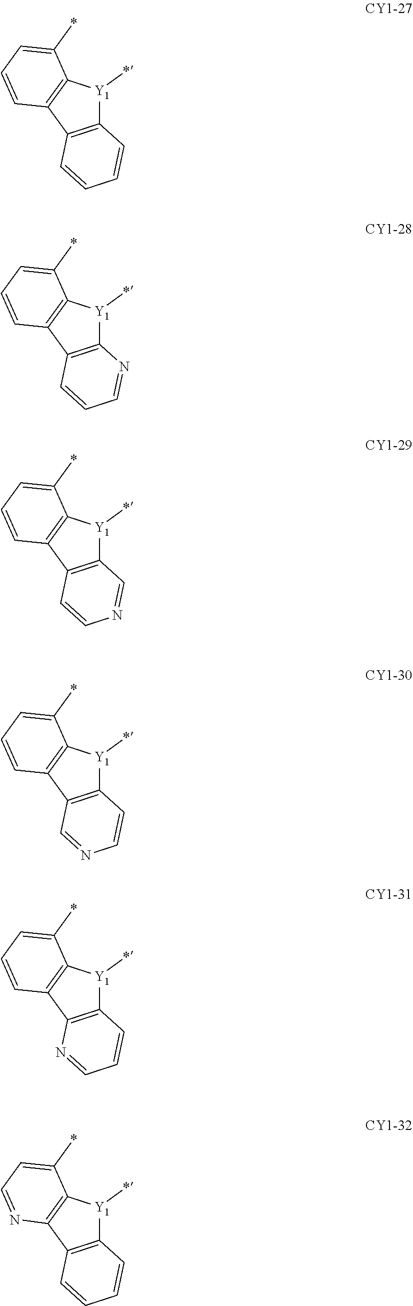

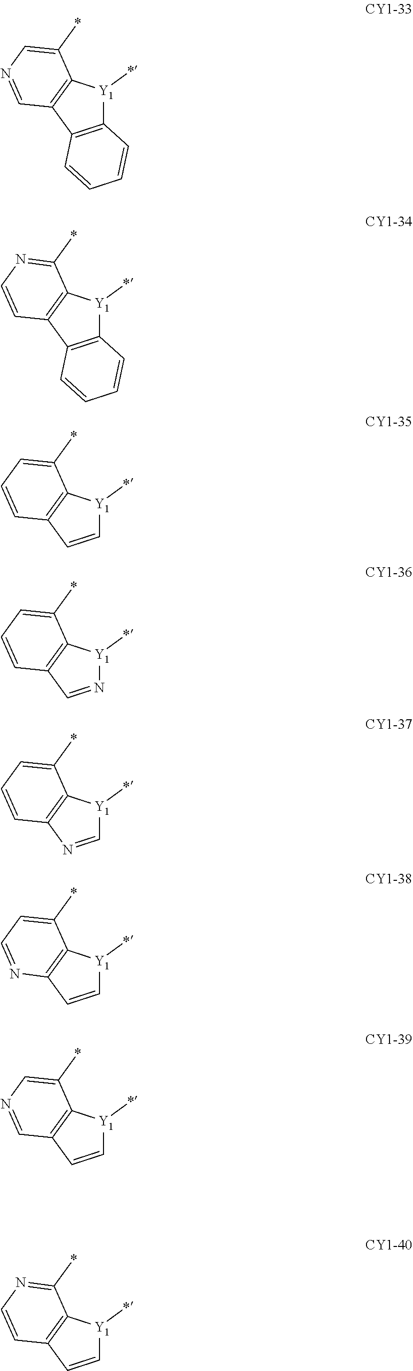

In Formulae CY1-1 to CY1-40,

Y₁ is as defined herein,

X₁₉ is C(R₁₉ₐ)(R_{19b}), N[(L₁₉)_{b19}-(R₁₉)_{c19}], O, S, or Si(R₁₉ₐ)(R_{19b}),

L₁₉ may be as defined in connection with L1;

b19 and c19 are each as defined in connection with b1 and c1,

R₁₉, R₁₉ₐ, and R_{19b} are each as defined in connection with R₁, and

*′ indicates a binding site to X₁ or M in Formula 1, and

* indicates a binding site to ring CY₅ in Formula 1.

In one or more embodiments, the group represented by

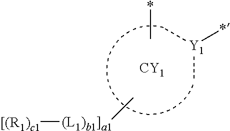

in Formula 1 may be a group represented by one of Formulae CY1(1) to CY1(22):

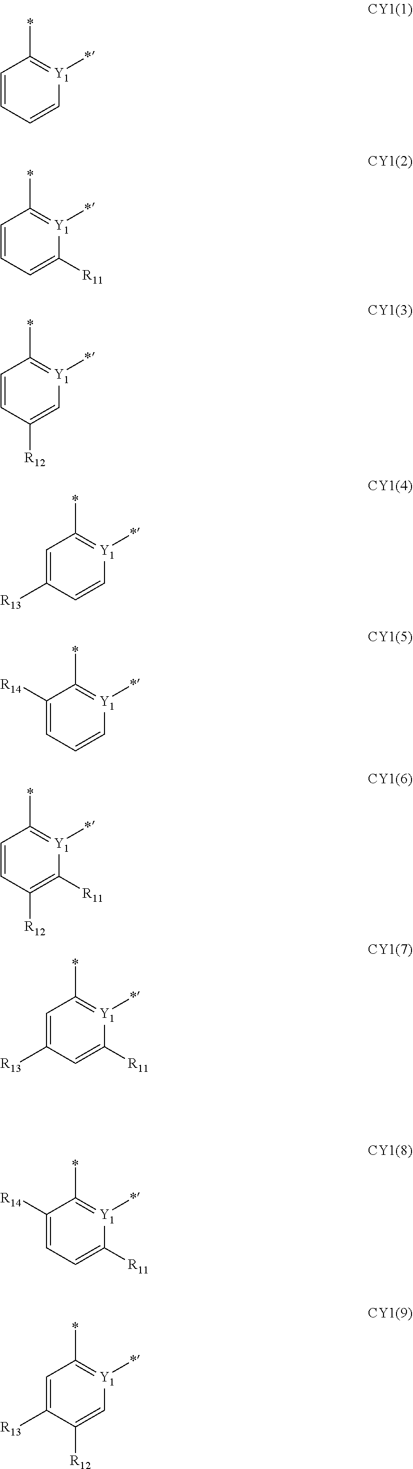

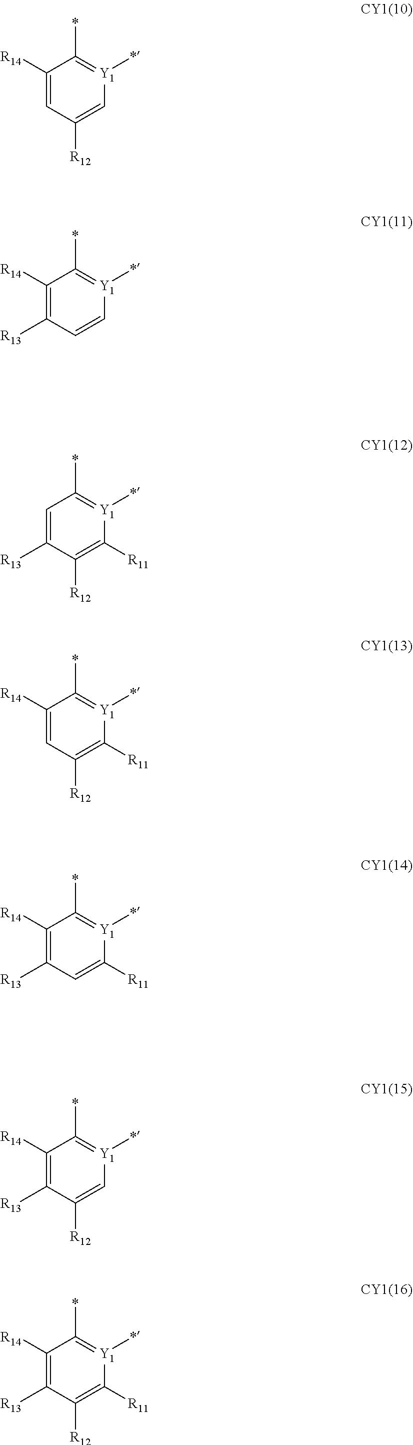

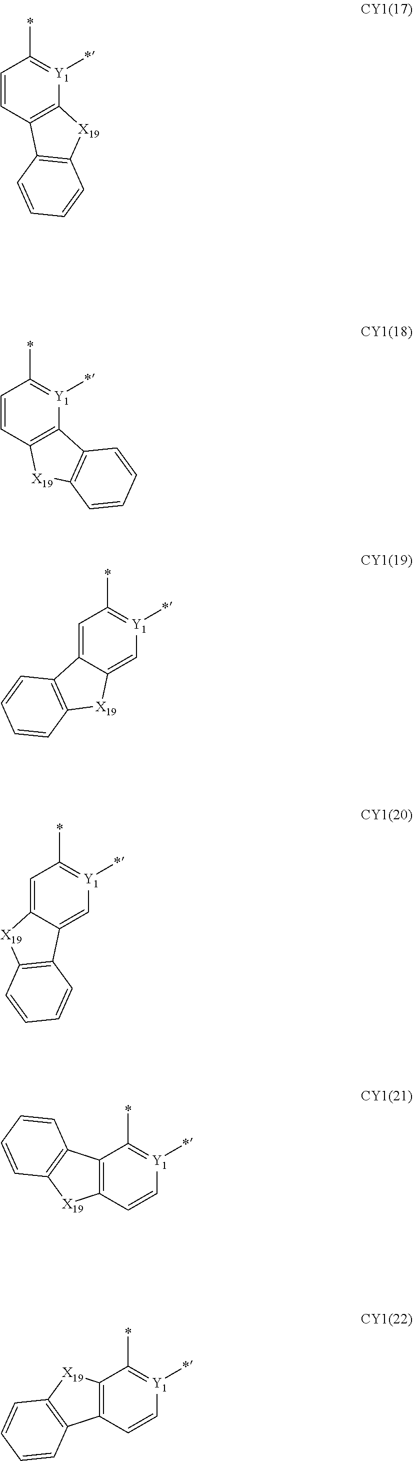

In Formulae CY1(1) to CY1 (22),

Y₁ is as defined herein,

R₁₁ to R₁₄ are each as defined in connection with R₁, provided that each of R₁₁ to R₁₄ is not hydrogen,

X₁₉ may be C(R₁₉ₐ)(R_{19b}), N[(L₁₉)_{b19}-(R₁₉)_{c19}], O, S, or Si(R₁₉ₐ)(R_{19b}),

L₁₉ may be the same as defined in connection with L₁;

b19 and c19 are each as defined in connection with b1 and c1,

R₁₉, R₁₉ₐ, and R_{19b} are each as defined in connection with R₁,

*′ indicates a binding site to X₁ or M in Formula 1, and

* indicates a binding site to ring CY₅ in Formula 1.

For example, R₁₁ to R₁₄ in Formula CY1(1) to CY1(22) may be a substituted or unsubstituted C₄-C₂₀ alkyl group.

In one or more embodiments, the group represented by

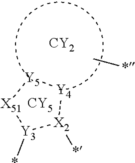

in Formula 1 may be a group represented by one of Formulae CY2-1 to CY2-20:

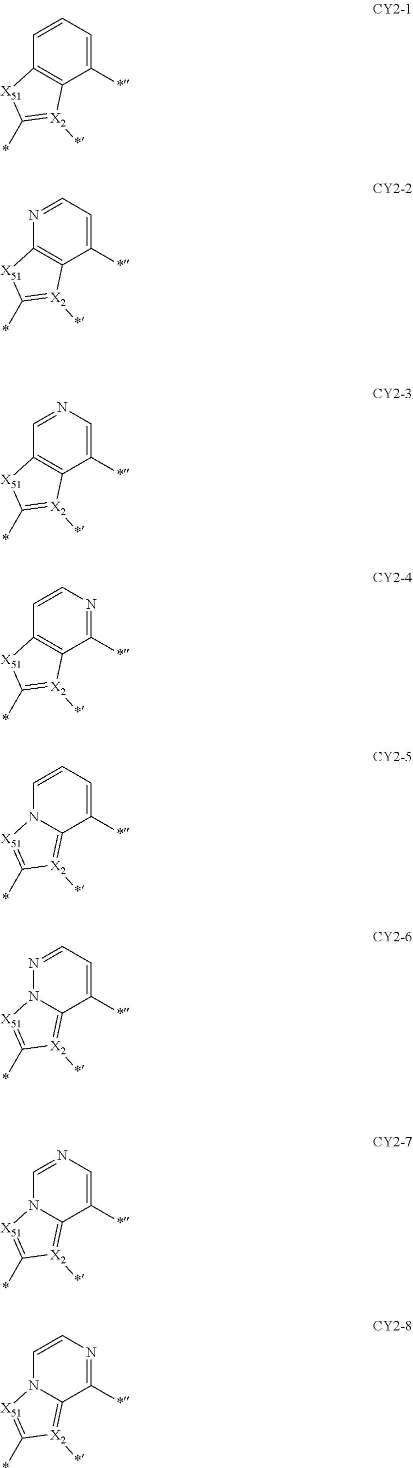

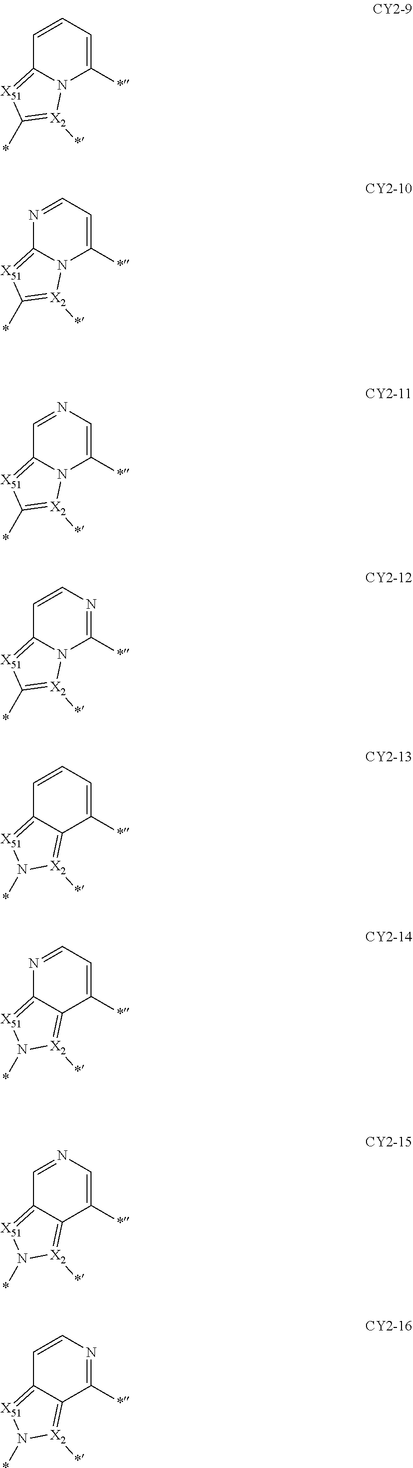

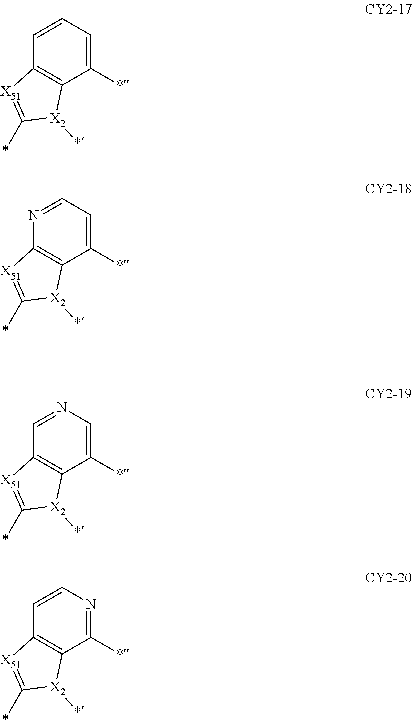

wherein, in Formulae CY2-1 to CY2-20,

X₂ and X₅₁ are each as defined herein,

* indicates a binding site to ring CY1 in Formula 1,

*′ indicates a binding site to M in Formula 1, and

*″ indicates a binding site to T₁ in Formula 1.

In one or more embodiments, the group represented by

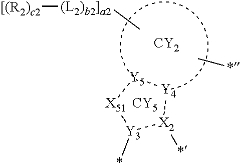

in Formula 1 may be a group represented by one of Formulae CY2(1) to CY2(20):

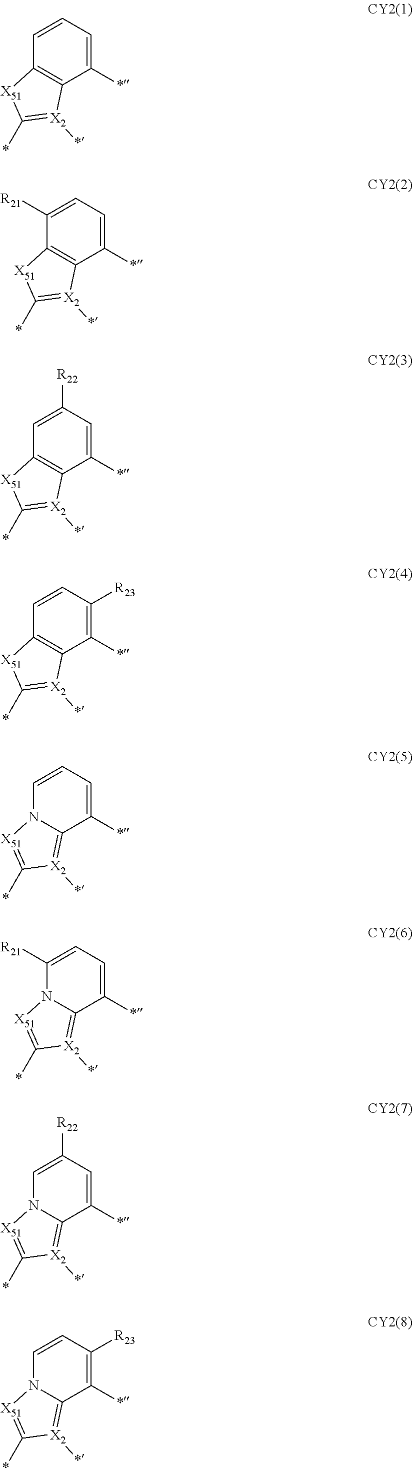

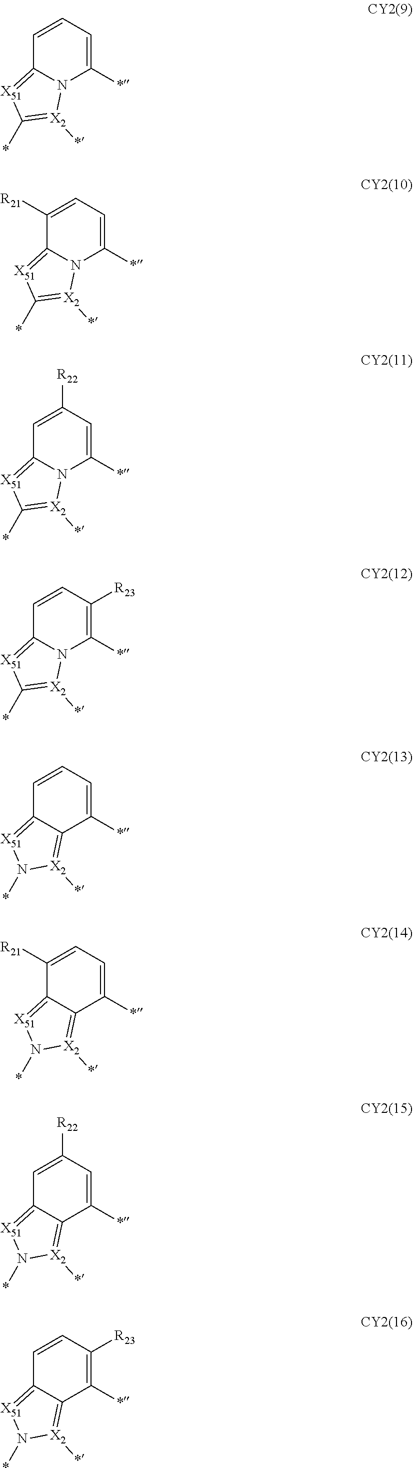

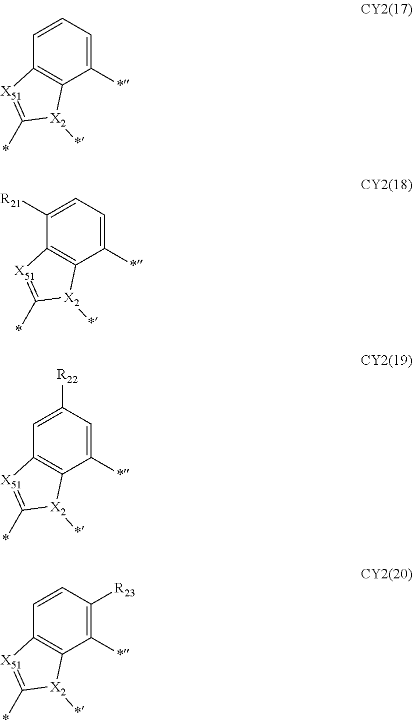

In Formulae CY2(1) to CY2(20),

X₂ and X₅₁ are each as defined herein,

R₂₁ to R₂₃ are each as defined in connection with R₂, provided that each of R₂₁ to R₂₃ may not be hydrogen,

* indicates a binding site to ring CY₁ in Formula 1,

*′ indicates a binding site to M in Formula 1, and

*″ indicates a binding site to T₁ in Formula 1.

In one or more embodiments,

the group represented by

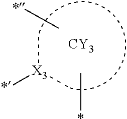

in Formula 1 may be a group represented by one of Formulae CY3-1 to CY3-14, and

the group represented by

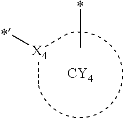

in Formula 1 may be a group represented by one of Formulae CY4-1 to CY4-26.

In one or more embodiments,

the group represented by

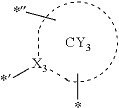

in Formula 1 may be a group represented by one of Formulae CY3-1 to CY3-14, or

the group represented by

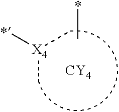

in Formula 1 may be a group represented by one of Formulae CY4-1 to CY4-26.

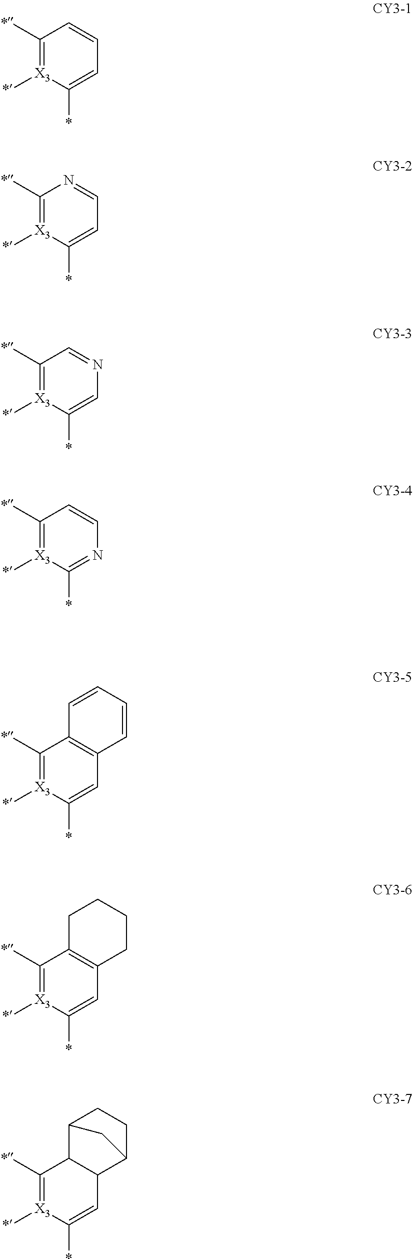

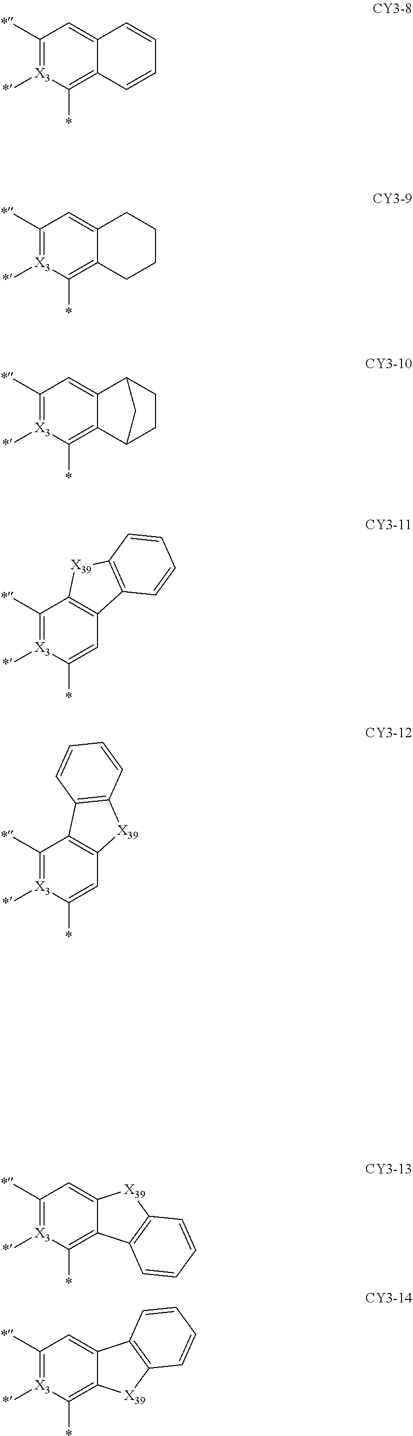

In Formulae CY3-1 to 3-14,

X₃ is as defined herein,

X₃₉ may be C(R₃₉ₐ)(R_{39b}), N[(L₃₉)_{b39}-(R₃₉)_{c39}], O, S, or Si(R₃₉ₐ)(R_{39b}),

L₃₉ is as defined in connection with L₃,

b39 and c39 are each as defined in connection with b3 and c3,

R₃₉, R₃₉ₐ, and R_{39b} are each as defined in connection with R₃,

* indicates a binding site to T₂ in Formula 1,

*′ indicates a binding site to M in Formula 1,

*″ indicates a binding site to T₁ in Formula 1.

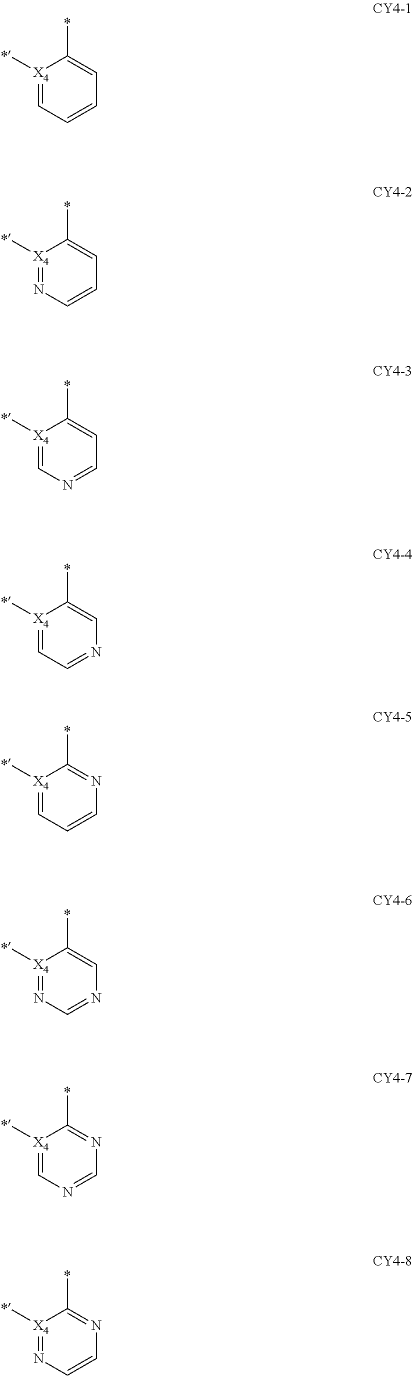

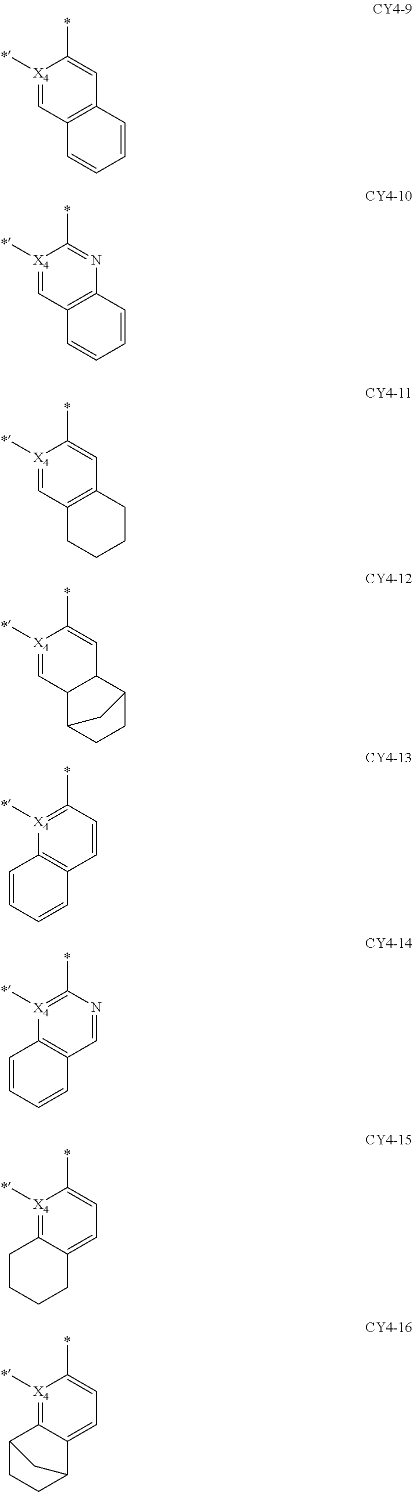

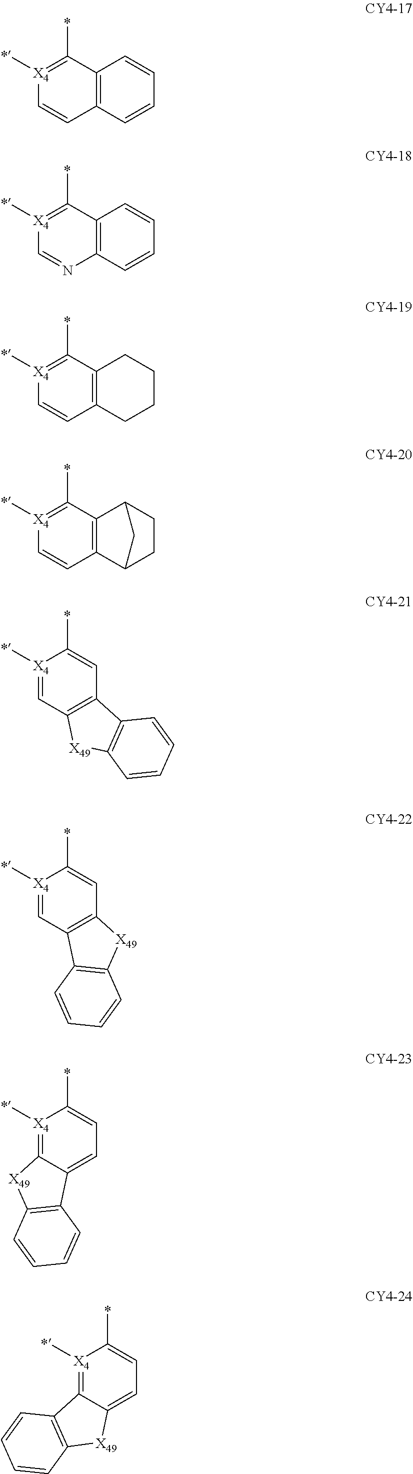

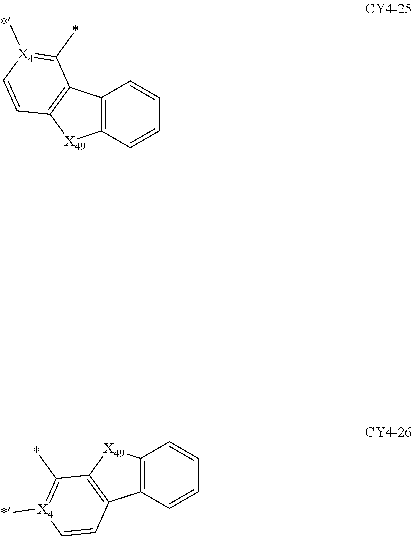

In Formulae CY4-1 to 4-26,

X₄ is as defined herein,

X₄₉ may be C(R₄₉ₐ)(R_{49b}), N[(L₄₉)_{b49}-(R₄₉)_{c49}], O, S, or Si(R₄₉ₐ)(R_{49b}),

L₄₉ is as defined in connection with L₄,

b49 and c49 are each as defined in connection with b4 and c4,

R₄₉, R₄₉ₐ, and R_{49b} are each as defined in connection with R₄,

* indicates a binding site to T₂ in Formula 1, and

*′ indicates a binding site to M in Formula 1.

In one or more embodiments,

the group represented by

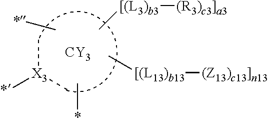

in Formula 1 may be a group represented by one of Formulae CY3(1) to CY3(12) or CY3(1)F to CY3(12)F, and

the group represented by

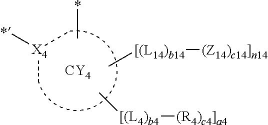

in Formula 1 may be a group represented by one of Formulae CY4(1) to CY4(16) or CY4(1)F to CY4(32)F.

In one or more embodiments,

the group represented by

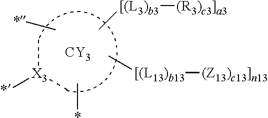

in Formula 1 may be a group represented by one of Formulae CY3(1) to CY3(12) or CY3(1)F to CY3(12)F, or

the group represented by

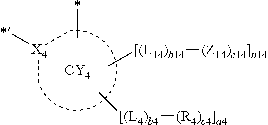

in Formula 1 may be a group represented by one of Formulae CY4(1) to CY4(16) or CY4(1)F to CY4(32)F.

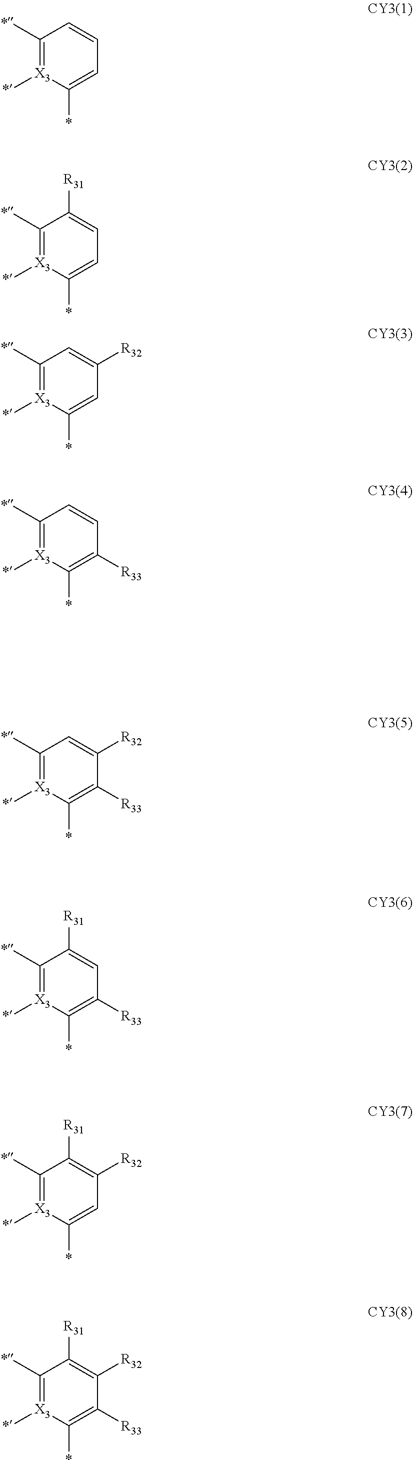

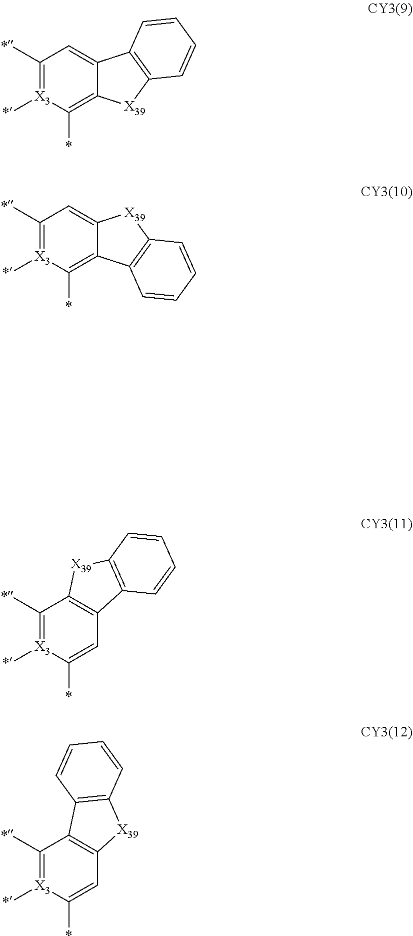

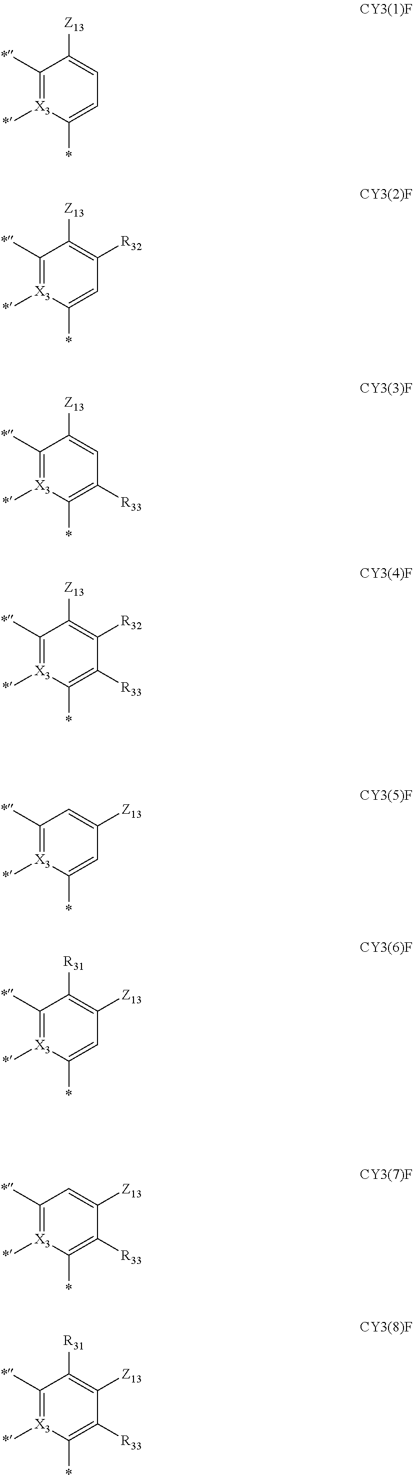

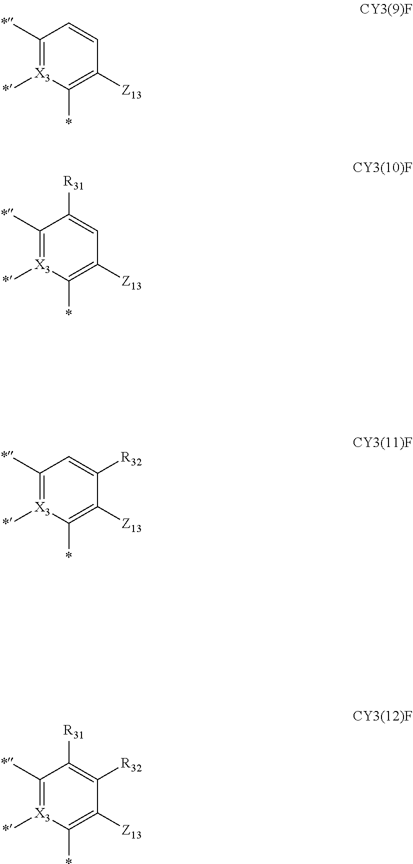

In Formulae CY3(1) to CY3(12) and CY3(1)F to CY3(12)F,

X₃ and Z₁₃ are each as defined herein,

R₃₁ to R₃₃ are each as defined in connection with R₃, provided that each of R₃₁ to R₃₃ may not be hydrogen,

X₃₉ may be C(R₃₉ₐ)(R_{39b}), N[(L₃₉)_{b39}-(R₃₉)_{c39}], O, S, or Si(R₃₉ₐ)(R_{39b}),

L₃₉ is as defined in connection with L₃,

b39 and c39 are each as defined in connection with b3 and c3,

R₃₉, R₃₉ₐ, and R_{39b} are each as defined in connection with R₃,

* indicates a binding site to T₂ in Formula 1,

*′ indicates a binding site to M in Formula 1, and

*″ indicates a binding site to T₁ in Formula 1.

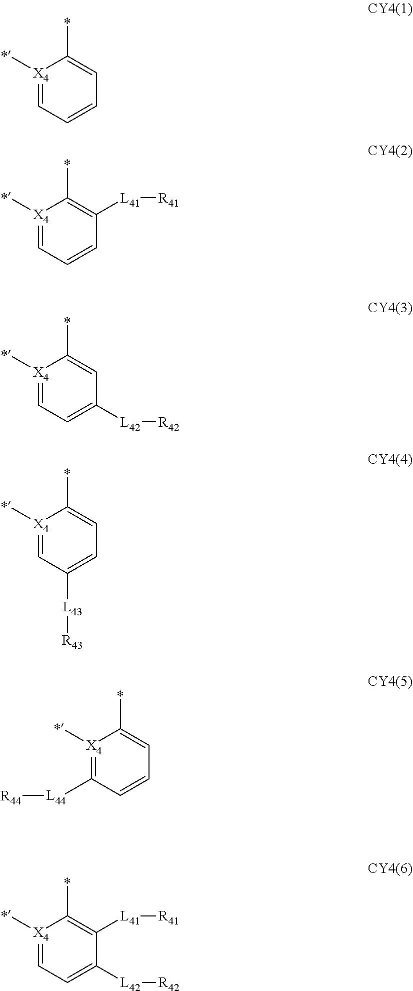

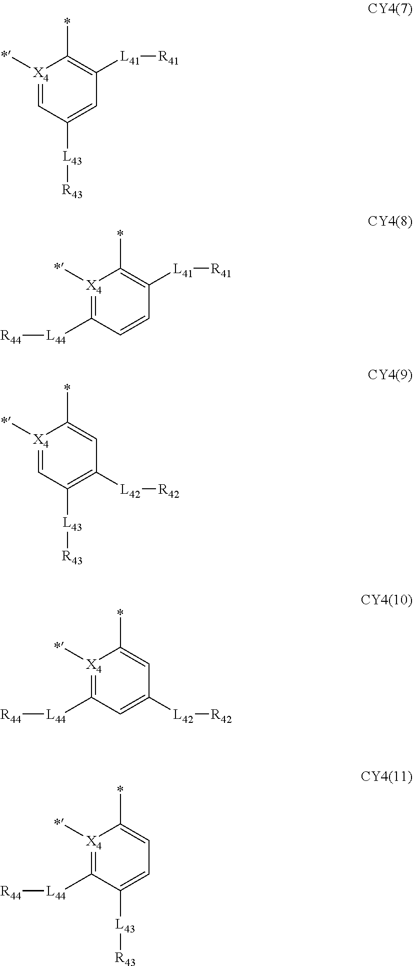

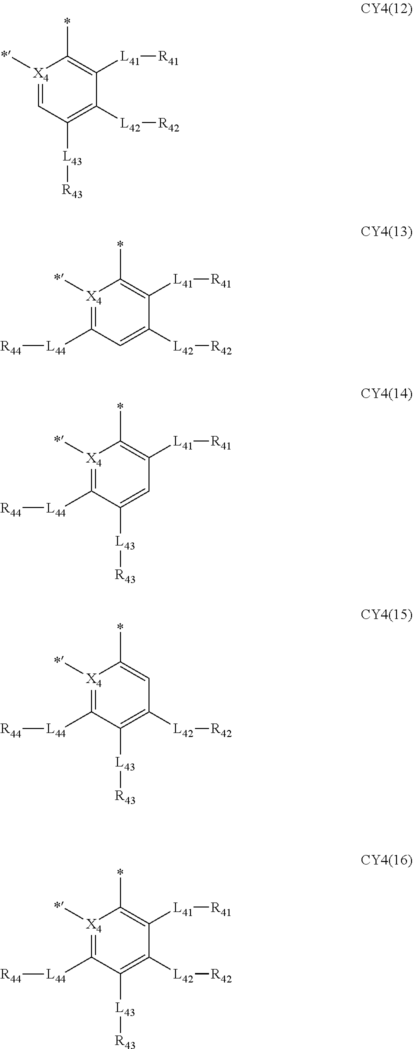

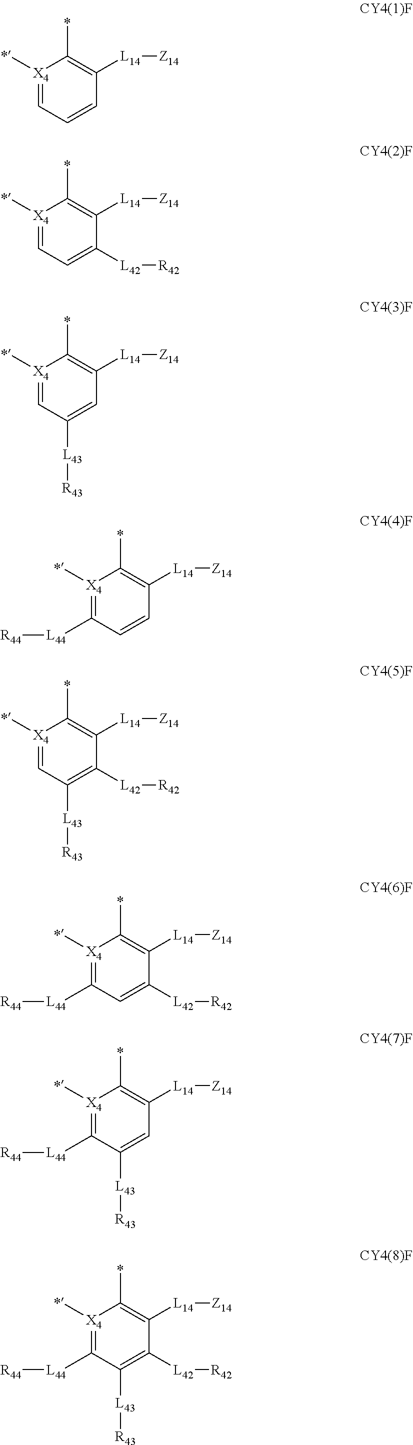

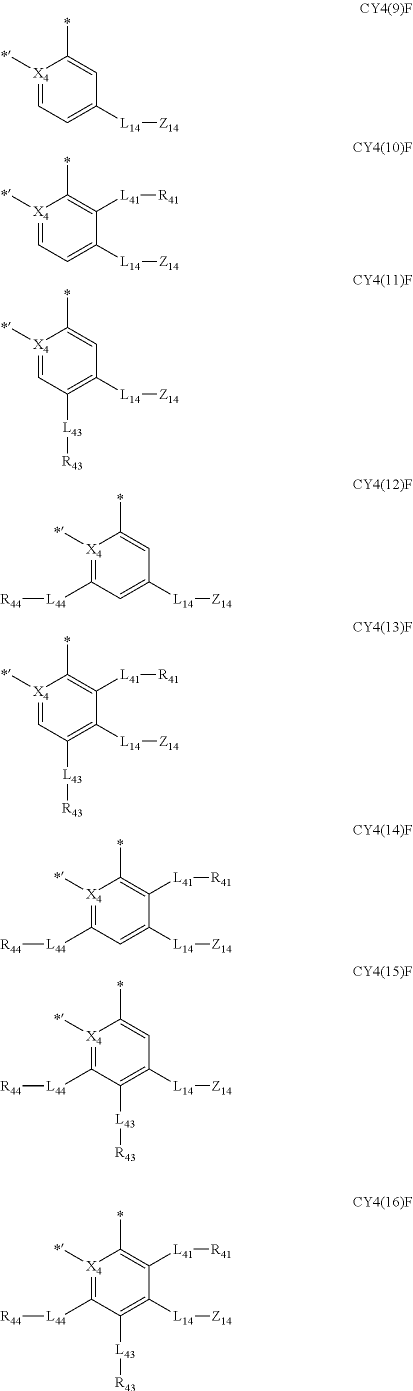

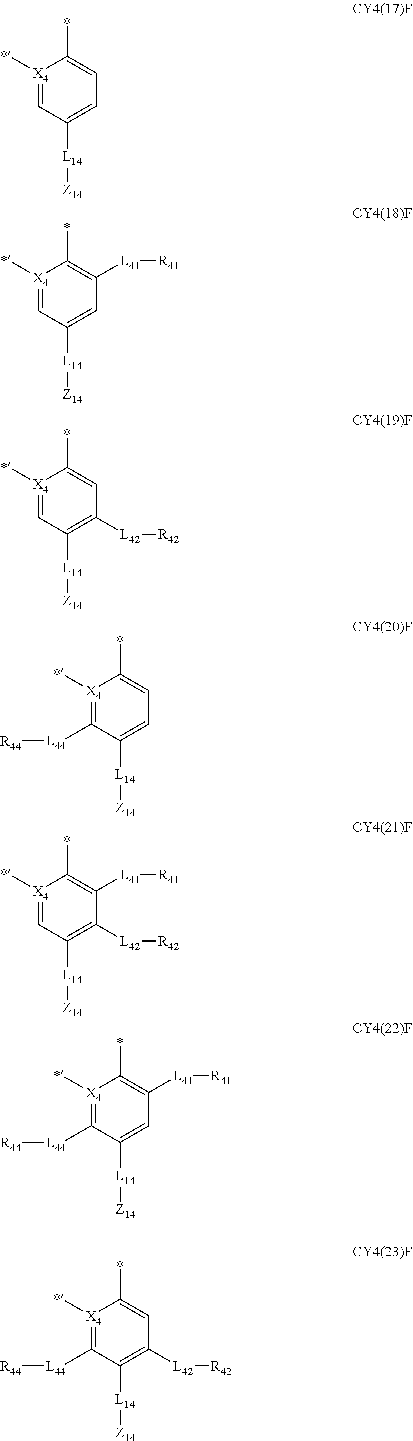

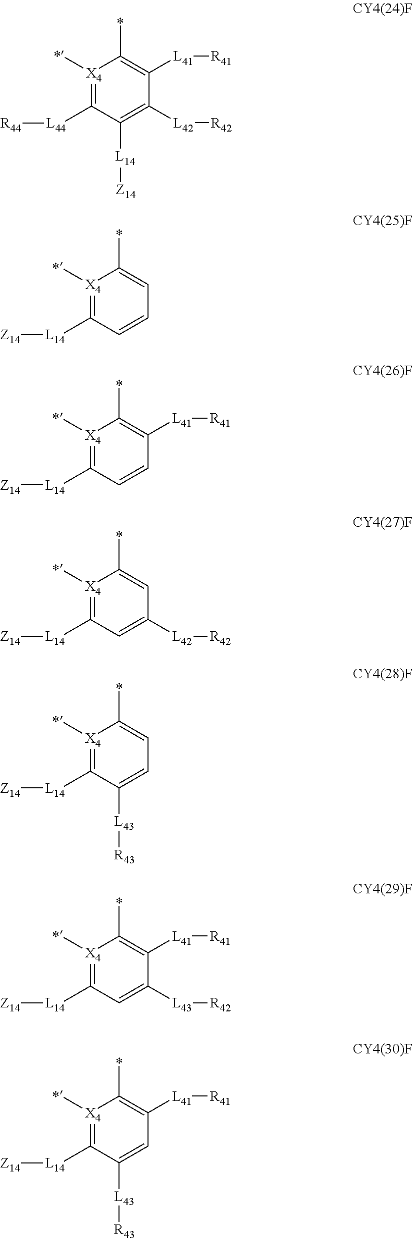

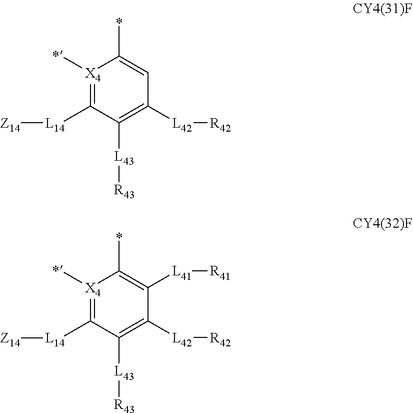

In Formulae CY4(1) to CY4(16) and CY4(1)F to CY4(32)F,

X₄, L₁₄, and Z₁₄ are each as defined herein,

L₄₁ to L₄₄ are each as defined in connection with L₄,

R₄₁ to R₄₄ are each as defined in connection with R₄, provided that each of R₄₁ to R₄₄ may not be hydrogen,

* indicates a binding site to T₂ in Formula 1, and

*′ indicates a binding site to M in Formula 1.

In one or more embodiments, the organometallic compound represented by Formula 1 may satisfy at least one of Condition 3-1 and Condition 4-1:

Condition 3-1

the group represented by

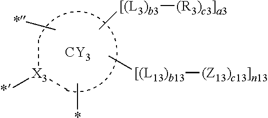

in Formula 1 is a group represented by one of Formulae CY3(1)F to CY3(12)F

Condition 4-1

the group represented by

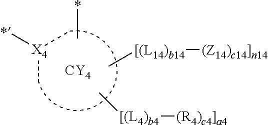

in Formula 1 is a group represented by one of Formulae CY4(1)F to CY4(32)F

The organometallic compound represented by Formula 1 may be represented by Formula 1A:

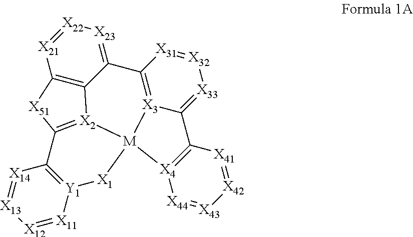

In Formula 1A,

M, X₁ to X₄, Y₁, and X₅₁ are each as defined herein,

X₁₁ may be C(R₁₁) or N, X₁₂ may be C(R₁₂) or N, X₁₃ may be C(R₁₃) or N, X₁₄ may be C(R₁₄) or N, R₁₁ to R₁₄ are each as defined in connection with R₁,

X₂₁ may be C(R₂₁) or N, X₂₂ may be C(R₂₂) or N, X₂₃ may be C(R₂₃) or N, R₂₁ to R₂₃ are each as defined in connection with R₂,

X₃₁ may be C(R₃₁), C(Z₁₃) or N, X₃₂ may be C(R₃₂), C(Z₁₃), or N, X₃₃ may be C(R₃₃), C(Z₁₃) or N, R₃₁ to R₃₃ are each as defined in connection with R₃, Z₁₃ is as defined herein,

X₄₁ may be C-[(L₄₁)-(R₄₁)], C-[(L₁₄)-(Z₁₄)], or N, X₄₂ may be C-[(L₄₂)-(R₄₂)], C-[(L₁₄)-(Z₁₄)], or N, X₄₃ may be C-[(L₄₃)-(R₄₃)], C-[(L₁₄)-(Z₁₄)], or N, X₄₄ may be C-[(L₄₄)-(R₄₄)], C-[(L₁₄)-(Z₁₄)], or N, L₄₁ to L₄₄ are each as defined in connection with L₄, R₄₁ to R₄₄ are each as defined in connection with R₄, and L₁₄ and Z₁₄ are each as defined herein,

two or more of R₁₁ to R₁₄ may optionally be linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more of R₂₁ to R₂₃ may optionally be linked to form a C₅-C₃₀ carbocyclic group unsubstituted or substituted with at least one R₁₀ₐ, or a C₁-C₃₀ heterocyclic group unsubstituted or substituted with at least one R₁₀ₐ,

two or more of R₃₁ to R₃₃ may optionally be linked to form a C₅-C₃₀ carbocyclic group unsubstituted or substituted with at least one R₁₀ₐ, or a C₁-C₃₀ heterocyclic group unsubstituted or substituted with at least one R₁₀ₐ, and

two or more of R₄₁ to R₄₄ may optionally be linked to form a C₅-C₃₀ carbocyclic group unsubstituted or substituted with at least one R₁₀ₐ, or a C₁-C₃₀ heterocyclic group unsubstituted or substituted with at least one R₁₀ₐ.

R₁₀ₐ may be as defined in connection with R₁.

The organometallic compound represented by Formula 1A may satisfy at least one of Condition (1) to Condition (7):

Condition (1)

X₃₁ is C(Z₁₃)

Condition (2)

X₃₂ is C(Z₁₃)

Condition (3)

X₃₃ is C(Z₁₃)

Condition (4)

X₄₁ is C-[(L₁₄)-(Z₁₄)]

Condition (5)

X₄₂ is C-[(L₁₄)-(Z₁₄)]

Condition (6)

X₄₃ is C-[(L₁₄)-(Z₁₄)]

Condition (7)

X₄₄ is C-[(L₁₄)-(Z₁₄)]

In one or more embodiments, X₅₁ in Formula 1A may be O, S, N-[(L₇)_{b7}-(R₇)_{c7}], C(R₇)(R₈), Si(R₇)(R₈), Ge(R₇)(R₈), or C(═O).

In one or more embodiments, X₅₁ in Formula 1A may be N-[(L₇)_{b7}-(R₇)_{c7}].

In one or more embodiments, in Formula 1A, X₅₁ may be N-[(L₇)_{b7}-(R₇)_{c7}], L₇ may not be a single bond, c7 may be greater than or equal to 2, one of two or more R₇(s) may be a substituted or unsubstituted C₄-C₂₀ alkyl group (for example, a tert-butyl group, etc.), one of the remaining R₇ may be a substituted or unsubstituted phenyl group (for example, a phenyl group, a deuterated phenyl group, a (C₁-C₂₀ alkyl) phenyl group, etc.) or a substituted or unsubstituted biphenyl group (for example, a biphenyl group, a deuterated biphenyl group, or a (C₁-C₂₀ alkyl) biphenyl group, etc.)

In one or more embodiments, in Formula 1A, X₁₁ may be C(R₁₁), X₁₃ may be C(R₁₃), and R₁₁ and R₁₃ may each independently be a substituted or unsubstituted C₄-C₂₀alkyl group.

In one or more embodiments, the organometallic compound represented by Formula 1A may satisfy at least one of Condition (1) to Condition (3).

In one or more embodiments, the organometallic compound represented by Formula 1A may satisfy at least one of Condition (4) to Condition (7).

The additional description regarding Formula 1A is the same as the description in connection with Formula 1.

In one or more embodiments, the group represented by

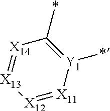

in Formula 1A may be a group represented by one of Formulae CY1(1) to CY1(22).

In one or more embodiments, the group represented by

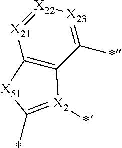

in Formula 1A may be a group represented by one of Formulae CY2(1) to CY2(20).

In one or more embodiments, the group represented by

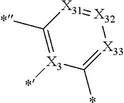

in Formula 1A may be a group represented by one of Formulae CY3(1) to CY3(12) or CY3(1)F to CY3(12)F.

In one or more embodiments, the group represented by

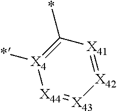

in Formula 1A may be a group represented by one of Formulae CY4(1) to CY4(16) or CY4(1)F to CY4(32)F.

In one or more embodiments, Formulae 1 and 1A may each include at least one deuterium.

In one or more embodiments, each of L1, L₂, R₁, R₂, and X₅₁ in Formula 1 may not include a fluoro group (—F).

In one or more embodiments, each of R₁₁ to R₁₄, R₂₁ to R₂₃, and X₅₁ in Formula 1A may not include a fluoro group (—F).

In one or more embodiments, the organometallic compound may be one of Compounds 1 to 3:

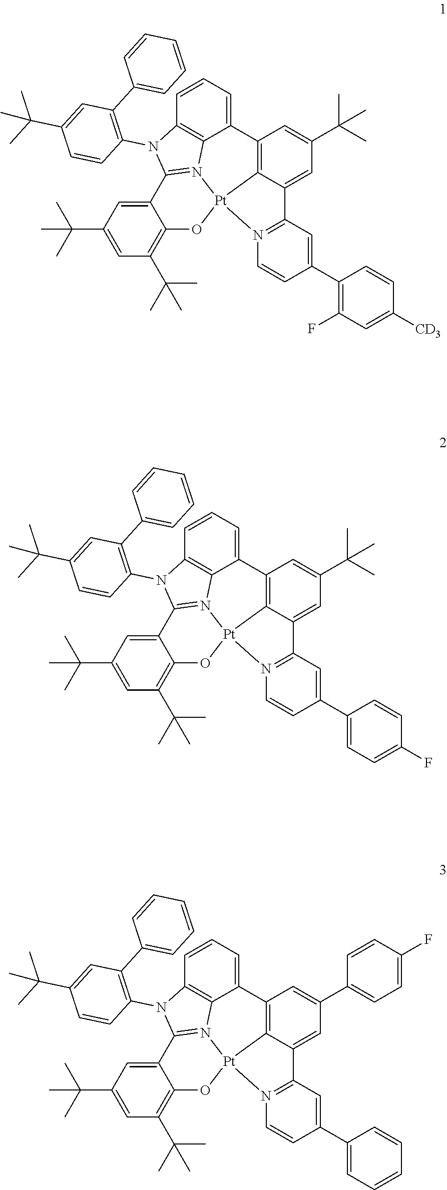

In Formula 1, Z₁₃ and Z₁₄ may each independently be a group represented by Formula 2, n13 and n14 may each independently be an integer from 0 to 20, and the sum of n13 and n14 may be 1 or greater. Thus, at least one of ring CY₃ and ring CY₄ in the organometallic compounds represented by Formula 1 may include a group represented by Formula 2. Furthermore, a group represented by Formula 2 may include ring CY₁₀ as defined in the present specification. Accordingly, as the organometallic compound represented by Formula 1 may maintain excellent electric characteristics and have a low Ts temperature or a low sublimation temperature at the same time, the electronic device, for example, an organic light-emitting device, using the organometallic compound may have excellent emission efficiency and lifespan characteristics at the same time.

Furthermore, each of ring CY₁, ring CY₃, and ring CY₄ in Formula 1 may not be a benzimidazole group. Accordingly, since the steric hindrance of a ligand surrounding the center metal M is improved, an electronic device, for example, an organic light-emitting device, including the organometallic compound may have an improved lifespan characteristic and a sharp electroluminescence peak.

For example, the highest occupied molecular orbital (HOMO) energy level, the lowest unoccupied molecular orbital (LUMO) energy level, the energy gap (eV), the lowest excitation singlet (S₁) energy level, and the lowest excited state triplet (T₁) energy level of Compounds 1 to 3 were calculated using a density functional theory (DFT) method of the Gaussian 09 program (structurally optimized at a level of B3LYP, 6-31G(d,p)). Evaluation results are shown in Table 1 below.

TABLE 1

| Compound | HOMO | LUMO | Energy | S₁ energy | T₁ energy |
|---|---|---|---|---|---|
| No. | (eV) | (eV) | gap (eV) | level (eV) | level (eV) |
| 1 | −4.602 | −1.688 | 2.914 | 2.444 | 2.293 |
| 2 | −4.656 | −1.734 | 2.921 | 2.443 | 2.302 |
| 3 | −4.746 | −1.791 | 2.954 | 2.474 | 2.326 |

From Table 1, it is confirmed that the organometallic compound represented by Formula 1 has such electric characteristics that are suitable for use as a dopant for an electronic device, for example, an organic light-emitting device.

Synthesis methods of the organometallic compound represented by Formula 1 may be recognizable by one of ordinary skill in the art by referring to Synthesis Examples provided below.

Accordingly, the organometallic compound represented by Formula 1 is suitable for use as a material for an organic layer of organic light-emitting device, for example, a dopant in an emission layer of the organic layer. Thus, another aspect provides an organic light-emitting device including: a first electrode; a second electrode; and an organic layer between the first electrode and the second electrode and including an emission layer, and the organic layer includes at least one organometallic compound represented by Formula 1.

The organic light-emitting device may have, due to the inclusion of an organic layer including the organometallic compound represented by Formula 1, a low driving voltage, a high external quantum efficiency, a low roll-off ratio, and long lifespan.

The organometallic compound of Formula 1 may be used between a pair of electrodes of an organic light-emitting device. For example, the organometallic compound represented by Formula 1 may be included in the emission layer. In this regard, the organometallic compound may act as a dopant, and the emission layer may further include a host (that is, an amount of the organometallic compound represented by Formula 1 is smaller than an amount of the host). The emission layer may emit, for example, green light or blue light.

As used herein, the expression “(an organic layer) includes at least one of organometallic compounds” used herein may include a case in which “(an organic layer) includes identical organometallic compounds represented by Formula 1” and a case in which “(an organic layer) includes two or more different organometallic compounds represented by Formula 1”.

For example, the organic layer may include, as the organometallic compound, only Compound 1. In this embodiment, Compound 1 may be included in the emission layer of the organic light-emitting device. In one or more embodiments, the organic layer may include, as the organometallic compound, Compound 1 and Compound 2. In this regard, Compound 1 and Compound 2 may be in an identical layer (for example, Compound 1 and Compound 2 both may be in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one or more embodiments, in the organic light-emitting device, the first electrode is an anode, and the second electrode is a cathode, and the organic layer may further include a hole transport region located between the first electrode and the emission layer and an electron transport region located between the emission layer and the second electrode, and the hole transport region may include a hole injection layer, a hole transport layer, an electron blocking layer, a buffer layer, or a combination thereof, and the electron transport region may include a hole blocking layer, an electron transport layer, an electron injection layer, or a combination thereof.

The term “organic layer” as used herein refers to a single layer and/or a plurality of layers between the first electrode and the second electrode of the organic light-emitting device. The “organic layer” may include, in addition to an organic compound, an organometallic complex including a metal.

The FIGURE is a schematic cross-sectional view of an organic light-emitting device 10 according to one or more embodiments. Hereinafter, the structure of an organic light-emitting device according to one or more embodiments and a method of manufacturing an organic light-emitting device according to one or more embodiments of the present disclosure will be described in connection with the FIGURE. The organic light-emitting device 10 includes a first electrode 11, an organic layer 15, and a second electrode 19, which are sequentially stacked.

A substrate may be additionally located under the first electrode 11 or above the second electrode 19. For use as the substrate, any substrate that is used in organic light-emitting devices available in the art may be used, and the substrate may be a glass substrate or a transparent plastic substrate, each having excellent mechanical strength, thermal stability, transparency, surface smoothness, ease of handling, and water resistance.

In one or more embodiments, the first electrode 11 may be formed by depositing or sputtering a material for forming the first electrode 11 on the substrate. The first electrode 11 may be an anode. The material for forming the first electrode 11 may include materials with a high work function to facilitate hole injection. The first electrode 11 may be a reflective electrode, a semi-transmissive electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be metal, such as magnesium (Mg), silver (Ag), aluminum (Al), aluminum-lithium (Al—Li), calcium (Ca), magnesium-indium (Mg—In), or magnesium-silver (Mg—Ag).

The first electrode 11 may have a single-layered structure or a multi-layered structure including two or more layers. For example, the first electrode 11 may have a three-layered structure of ITO/Ag/ITO.

The organic layer 15 is located on the first electrode 11.

The organic layer 15 may include a hole transport region, an emission layer, and an electron transport region.

The hole transport region may be located between the first electrode 11 and the emission layer.

The hole transport region may include a hole injection layer, a hole transport layer, an electron blocking layer, a buffer layer, or a combination thereof.

The hole transport region may include only either a hole injection layer or a hole transport layer. In one or more embodiments, the hole transport region may have a hole injection layer/hole transport layer structure or a hole injection layer/hole transport layer/electron blocking layer structure, wherein, for each structure, each layer is sequentially stacked in this stated order from the first electrode 11.

When the hole transport region includes a hole injection layer, the hole injection layer may be formed on the first electrode 11 by using one or more suitable methods, for example, vacuum deposition, spin coating, casting, and/or Langmuir-Blodgett (LB) deposition.

When a hole injection layer is formed by vacuum deposition, the deposition conditions may vary depending on a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C.

The conditions for forming the hole transport layer and the electron-blocking layer may be the same as the conditions for forming the hole injection layer.

The hole transport region may include 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(naphthalene-1-yl)-N,N′-diphenyl-benzidine (NPB), β-NPB, N,N′-bis(3-methylphenyl)-N,N′-diphenyl-[1,1-biphenyl]-4,4′-diamine (TPD), spiro-TPD, spiro-NPB, methylated NPB, 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201 below, a compound represented by Formula 202 below, or a combination thereof:

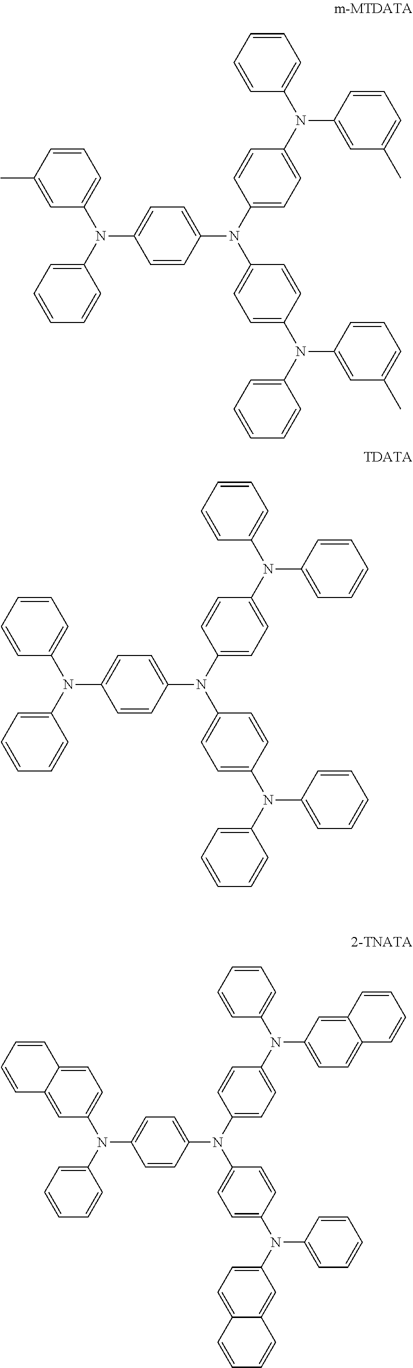

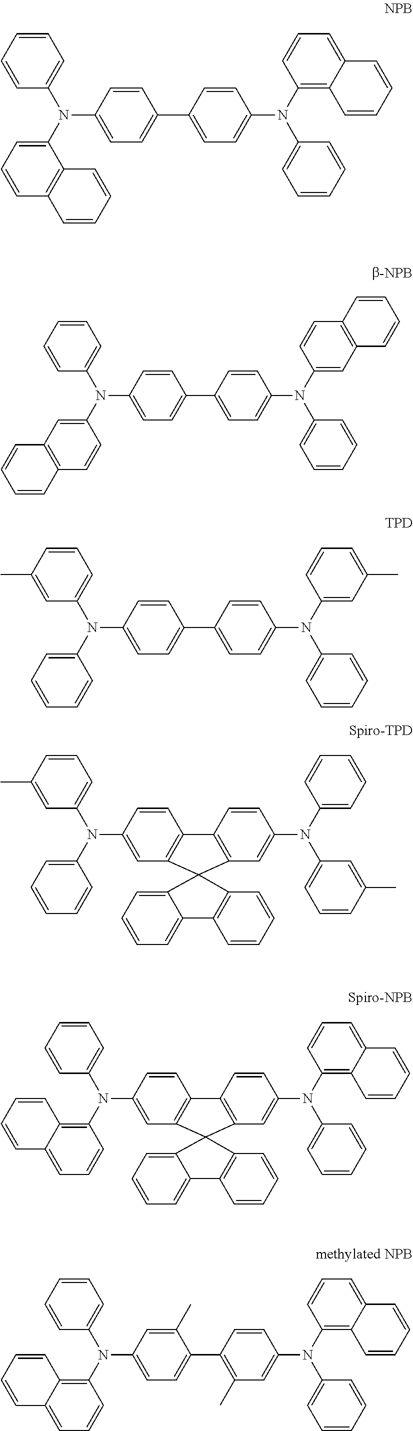

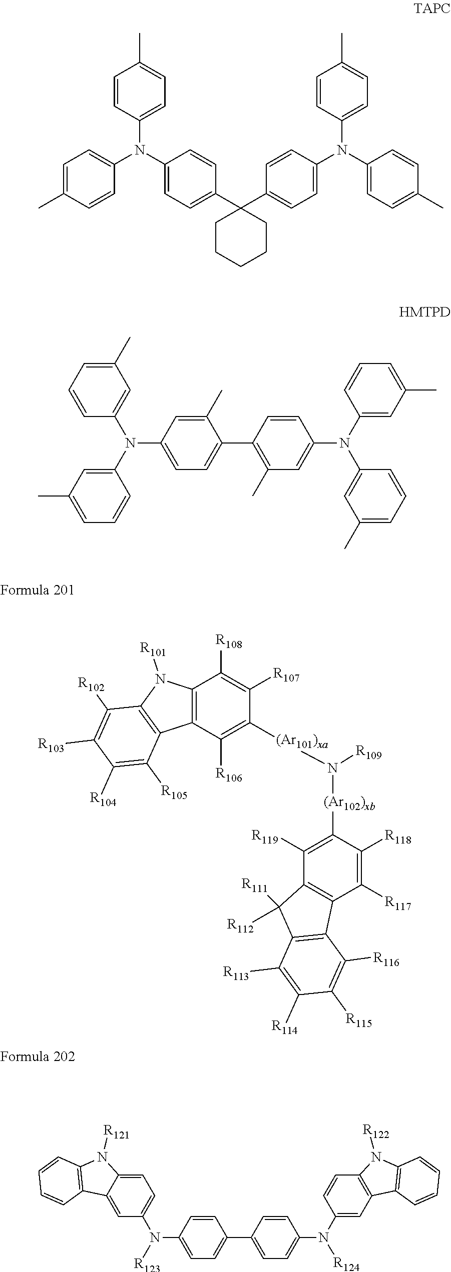

Ar₁₀₁ and Ar₁₀₂ in Formula 201 may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

xa and xb in Formula 201 may each independently be an integer from 0 to 5, or xa and xb in Formula 201 may each independently be 0, 1, or 2. For example, in one or more embodiments, xa may be 1 and xb may be 0.

R₁₀₁ to R₁₀₈, R₁₁₁ to R₁₁₉, and R₁₂₁ to R₁₂₄ in Formulae 201 and 202 may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, pentyl group, a hexyl group, etc.), or a C₁-C₁₀ alkoxy group (for example, a methoxy group, an ethoxy group, a propoxy group, a butoxy group, a pentoxy group, etc.);

a C₁-C₁₀ alkyl group or a C₁-C₁₀ alkoxy group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or

a phenyl group, a naphthyl group, an anthracenyl group, a fluorenyl group, or a pyrenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group or a C₁-C₁₀ alkoxy group, or a combination thereof.

R₁₀₉ in Formula 201 may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀alkyl group, a C₁-C₂₀ alkoxy group, a phenyl group, a naphthyl group, an anthracenyl group, a pyridinyl group, or a combination thereof.

In one embodiment, the compound represented by Formula 201 may be represented by Formula 201A:

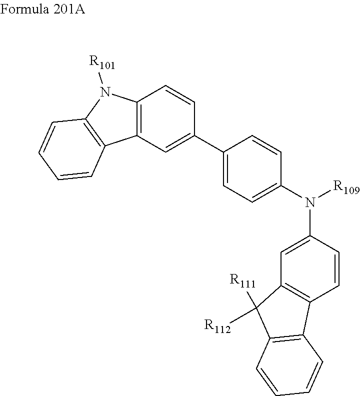

R₁₀₁, R₁₁₁, R₁₁₂, and R₁₀₉ in Formula 201A may be understood by referring to the description provided herein.

For example, the hole transport region may include one of Compounds HT1 to HT20 or a combination thereof:

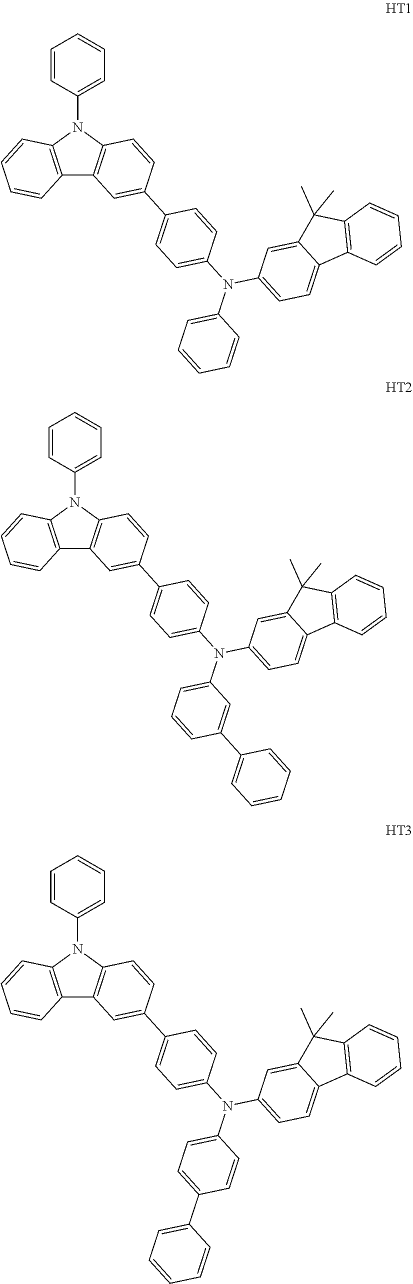 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

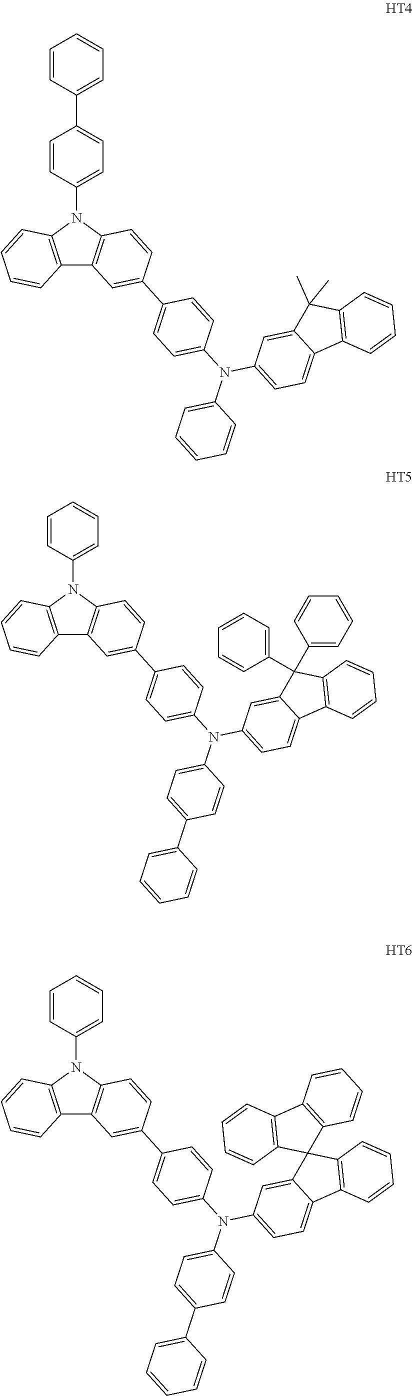 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

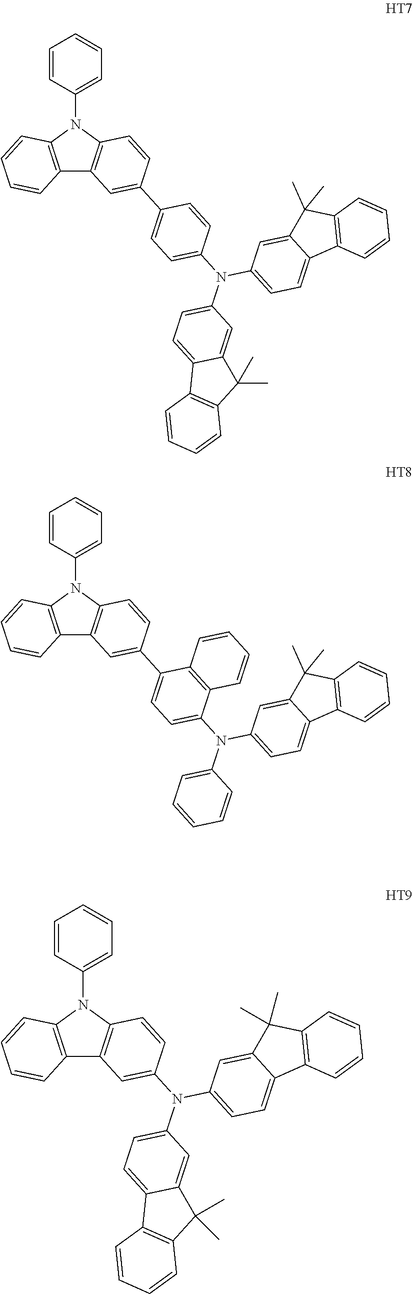 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

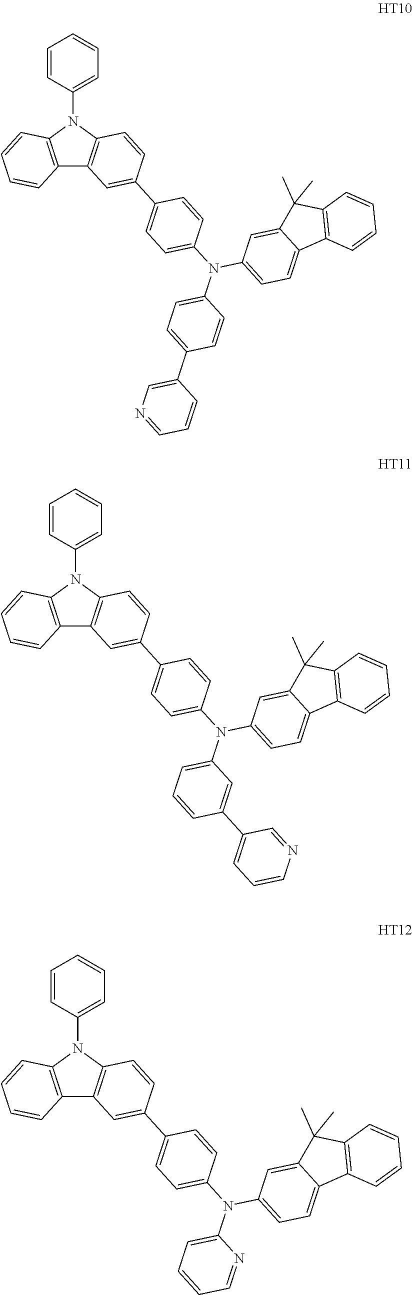 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

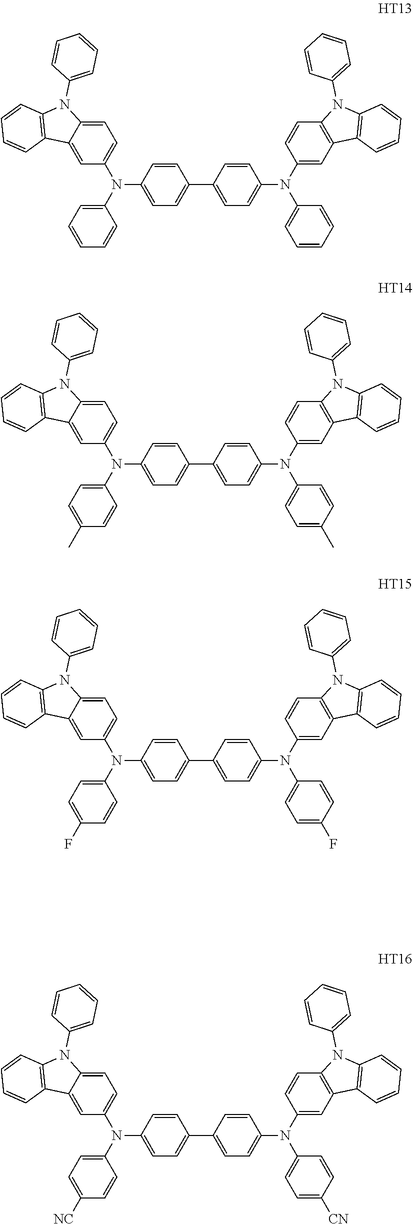 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

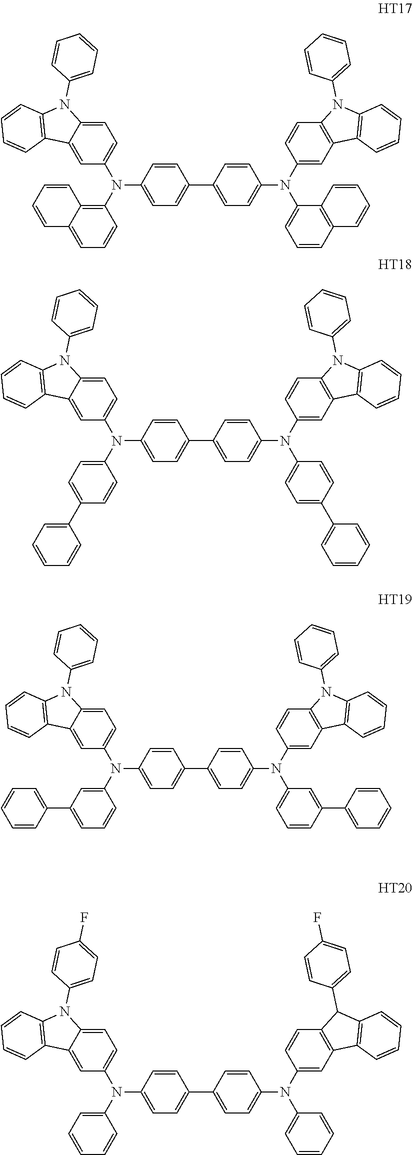 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(C2c3ccccc3-c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in the range of about 100 Å to about 10,000 Å, for example, about 100 Å to about 1,000 Å. When the hole transport region includes at least one of a hole injection layer and a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole-transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may include a quinone derivative, a metal oxide, a cyano group-containing compound, or a combination thereof. For example, the p-dopant may be: a quinone derivative such as tetracyanoquinodimethane (TCNQ), 2,3,5,6-tetrafluoro-tetracyano-1,4-benzoquinodimethane (F4-TCNQ), or F6-TCNNQ; metal oxide, such as tungsten oxide and molybdenum oxide; a cyano group-containing compound, such as Compound HT-D1; or a combination thereof.

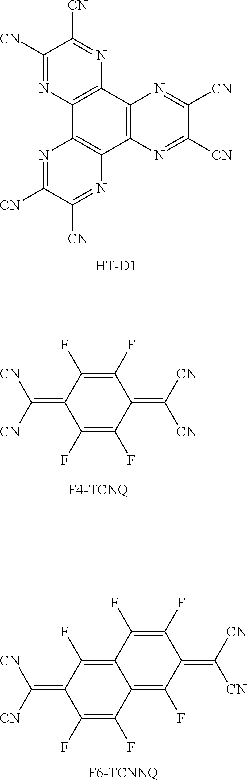

The hole transport region may include a buffer layer.

Also, the buffer layer may compensate for an optical resonance distance according to a wavelength of light emitted from the emission layer, and thus, the efficiency of a formed organic light-emitting device may be improved.

Meanwhile, when the hole transport region includes an electron blocking layer, a material for forming the electron blocking layer may include a material that is used in the hole transport region as described above, a host material described below, or a combination thereof. For example, when the hole transport region includes an electron blocking layer, mCP described below or a combination may be used as the material for forming the electron blocking layer.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a material that is used to form the emission layer.

The emission layer may include a host and a dopant, and the dopant may include the organometallic compound represented by Formula 1 as described herein.

The host may include 1,3,5-tris(N-phenylbenzimidazole-2-yl)benzene (TPBi), 3-tert-butyl-9,10-di-2-naphthylanthracene (TBADN), 9,10-di(naphthalene-2-yl)anthracene (ADN) (also referred to as “DNA”), 4,4′-bis(N-carbazolyl)-1,1′-biphenyl (CBP), 4,4′-bis(9-carbazolyl)-2,2′-dimethyl-biphenyl (CDBP), 1,3,5-tris(carbazol-9-yl) benzene (TCP), 1,3-bis(carbazol-9-yl)benzene (mCP), Compound H50, Compound H51, Compound H52, or a combination thereof:

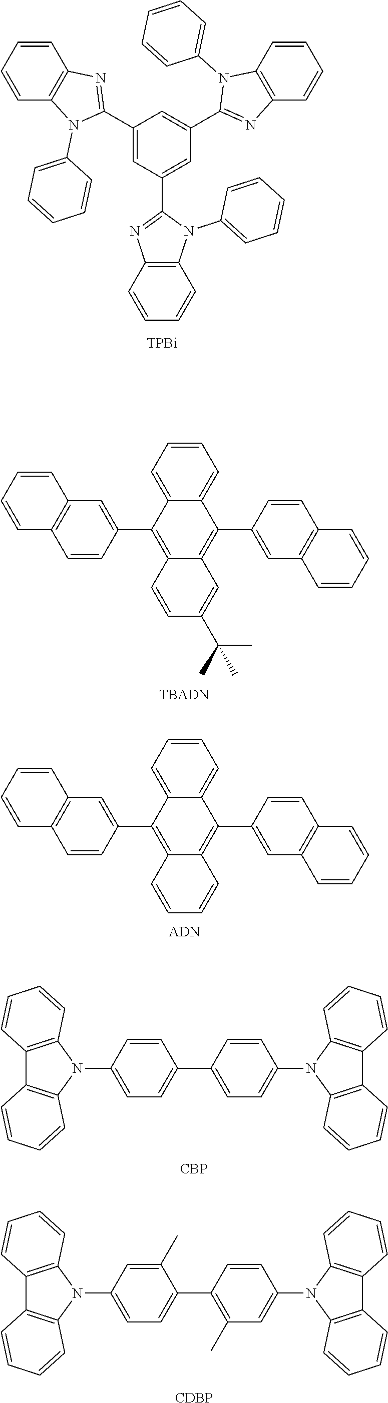

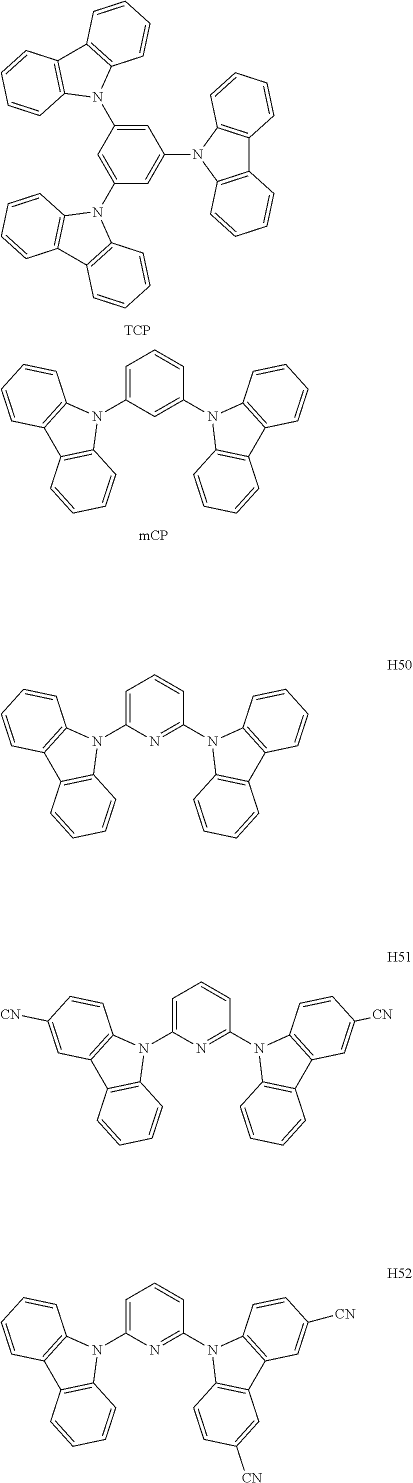

When the organic light-emitting device is a full-color organic light-emitting device, the emission layer may be patterned into a red emission layer, a green emission layer, and/or a blue emission layer. In one or more embodiments, due to a stacked structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight based on 100 parts by weight of the host.

A thickness of the emission layer may be in a range of about 100 Å to about 1,000 Å, for example, about 200 Å to about 600 Å. When the thickness of the emission layer is within these ranges, excellent light-emission characteristics may be obtained without a substantial increase in driving voltage.

Then, an electron transport region may be located on the emission layer.

The electron transport region may include a hole blocking layer, an electron transport layer, an electron injection layer, or a combination thereof.

For example, the electron transport region may have a hole blocking layer/electron transport layer/electron injection layer structure or an electron transport layer/electron injection layer structure. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, 2,9-dimethyl-4,7-diphenyl-1,10-phenanthroline (BCP), 4,7-diphenyl-1,10-phenanthroline (Bphen), bis(2-methyl-8-quinolinolato-N1,O8)-(1,1′-biphenyl-4-olato)aluminum (BAlq), or a combination thereof:

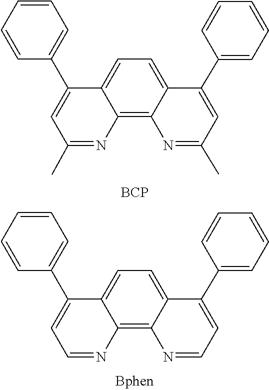

A thickness of the hole blocking layer may be in a range of about 20 Å to about 1,000 Å, for example, about 30 Å to about 600 Å. When the thickness of the hole-blocking layer is within these ranges, excellent hole-blocking characteristics may be obtained without a substantial increase in driving voltage.

The electron transport layer may include BCP, Bphen, TPBi, Alq₃, Balq, TAZ, NTAZ, or combination thereof:

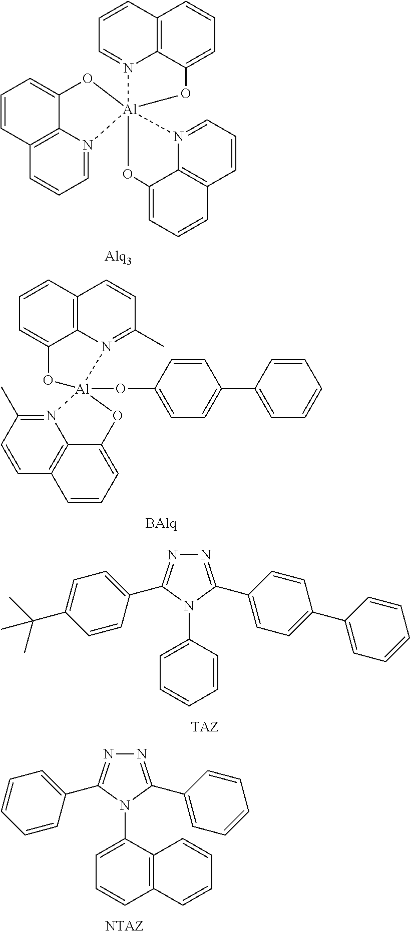

In one or more embodiments, the electron transport layer may include one of Compounds ET1 to ET25 or a combination thereof:

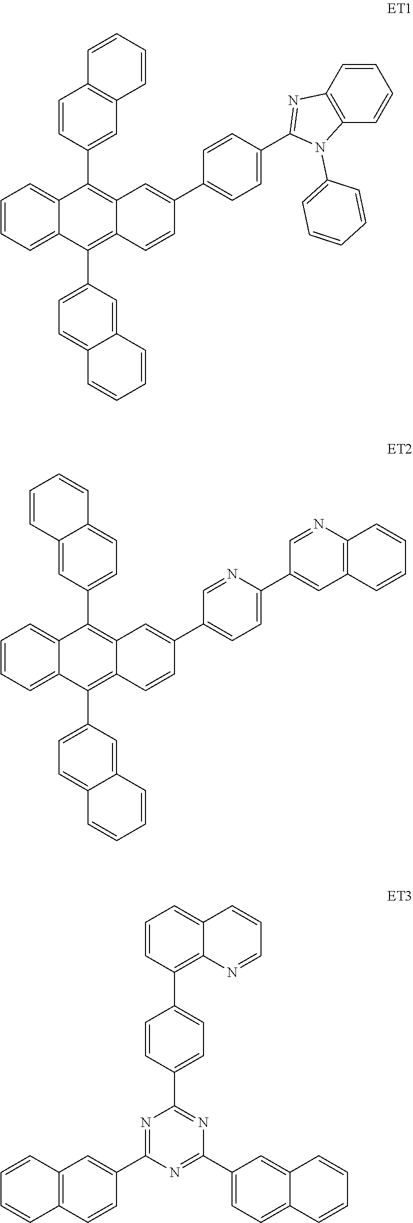 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

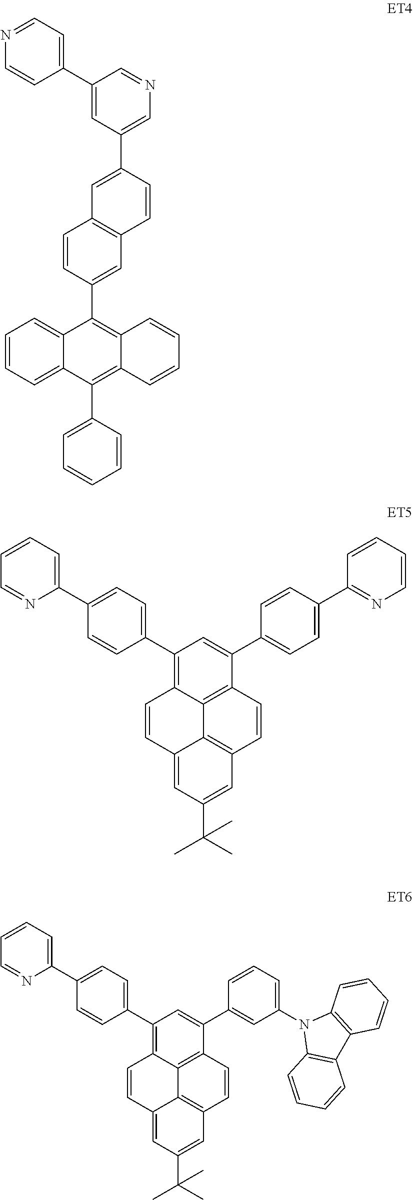 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

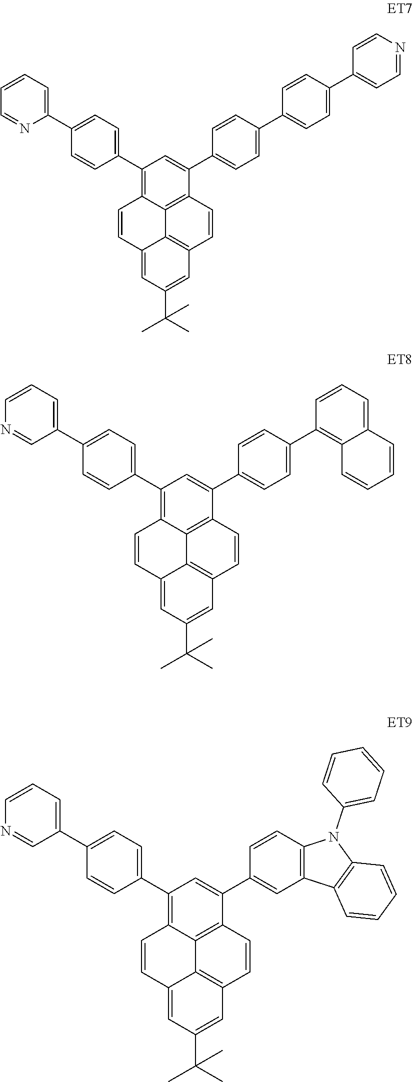 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

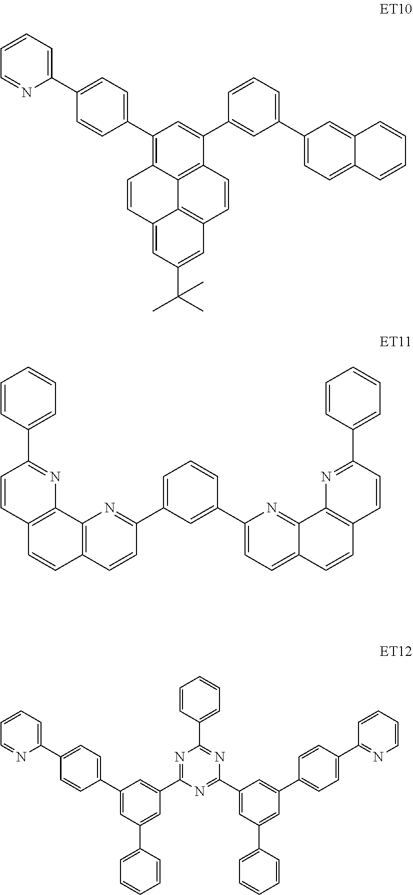 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

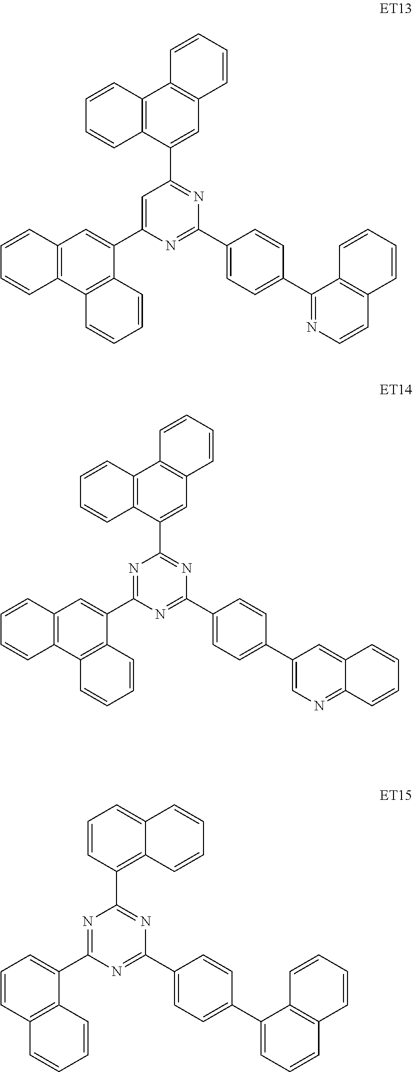 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1]

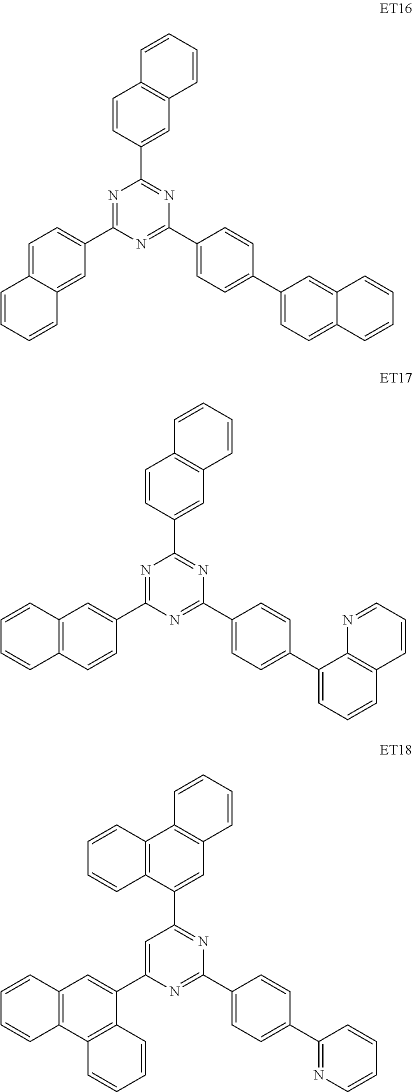 [SMILES: c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1]

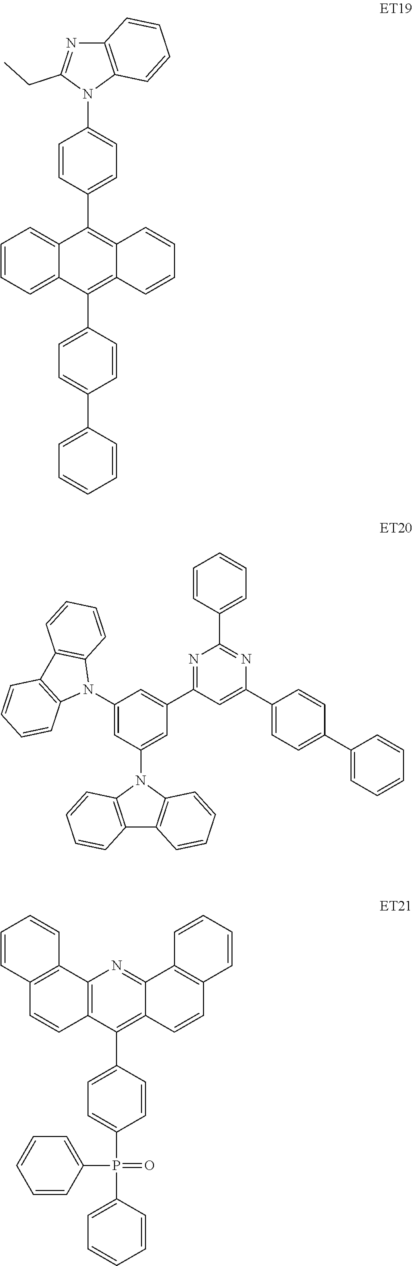 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1]

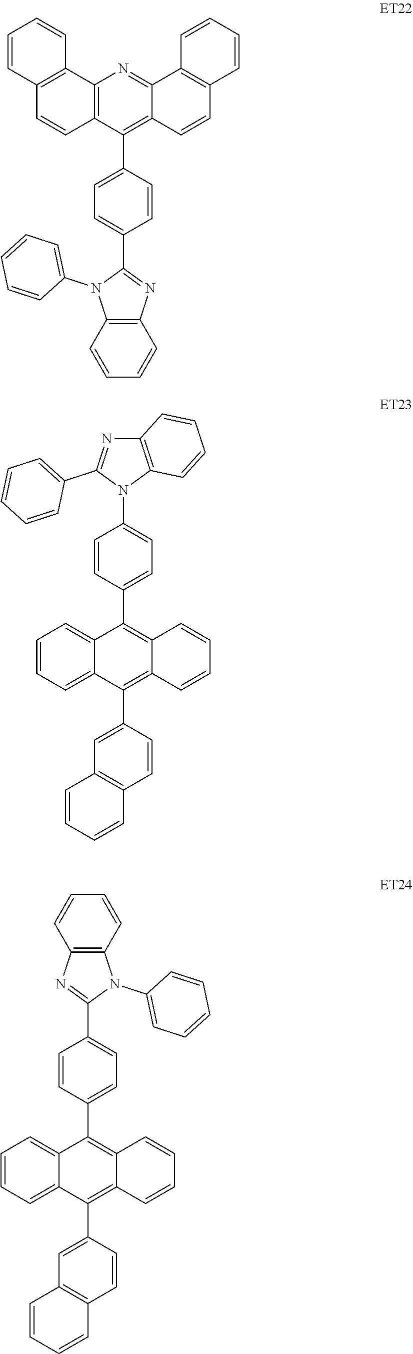

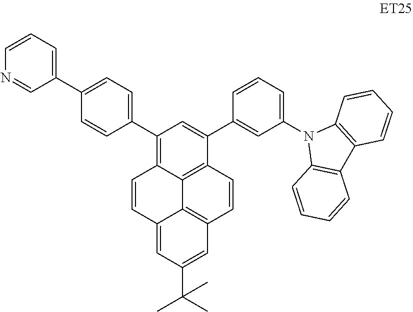 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in the range of about 100 Å to about 1,000 Å, for example, about 150 Å to about 500 Å. When the thickness of the electron transport layer is within the range described above, the electron transport layer may have satisfactory electron-transporting characteristics without a substantial increase in driving voltage.

The electron transport layer may include a metal-containing material in addition to the material as described above.

The metal-containing material may include a Li complex. The Li complex may include, for example, Compound ET-D1 or ET-D2:

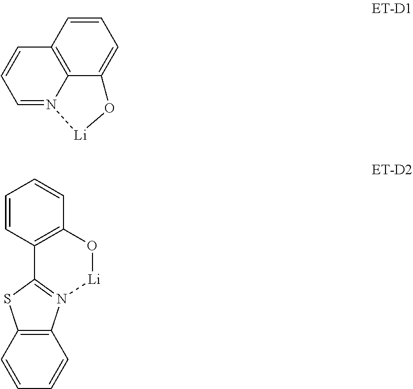

The electron transport region may include an electron injection layer that promotes the flow of electrons from the second electrode 19 thereinto.

The electron injection layer may include LiF, NaCl, CsF, Li₂O, BaO, or a combination thereof.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

The second electrode 19 may be located on the organic layer 15. The second electrode 19 may be a cathode. A material for forming the second electrode 19 may be a metal, an alloy, an electrically conductive compound, or a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as the material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIGURE, but embodiments of the present disclosure are not limited thereto.

According to another aspect, the organic light-emitting device may be included in an electronic apparatus. Thus, an electronic apparatus including the organic light-emitting device is provided. The electronic apparatus may include, for example, a display, an illumination, a sensor, and the like.

Another aspect provides a diagnostic composition including at least one organometallic compound represented by Formula 1.

The organometallic compound represented by Formula 1 provides high emission efficiency. Accordingly, a diagnostic composition including the organometallic compound may have high diagnostic efficiency.

The diagnostic composition may be used in various applications including a diagnosis kit, a diagnosis reagent, a biosensor, and a biomarker.

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, Formula 9-33 is a branched C alkyl group, for example, a tert-butyl group that is substituted with two methyl groups.

The term “C₁-C₆₀ alkoxy group” used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆ alkynyl group” as used herein refers to a hydrocarbon group formed by substituting at least one carbon-carbon triple bond in the middle or at the terminus of the C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the C₃-C₁₀ cycloalkylene group is a divalent group having the same structure as the C₃-C₁₀ cycloalkyl group.

Examples of the C₃-C₁₀ cycloalkyl group may include a cyclopropyl group, a cyclobutyl group, a cyclopentyl group, a cyclohexyl group, a cycloheptyl group, a cyclooctyl group, an adamantanyl group, a bicyclo[1.1.1]pentyl group, a bicyclo[2.1.1]hexyl group, a bicyclo[2.2.1]heptyl(norbornanyl) group, a bicyclo[2.2.2]octyl group, and the like.

The term “C₁-C₁₀ heterocycloalkyl group” as used herein refers to a saturated monocyclic group that includes at least one heteroatom selected from N, O, P, Si, S, B, Ge, and Se as a ring-forming atom and 1 to 10 carbon atoms, and the term “C₁-C₁₀ heterocycloalkylene group” as used herein refers to a divalent group having the same structure as the C₁-C₁₀ heterocycloalkyl group.

Examples of the C₁-C₁₀ heterocycloalkyl group include a silolanyl group, a silinanyl group, a tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, B, Ge, and Se as a ring-forming atom, 1 to 10 carbon atoms, and at least one double bond in its ring. Examples of the C₁-C₁₀ heterocycloalkenyl group are a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₇-C₆₀ alkyl aryl group” used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group having at least one heteroatom selected from N, O, P, Si, S, B, Ge, and Se as a ring-forming atom and a cyclic aromatic system having 1 to 60 carbon atoms, and the term “C₁-C₆₀ heteroarylene group” as used herein refers to a divalent group having at least one heteroatom selected from N, O, P, Si, S, B, Ge, and Se as a ring-forming atom and a carbocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₆-C₆₀ heteroaryl group and the C₆-C₆₀ heteroarylene group each include two or more rings, the rings may be fused to each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates —OA₁₀₂ (wherein A₁₀₂ indicates the C₆-C₆₀ aryl group), the C₆-C₆₀ arylthio group indicates —SA₁₀₃ (wherein A₁₀₃ indicates the C₆-C₆₀ aryl group), and the C₁-C₆₀ alkylthio group indicates —SA₁₀₄ (wherein A₁₀₄ indicates the C₁-C₆₀ alkyl group).

The term “C1-C heteroaryloxy group” as used herein indicates a group of formula —OA₁₀₂ₐ (wherein A₁₀₂ₐ indicates the C₁-C₆₀ heteroaryl group), and the C₁-C₆₀ heteroarylthio group indicates a group of formula—SA₁₀₃ₐ (wherein A₁₀₃ₐ indicates the C₁-C₆₀ heteroaryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, S, B, Ge, and Se, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as a monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Examples of the “C₅-C₃₀ carbocyclic group (unsubstituted or substituted with at least one R₁₀ₐ)” are an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, Se, Ge, B, and S other than 1 to 30 carbon atoms. The C₁-C₃₀ heterocyclic group may be a monocyclic group or a polycyclic group. The “C₁-C₃₀ heterocyclic group (unsubstituted or substituted with at least one R₁₀ₐ)” may be, for example, a thiophene group, a furan group, a pyrrole group, a silole group, a borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group (each unsubstituted or substituted with at least one R₁₀ₐ as defined herein).

The terms “fluorinated C₁-C₆₀ alkyl group (or a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” as used herein respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group (—F). For example, the term “fluorinated C₁ alkyl group (that is, a fluorinated methyl group)” includes —CF₃, —CF₂H, and —CFH₂. The “fluorinated C₁-C₆₀ alkyl group (or, a fluorinated C₁-C₂₀ alkyl group, or the like)”, “the fluorinated C₃-C₁₀ cycloalkyl group”, “the fluorinated C₁-C₁₀ heterocycloalkyl group”, or “the fluorinated a phenyl group” may be i) a fully fluorinated C₁-C₆₀ alkyl group (or, a fully fluorinated C₁-C₂₀ alkyl group, or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, all hydrogen included therein is not substituted with a fluoro group.

The terms “deuterated C₁-C₆₀ alkyl group (or a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” as used herein respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one deuterium. For example, the “deuterated C₁ alkyl group (that is, the deuterated methyl group)” may include—CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, in which, in each group, all hydrogen included therein are not substituted with deuterium.

The term “(C₁-C₂₀ alkyl) ‘X’ group” as used herein refers to an ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of a (C₁ alkyl) phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon selected from a ring-forming carbon is substituted with nitrogen.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may each independently be:

deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof,

wherein Q₁ to Q₉, Q₁₁ to Q₁₉, Q₂₁ to Q₂₉ and Q₃₁ to Q₃₉ as used herein may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a C₁-C₆₀ heteroaryloxy group; a C₁-C₆₀ heteroarylthio group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉ and Q₃₁ to Q₃₉ as used herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

Hereinafter, compounds and organic light-emitting devices according to one or more exemplary embodiments are described in further detail with reference to the Synthesis Example and Examples. However, the organic light-emitting device is not limited thereto. The wording “B was used instead of A” used in describing Synthesis Examples means that an amount of A used was identical to an amount of B used, in terms of a molar equivalent.

### EXAMPLES

### Synthesis Example 1 (Compound 1)

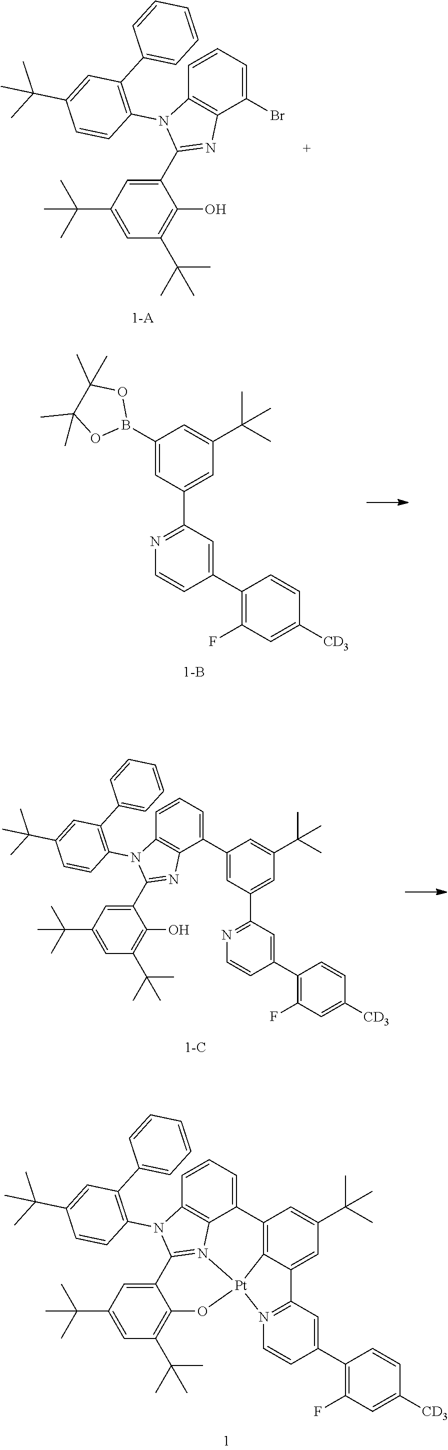

### Synthesis of Compound 1-C (2,4-di-tert-butyl-6-(4-(3-(tert-butyl)-5-(4-(2-fluoro-4-(methyl-d3)phenyl)pyridin-2-yl)phenyl)-1-(5-(tert-butyl)-[1,1′-biphenyl]-2-yl)-1H-benzo[d]imidazol-2-yl)phenol)

1.5 grams (g) (0.002 moles (mol), 1.0 equivalent (equiv.)) of Compound 1-A (2-(4-bromo-1-(5-(tert-butyl)-[1,1′-biphenyl]-2-yl)-1H-benzo[d]imidazol-2-yl)-4,6-di-tert-butylphenol), 1.22 g (0.003 mol, 1.1 equiv.) of Compound 1-B (2-(3-(tert-butyl)-5-(4,4,5,5-tetramethyl-1,3,2-dioxaborolan-2-yl)phenyl)-4-(2-fluoro-4-(methyl-d3)phenyl)pyridine), 0.20 g (0.001 mol, 0.07 equiv.) of tetrakis(triphenylphosphine)palladium(0), and 1.0 g (0.007 mol, 3 equiv.) of potassium carbonate were mixed with 40 mL of solvent wherein tetrahydrofuran (THF) and deionized water (DI water) were mixed at a volume ratio of 3:1 and then, the resultant mixture was heated at reflux for 12 hours. The obtained crude product mixture was allowed to cool to room temperature, and then, the precipitate was removed therefrom to obtain a filtrate. The filtrate was washed with ethyl acetate (EA) and DI water, and column chromatography (column performed using a solvent gradient of 5-10 volume percent (vol %) of EA and 90-95 vol % of hexanes) was performed thereon to complete the production of 1.8 g (yield of 86%) of Ligand C. The obtained compound was identified by high resolution mass spectrometry (HRMS) (using matrix assisted laser desorption ionization (MALDI)) and high-performance liquid chromatography (HPLC) analysis.

HRMS (MALDI) calculated (calcd.) for C₅₉H₅₉D₃FN₃O: mass to charge ratio (m/z) 850.5065. Found: 850.5067.

### Synthesis of Compound 1

1.8 g (2.03 millimoles (mmol)) of Compound 1-C and 1.01 g (2.43 mmol, 1.2 equiv.) of K₂PtCl₄ were mixed with 40 mL of a solvent mixture containing 30 mL of acetic acid (AcOH) and 10 mL of DI water, and then the resultant mixture was heated at reflux for 16 hours. The obtained crude product mixture was allowed to cool to room temperature, and then the precipitate was removed therefrom to obtain a filtrate. The filtrate was dissolved in methylene chloride (MC) and washed with DI water, and column chromatography (using a solvent gradient of 10-35 vol % of MC and 65-90 vol % of hexanes) was performed thereon to complete the production of 1.2 g (yield of 57%) of Compound 1. The obtained compound was identified by HRMS and HPLC analysis.

HRMS (MALDI) calcd. for C₅₉H₅₇D₃FN₃OPt: m/z 1043.4556. Found: 1043.4555.

### Synthesis Example 2 (Compound 2)

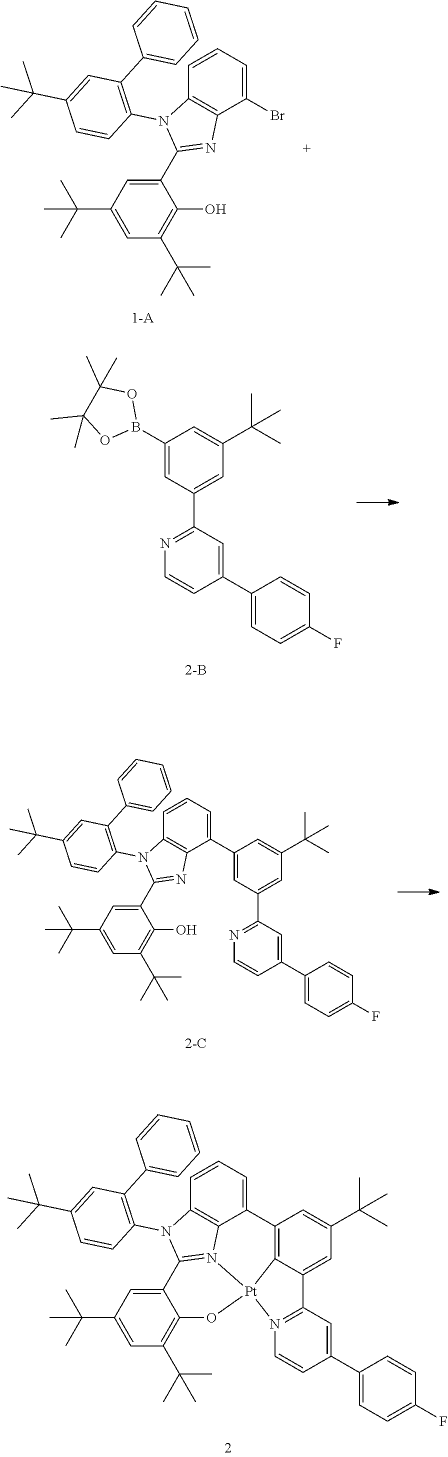

### Synthesis of Compound 2-C (2,4-di-tert-butyl-6-(4-(3-(tert-butyl)-5-(4-(4-fluorophenyl)pyridin-2-yl)phenyl)-1-(5-(tert-butyl)-[1,1′-biphenyl]-2-yl)-1H-benzo[d]imidazol-2-yl)phenol)

1.7 g (a yield of 83%) of Compound 2-C was obtained in a similar manner as used to obtain Compound 1-C of Synthesis Example 1, except that Compound 2-B (2-(3-(tert-butyl)-5-(4,4,5,5-tetramethyl-1,3,2-dioxaborolan-2-yl)phenyl)-4-(4-fluorophenyl)pyridine) was used instead of Compound 1-B. The obtained compound was identified by HRMS and HPLC analysis.

HRMS (MALDI) calcd. for C₅₈H₆₀FN₃O: m/z 833.4720. Found: 833.4722.

### Synthesis of Compound 2

1.2 g (yield of 57%) of Compound 2 was obtained in a manner similar to that used to obtain Compound 1 of Synthesis Example 1, except that 1.7 g (1.92 mmol) of Compound 2-C was used instead of Compound 1-C. The obtained compound was identified by HRMS and HPLC analysis.

HRMS (MALDI) calcd for C₅₈H₅₈FN₃OPt: m/z 1026.4212. Found: 1026.4213.

### Synthesis Example 3 (Compound 3)

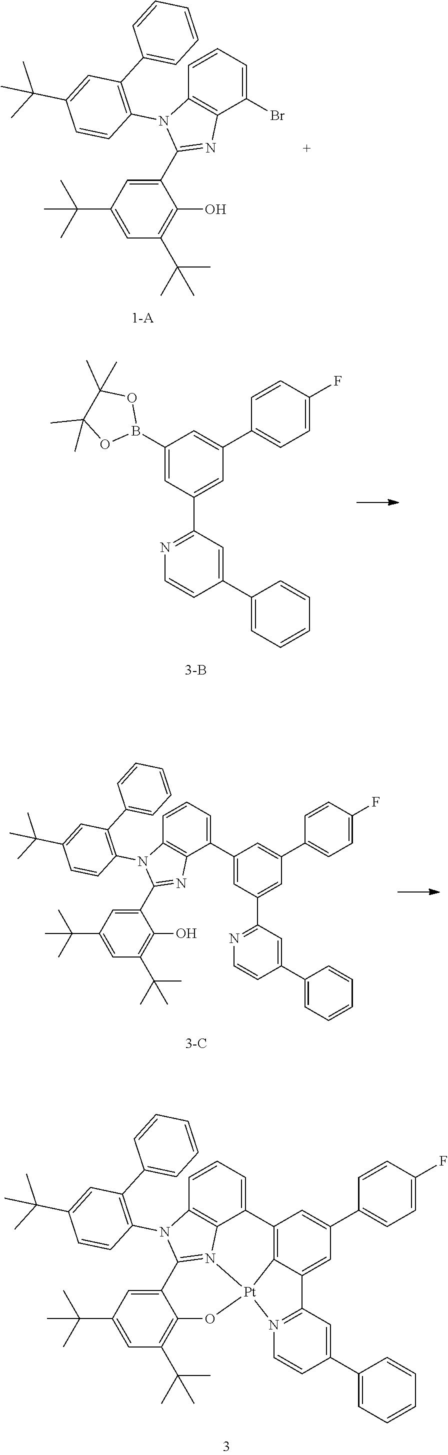

### Synthesis of Compound 3-C (2,4-di-tert-butyl-6-(1-(5-(tert-butyl)-[1,1′-biphenyl]-2-yl)-4-(4′-fluoro-5-(4-phenylpyridin-2-yl)-[1,1′-biphenyl]-3-yl)-1H-benzo[d]imidazol-2-yl)phenol)

2.4 g (yield of 86%) of Compound 3-C was obtained in a manner similar to that used to obtain Compound 1-C of Synthesis Example 1, except that Compound 3-B (2-(4′-fluoro-5-(4,4,5,5-tetramethyl-1,3,2-dioxaborolan-2-yl)-[1,1′-biphenyl]-3-yl)-4-phenylpyridine) was used instead of Compound 1-B. The obtained compound was identified by HRMS and HPLC analysis.

HRMS (MALDI) calcd. for C₆₀H₅₆FN₃O: m/z 853.4407. Found: 853.4408.

### Synthesis of Compound 3

1.8 g (yield of 61%) of Compound 3 was obtained in a manner similar to that used to obtain Compound 1 of Synthesis Example 1, except that 2.4 g (2.81 mmol) of Compound 3-C was used instead of Compound 1-C. The obtained compound was identified by HRMS and HPLC analysis.

HRMS (MALDI) calcd. for C₆₀H₅₄FN₃OPt: m/z 1046.3899. Found: 1046.3896.

### Evaluation Example 1: Evaluation of Thermal Characteristics

Thermal analysis was performed under an N₂ atmosphere. The temperature zones were as follows: from room temperature to 800° C. (10° C./min) for thermal gravimetric analysis (TGA) or from room temperature to 400° C. (10° C./min) for differential scanning calorimetry (DSC). The pan types were as follows: a Pt pan was situated in a disposable Al pan for TGA or a disposable Al pan was used for DSC. Thermal analysis to obtain glass transition temperature (T_{g}, ° C.) was performed for Compounds 1 to 2 and A to C using TGA and DSC, and the results are shown in Table 2.

TABLE 2

| Compound No. | T_{g} (° C.) |
|---|---|
| 1 | 269 |
| 2 | 267 |
| A | 289 |
| B | 339 |
| C | 342 |

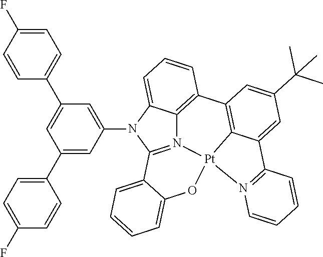

A 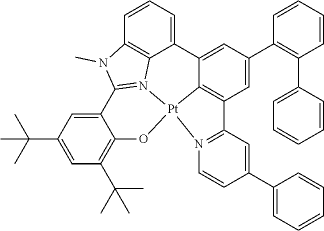
B 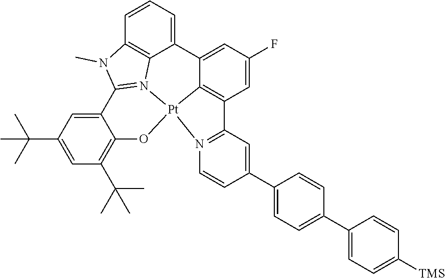
C

Table 2 shows that Compounds 1 and 2 have lower T_{g} than the T_{g} of Compounds A to C. Hence, Compounds 1 and 2 each have excellent thermal stability as compared to the thermal stability of Compounds A to C, and the amount of impurities generated after sublimation purification of Compounds 1 and 2 is smaller than the amount of impurities generated after sublimation purification of Compounds A to C and may have high purity.

### Evaluation Example 2: Evaluation of Photoluminescence Quantum Efficiency (PLQY)

A PMMA solution in CH₂Cl₂, CBP, and Compound 1 (5 parts by weight per 100 parts by weight of CBP) were mixed, and then the resultant mixture was coated on a quartz substrate by using a spin coater, and then the coated substrate was heated in an oven at a temperature of 80° C., and subsequently allowed to cool to room temperature to obtain a film.

The PLQY of the film derived from Compound 1 was evaluated by using a Hamamatsu Photonics absolute photoluminescent (PL) quantum yield measurement system equipped with a xenon light source, a monochromator, a photonic multichannel analyzer, and an integrating sphere, and data analysis as performed using PLQY measurement software (Hamamatsu Photonics, Ltd., Shizuoka, Japan). The process was repeated for Compounds 2 and 3. The PLQY results for the films derived from Compounds 1 to 3 are shown in Table 3.

TABLE 3

| Compound No. | PLQY |
|---|---|
| 1 | 0.985 |
| 2 | 0.996 |
| 3 | 0.929 |

Referring to Table 3, it was confirmed that films derived from Compounds 1 to 3 have excellent PLQY.

### Evaluation Example 3: Decay Time Measurement

A quartz substrate was prepared by washing with chloroform and deionized water, and then a predetermined material as shown in Table 4 was vacuum-(co)deposited (under a static vacuum of 10⁻⁷ torr) to prepare Films 1 to 3, with each having a thickness of 50 nm.

TABLE 4

| | Components used in film production |
|---|---|
| Film 1 | CBP/Compound 1 (at a weight ratio of 9:1) |
| Film 2 | CBP/Compound 2 (at a weight ratio of 9:1) |
| Film 3 | CBP/Compound 3 (at a weight ratio of 9:1) |

Photoluminescence (PL) spectra of each of Films 1 to 3 was measured at room temperature by using a FluoTime 300 spectrometer (a TRPL measurement system manufactured by PicoQuant Inc.). Excitation light was provided using a PLS340 light source (excitation wavelength=340 nm, spectral width=20 nm), which is a pumping light source (PicoQuant Inc.). Then, the main peak of each spectrum was identified, and the number of photons emitted at the wavelength of the photon pulse (pulse width=500 picoseconds) applied by PLS340 to each of Films 1 to 3 was measured multiple times based on time-correlated single photon counting (TCSPC) according to time, thereby obtaining a TRPL curve sufficient for fitting. The obtained result was fitted with two or more exponential decay functions to obtain T_{decay} (Ex), that is, decay time of each of Films 1 to 3 (decay time). Results obtained therefrom are shown in Table 5. A function for fitting is as shown in Equation 1, and from among T_{decay} values obtained from each exponential decay function used for fitting, the largest T_{decay} was used as T_{decay} (Ex). In this regard, the same measurement was performed during the same measurement time as that for obtaining TRPL curve in the dark state (in which pumping signals entering a film are blocked) to obtain a baseline spectrum or a background signal curve for use as a baseline spectrum for fitting.

$$f ( t ) = {\sum }_{i = 1}^{n} {A}_{i} exp ( - t / {T}_{decay , i} ) \qquad Equation 1$$

TABLE 5

| | Decay time(μs) |
|---|---|
| Film 1 (Compound 3) | 2.201 |
| Film 2 (Compound 2) | 2.332 |
| Film 3 (Compound 3) | 2.572 |

Referring to Table 5, it is confirmed that Compounds 1 to 3 have excellent decay time.

### Example 1

An ITO glass substrate was cut to a size of 50 millimeters (mm)×50 mm×0.5 mm and then sonicated in each of acetone, isopropyl alcohol, and DI water, each for 15 minutes, and then exposed to ultraviolet light (UV light)-generated ozone for 30 minutes.

Then, m-MTDATA was deposited on an ITO electrode (anode) of the ITO glass substrate at a deposition rate of 1 angstrom per second (Å/sec) to form a hole injection layer having a thickness of 600 angstroms (Å), and then, NPB (α-NPD) was deposited on the hole injection layer at a deposition rate of 1 Å/sec to form a hole transport layer having a thickness of 250 Å.

Compound 1 (dopant) and CBP (host) were co-deposited on the hole transport layer at a deposition rate of 0.1 Å/sec and a deposition rate of 1 Å/sec, respectively, to form an emission layer having a thickness of 400 Å. The emission layer included Compound 1 in an amount of 10 wt % based on the total weight of the emission layer.

BAlq was deposited on the emission layer at a deposition rate of 1 Å/sec to form a hole blocking layer having a thickness of 50 Å, and Alq₃ was deposited on the hole blocking layer to form an electron transport layer having a thickness of 300 Å, and then, LiF was deposited on the electron transport layer to form an electron injection layer having a thickness of 10 Å, and then, Al was vacuum-deposited on the electron injection layer to form a second electrode (cathode) having a thickness of 1,200 Å, thereby completing the manufacturing of an organic light-emitting device having a structure of ITO/m-MTDATA (600 Å)/NPB (250 Å)/CBP+Compound 1 (10 wt %) (400 Å)/BAlq (50 Å)/Alq₃ (300 Å)/LiF (10 Å)/Al (1,200 Å).

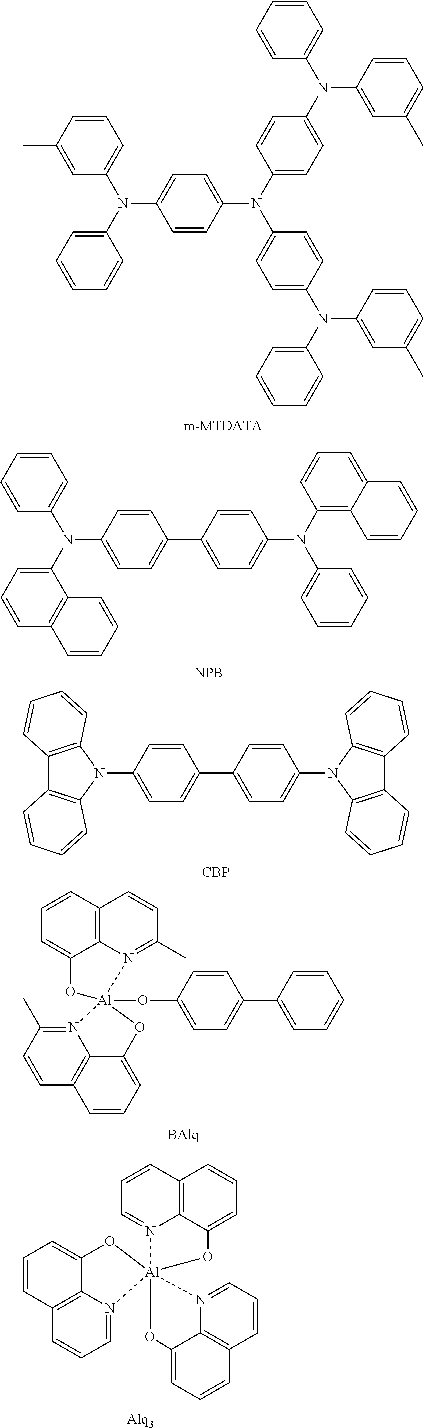

### Examples 2 to 3 and Comparative Examples A to C

Organic light-emitting devices were manufactured in a manner similar to that used to prepare Example 1, except that compounds shown in Table 4 were each used instead of Compound 1 as a dopant in forming an emission layer.

### Evaluation Example 4: Evaluation on Characteristics of Organic Light-Emitting Devices

The driving voltage (volts, V), the luminescence quantum efficiency (%), the roll-off ratio (%), and the lifespan (LT₉₅) of each of the organic light-emitting devices manufactured according to Examples 1 to 3 and Comparative Examples A to C were evaluated. Results thereof are shown in Table 6. This evaluation was performed using a current-voltage meter (Keithley 2400) and a luminescence meter (Minolta Cs-1,000A), and the lifespan (LT₉₅)(at 6,000 cd/m²) was evaluated by evaluating, as a relative value (%), the amount of time that elapsed for the brightness to be reduced to 95% of the initial brightness of 100%. The roll-off ratio was calculated using Equation 2:

Roll off ratio={1−(efficiency (at 9,000 cd/m²)/maximum emission efficiency)}×100% Equation 2

TABLE 6

| | Compound No. | Driving | Luminescent | Roll-off ratio | LT₉₅ |
|---|---|---|---|---|---|
| | as dopant in | Voltage | quantum efficiency | (at 9,000 cd/m²) | (Relative |
| | emission layer | (V) | (%) | (%) | value, %) |
| Example 1 | 1 | 3.78 | 119 | 7 | 100 |
| Example 2 | 2 | 3.95 | 116 | 6 | 130 |
| Example 3 | 3 | 3.61 | 115 | 9 | 120 |
| Comparative | A | 4.42 | 84 | 20 | 15 |
| Example A | | | | | |
| Comparative | B | 4.39 | 108 | 10 | 60 |
| Example B | | | | | |
| Comparative | C | 3.83 | 110 | 10 | 65 |
| Example C | | | | | |

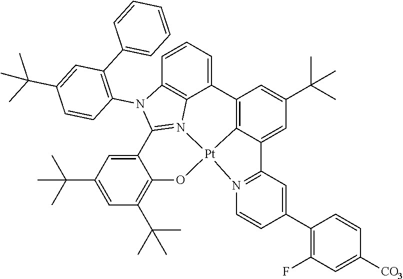

1 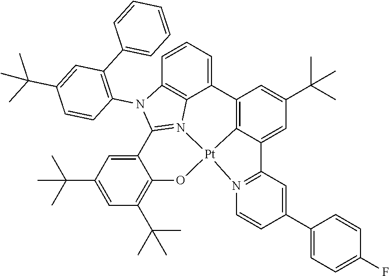
2 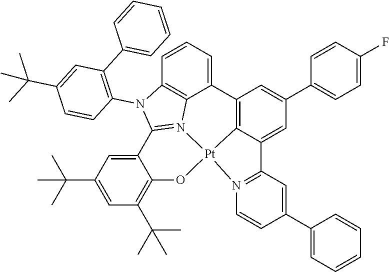
3 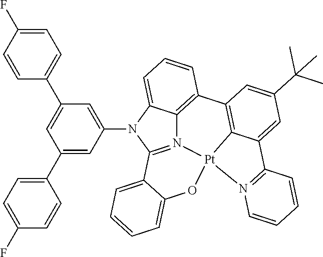
A 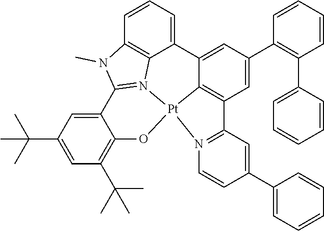
B 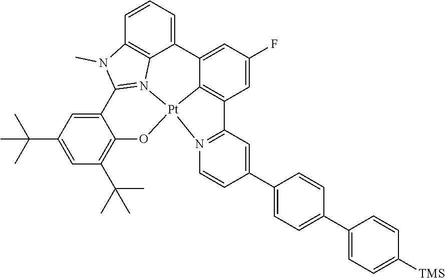
C

From Table 6, it was confirmed that the organic light-emitting devices of Examples 1 to 3 have excellent luminescence quantum efficiency, excellent roll-off ratio, and excellent lifespan characteristics compared to the luminescence quantum efficiency, roll-off ratio, and lifespan characteristics of the organic light-emitting devices of Comparative Examples A to C.

The organometallic compounds according to one or more embodiments have excellent electrical characteristics and/or thermal stability. Accordingly, an organic light-emitting device using the organometallic compounds can have improved characteristics in terms of driving voltage, external quantum efficiency (EQE), roll-off ratio, and lifespan characteristics. Therefore, the use of the organometallic compound according to the one or more embodiments as described herein may allow for the manufacture of a high-quality organic light-emitting device and an electron apparatus including the same.

It should be understood that one or more exemplary embodiments described herein should be considered in a descriptive sense only and not for purposes of limitation. Descriptions of features or aspects within each exemplary embodiment should typically be considered as available for other similar features or aspects in other exemplary embodiments. While one or more exemplary embodiments have been described with reference to the figures, it will be understood by those of ordinary skill in the art that various changes in form and details may be made therein without departing from the spirit and scope as defined by the following claims.

What is claimed is:

1. An organometallic compound represented by Formula 1: 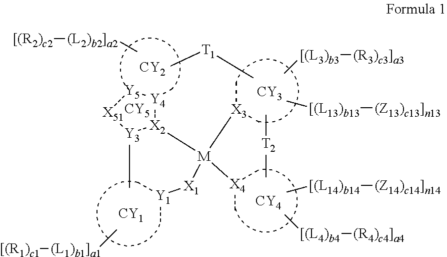
wherein, in Formula 1,
M is beryllium (Be), magnesium (Mg), aluminum (AI), calcium (Ca), titanium (Ti), manganese (Mn), cobalt (Co), copper (Cu), zinc (Zn), gallium (Ga), germanium (Ge), zirconium (Zr), ruthenium (Ru), rhodium (Rh), palladium (Pd), silver (Ag), rhenium (Re), platinum (Pt), or gold (Au),
X₁ is a single bond, O, S, N(R′), P(R′), B(R′), C(R′)(R″), or Si(R′)(R″), and when X₁ is a single bond, Y₁ is directly bonded to M,
X₂ to X₄ are each independently C or N,
a bond between X₁ or Y₁ and M is a covalent bond,
one of a bond between X₂ and M, a bond between X₃ and M, a bond between X₄ and M is a covalent bond, and the others of a bond between X₂ and M, a bond between X₃ and M, or a bond between X₄ and M are coordinate bonds,
Y₁ and Y₃ to Y₅ are each independently C or N,
X₂ and Y₃, X₂ and Y₄, Y₄ and Y₅, X₅₁ and Y₃, and X₅₁ and Y₅ are each independently linked through a chemical bond,
ring CY₁ to ring CY₄ are each independently a C₅-C₃₀ carbocyclic group or a C₁-C₃₀ heterocyclic group, provided that each of ring CY₁, ring CY₃, and ring CY₄ are not a benzimidazole group,
ring CY₅ is a 5-membered ring condensed with ring CY₂,
a cyclometalated ring group formed by ring CY₅, ring CY₂, ring CY₃, and M is a 6-membered ring,
X₅₁ is O, S, N-[(L₇)_{b7}-(R₇)_{c7}], C(R₇)(R₈), Si(R₇)(R₈), Ge(R₇)(R₈), C(═O), N, C(R₇), Si(R₇), or Ge(R₇),
R₇ and R₈ are optionally linked via a single bond, a double bond, or a first linking group to form a C₅-C₃₀ carbocyclic group unsubstituted or substituted with at least one R₁₀ₐ, or a C₁-C₃₀ heterocyclic group unsubstituted or substituted with at least one R₁₀ₐ,
T₁ and T₂ are each independently a single bond, a double bond, *—N(R₉)—*, *—B(R₉)—*, *—P(R₉)—*, *—C(R₉ₐ)(R_{9b})—*′, *—Si(R₉ₐ)(R_{9b})—*′, *—Ge(R₉ₐ)(R_{9b})—*′, *—S—*′, *—Se—*′,*—O—*′, *—C(═O)—*′, *—S(═O)—*′, *—S(═O)₂—*, *—C(R₉)=*, *═C(R₉)—*, *—C(R₉ₐ)═C(R_{9b})—*, *—C(═S)—*′, or *—C≡C—*′, wherein * and *′ each represent a bond to a neighboring atom,
wherein R₉ₐ and R_{9b} are optionally linked via a single bond, a double bond, or a second linking group to form a C₅-C₃₀ carbocyclic group unsubstituted or substituted with at least one R₁₀ₐ, or a C₁-C₃₀ heterocyclic group unsubstituted or substituted with at least one R₁₀ₐ, wherein the second linking group is as defined in connection with the first linking group, and
Z₁₃ and Z₁₄ are each independently a group represented by Formula 2,
n13 and n14 are each independently an integer from 0 to 20, and the sum of n13 and n14 is 1 or greater,
L₁ to L₄, L₇, L₁₃, and L₁₄ are each independently a single bond, a C₅-C₃₀ carbocyclic group unsubstituted or substituted with at least one R₁₀ₐ, or a C₁-C₃₀ heterocyclic group unsubstituted or substituted with at least one R₁₀ₐ,
b1 to b4, b7, b13, and b14 are each independently an integer from 1 to 5,
when b1 is 2 or greater, two or more of L₁(s) are identical to or different from each other, when b2 is 2 or greater, two or more of L₂(s) are identical to or different from each other, when b3 is 2 or greater, two or more of L₃(s) are identical to or different from each other, when b4 is 2 or greater, two or more of L₄(s) are identical to or different from each other, when b7 is 2 or greater, two or more of L₇(s) are identical to or different from each other, when b13 is 2 or greater, two or more of L₁₃(s) are identical to or different from each other, and when b14 is 2 or greater, two or more of L₁₄(s) are identical to or different from each other,
R₁ to R₄, R₇ to R₉, R₉ₐ, R_{9b}, R′, and R″ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
c1 to c4, c7, c13, and c14 are each independently an integer from 1 to 5,
a1 to a4 are each independently an integer from 0 to 20,
when c1 is 2 or greater, two or more of R₁(s) are identical to or different from each other, when c2 is 2 or greater, two or more of R₂(s) are identical to or different from each other, when c3 is 2 or greater, two or more of R₃(s) are identical to or different from each other, when c4 is 2 or greater, two or more of R₄(s) are identical to or different from each other, when c7 is 2 or greater, two or more of R₇(s) are identical to or different from each other, when c13 is 2 or greater, two or more of Z₁₃(s) are identical to or different from each other, and when c14 is 2 or greater, two or more of Z₁₄(s) are identical to or different from each other,
when a1 is 2 or greater, two or more of *-[(L₁)_{b1}-(R₁)_{c1}] are identical to or different from each other, when a2 is 2 or greater, two or more of *-[(L₂)_{b2}-(R₂)_{c2}] are identical to or different from each other, when a3 is 2 or greater, two or more of *-[(L₃)_{b3}-(R₃)_{c3}] are identical to or different from each other, and when a4 is 2 or greater, two or more of *-[(L₄)_{b4}-(R₄)_{c4}] are identical to or different from each other,
two or more of a plurality of R₁(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of a plurality of R₂(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of a plurality of R₃(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of a plurality of R₄(s) are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more groups of R₁ to R₄, R₇ to R₉, R₉ₐ, R_{9b}, R′, and R″ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
R₁₀ₐ is as defined in connection with R₁, 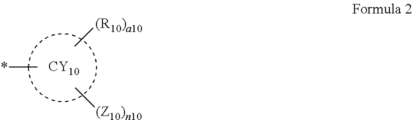
wherein, in Formula 2,
ring CY₁₀ is an unsaturated C₅-C₃₀ carbocyclic group or an unsaturated C₁-C₃₀ heterocyclic group,
R₁₀ is as defined in connection with R₁,
a10 is an integer from 0 to 20,
Z₁₀ is —F or a fluorinated group,
n10 is an integer from 1 to 20,
when a10 is 2 or greater, two or more of R₁₀(s) are identical to or different from each other,
when n10 is 2 or greater, two or more of Z₁₀(s) are identical to or different from each other, and
* indicates a binding site to a neighboring atom,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or
a combination thereof,
wherein Q₁ to Q₉, Q₁₁ to Q₁₉, Q₂₁ to Q₂₉, and Q₃₁ to Q₃₉ are each independently: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or a combination thereof; a C₆-C₆₀ aryloxy group; a C₆-C₆₀ arylthio group; a C₁-C₆₀ heteroaryl group; a C₁-C₆₀ heteroaryloxy group; a C₁-C₆₀ heteroarylthio group; a monovalent non-aromatic condensed polycyclic group; or a monovalent non-aromatic condensed heteropolycyclic group.

2. The organometallic compound of claim 1, wherein
i) X₂ and X₄ are each N, X₃ is C, a bond between X₂ and M and a bond between X₄ and M are each a coordinate bond, and a bond between X₃ and M is a covalent bond,
ii) X₂ and X₃ are each N, X₄ is C, a bond between X₂ and M and a bond between X₃ and M are each a coordinate bond, and a bond between X₄ and M is a covalent bond, or
iii) X₃ and X₄ are each N, X₂ is C, a bond between X₃ and M and a bond between X₄ and M are each a coordinate bond, and a bond between X₂ and M is a covalent bond.

3. The organometallic compound of claim 1, wherein ring CY₁ to ring CY₄ are each independently:
i) a first ring,
ii) a second ring,
iii) a condensed ring in which two or more of the first rings are condensed with each other,
iv) a condensed ring in which two or more of the second rings are condensed with each other, or
v) a condensed ring in which one or more of the first rings and one or more of the second rings are condensed with each other,
wherein the first ring is a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring is an adamantane group, a norbornane group, a norbornene group, a cyclohexane group, a cyclohexene group, a benzene group, a pyridine group, a pyrimidine group, a pyrazine group, a pyridazine group, or a triazine group, and
each of ring CY₁ to ring CY₄ is not a benzimidazole group.

4. The organometallic compound of claim 1, wherein ring CY₁₀ in Formula 2 is a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an isoindole group, an indole group, an indazole group, a purine group, a quinoline group, an isoquinoline group, a benzoquinoline group, a quinoxaline group, a quinazoline group, a cinnoline group, a carbazole group, a phenanthroline group, a benzimidazole group, a benzofuran group, a benzothiophene group, a benzisothiazole group, a benzoxazole group, a benzoisoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azacarbazole group, an azadibenzofuran group, or an azadibenzothiophene group.

5. The organometallic compound of claim 1, wherein Z₁₀ in Formula 2 is:
—F, or
a fluorinated C₁-C₂₀ alkyl group, a fluorinated phenyl group, or a fluorinated biphenyl group, each unsubstituted or substituted with deuterium, a C₁-C₂₀ alkyl group, a deuterated C₁-C₂₀ alkyl group, a phenyl group, a deuterated phenyl group, a (C₁-C₂₀ alkyl) phenyl group, a biphenyl group, a deuterated biphenyl group, a (C₁-C₂₀ alkyl) biphenyl group, or a combination thereof.

6. The organometallic compound of claim 1, wherein n10 in Formula 2 is an integer from 1 to 5.

7. The organometallic compound of claim 1, wherein the group represented by Formula 2 is a group represented by one of Formula 2-1 to 2-42: 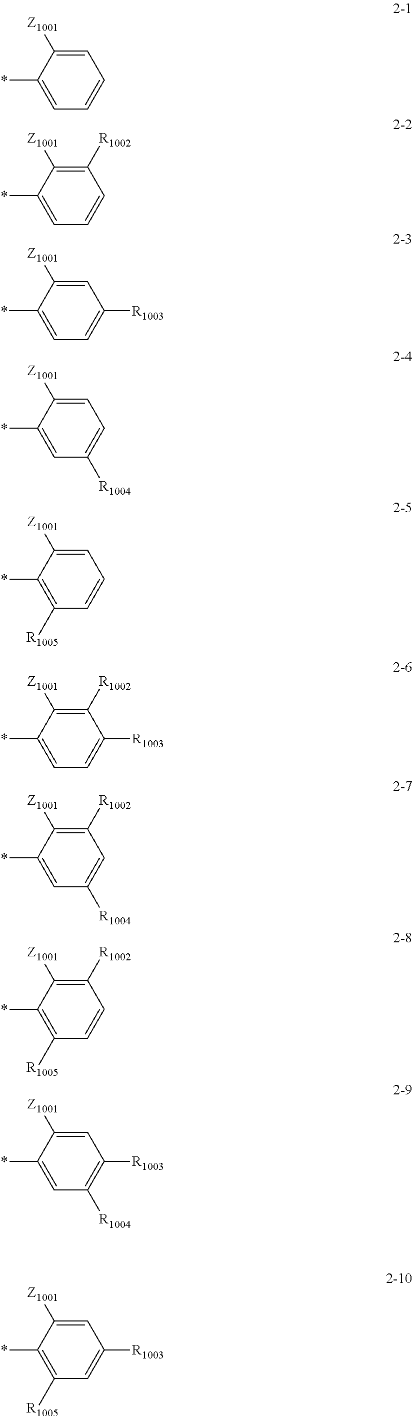 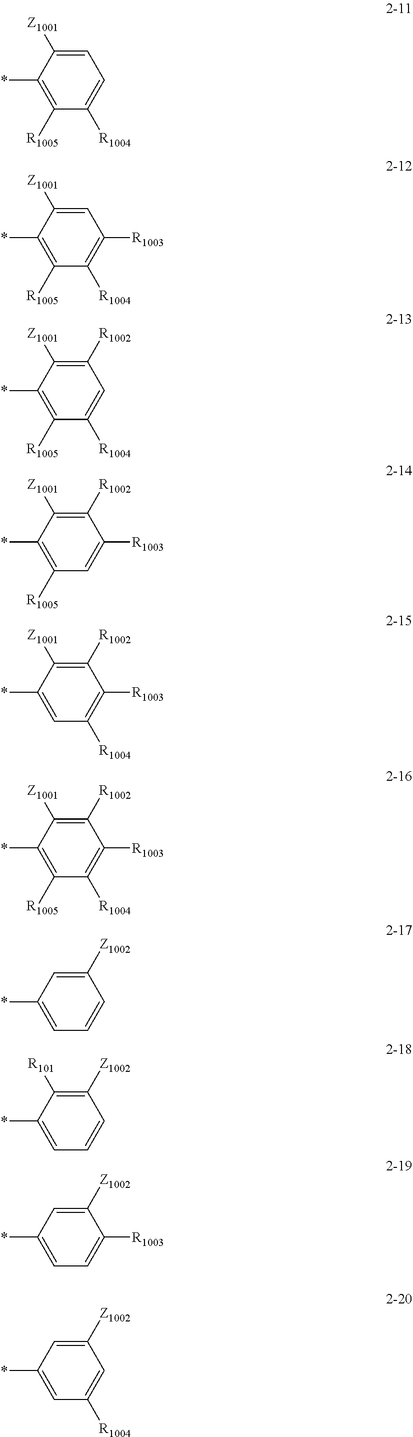 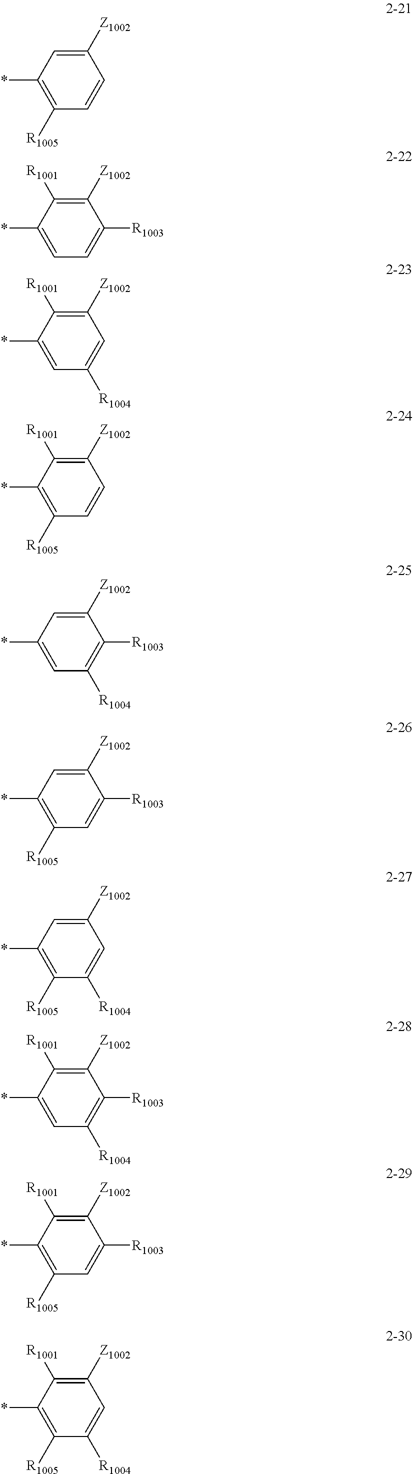 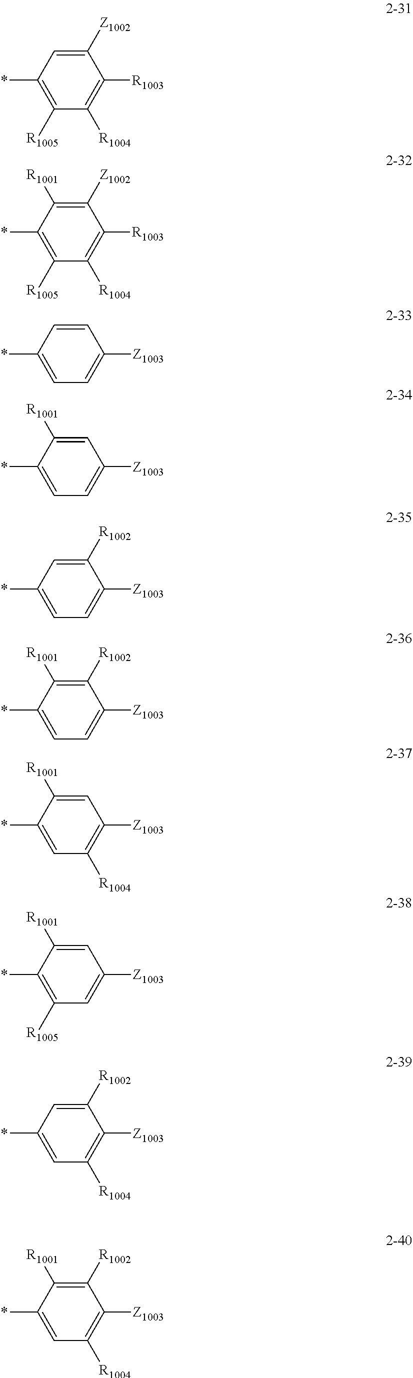 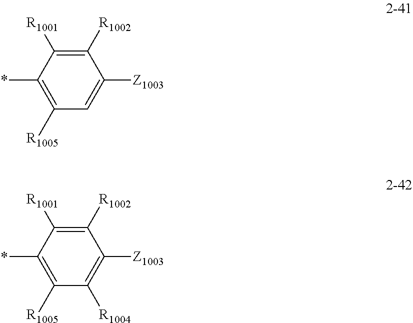
wherein, in Formula 2-1 to 2-42,
R₁₀₀₁ to R₁₀₀₅ are each as defined in connection with R₁₀ in claim 1, provided that each of R₁₀₀₁ to R₁₀₀₅ is not hydrogen,
Z₁₀₀₁ to Z₁₀₀₃ are each as defined in connection with Z₁₀ in claim 1, and
* indicates a binding site to a neighboring atom.

8. The organometallic compound of claim 1, wherein the organometallic compound satisfies at least one of Condition 3 or Condition 4:
Condition 3
n13 in Formula 1 is 1 or 2
Condition 4
n14 in Formula 1 is 1 or 2

9. The organometallic compound of claim 1, wherein the group represented by 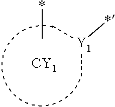
in Formula 1 is a group represented by one of Formulae CY1-1 to CY1-40: 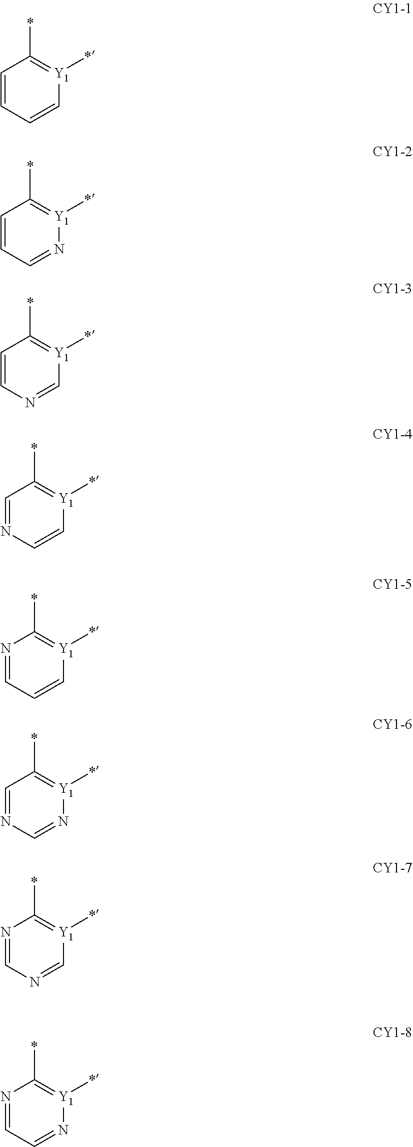 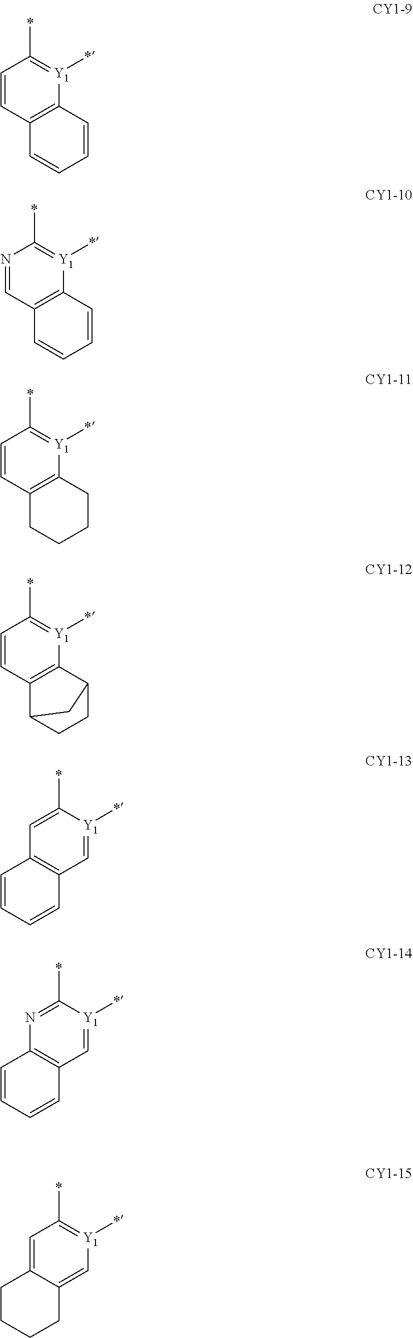 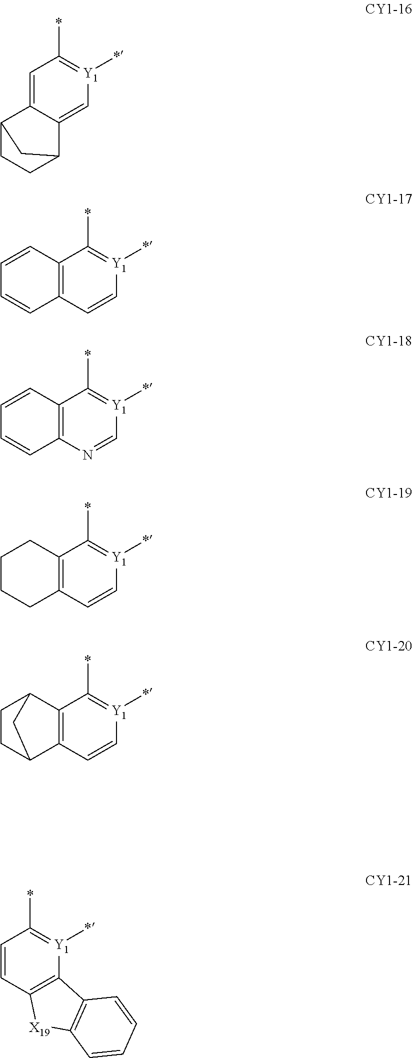 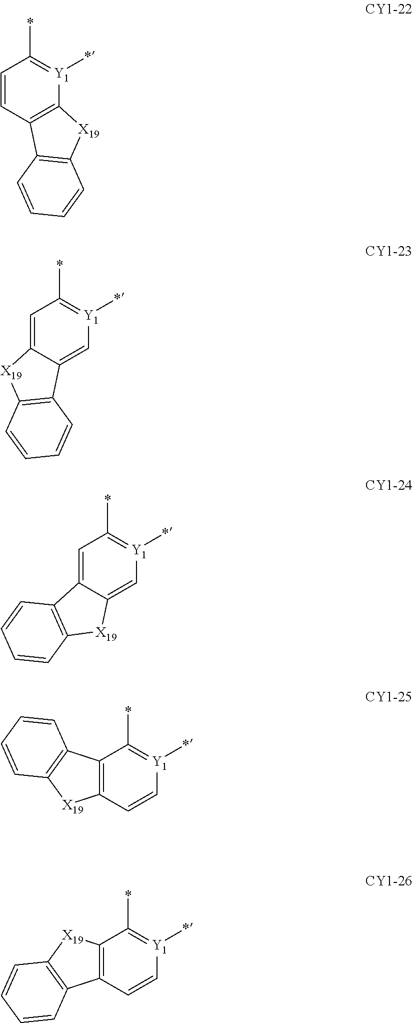 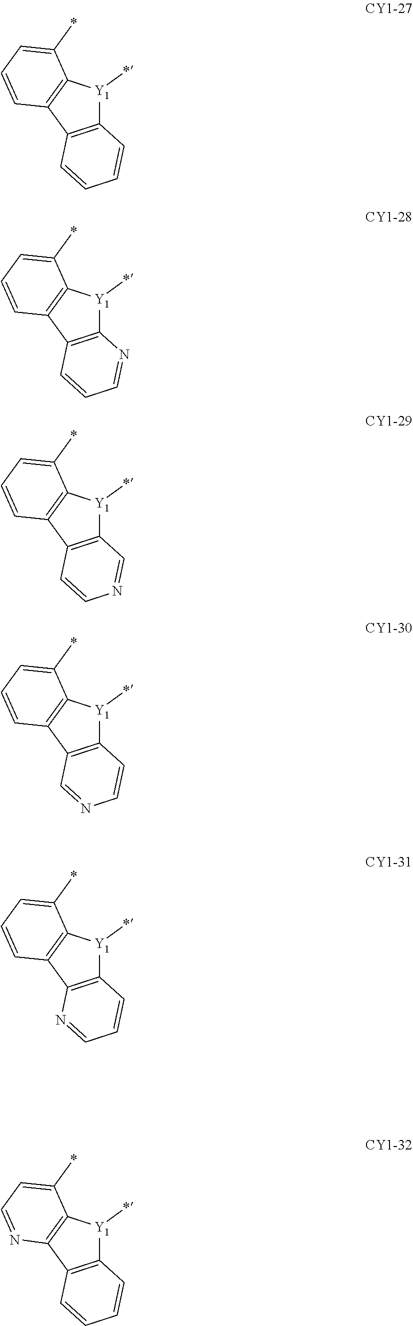 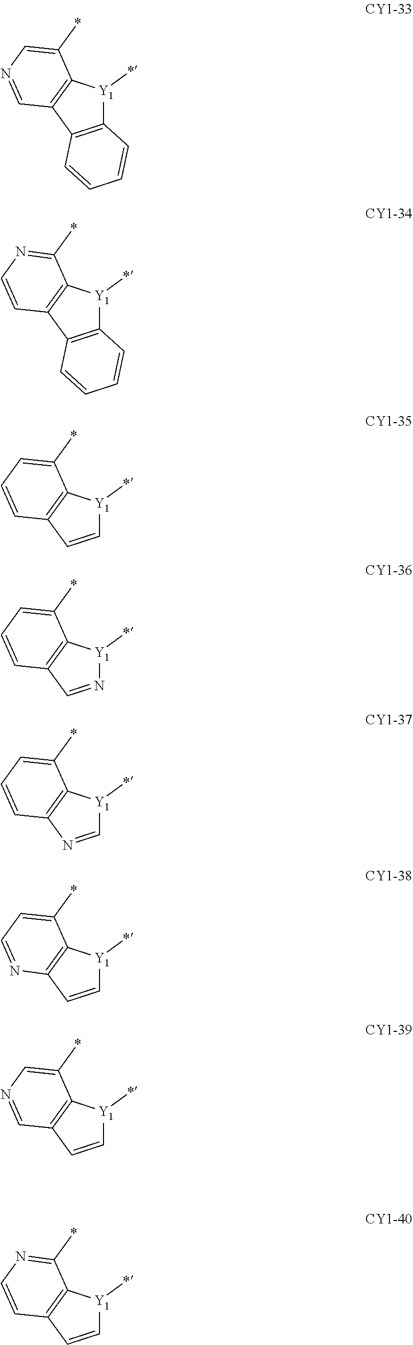
wherein, in Formulae CY1-1 to CY1-40,
Y₁ is as defined in claim 1,
X₁₉ is C(R₁₉ₐ)(R_{19b}), N[(L₁₉)_{b19}-(R¹⁹)_{c19}], O, S, or Si(R₁₉ₐ)(R_{19b}),
L₁₉ is as defined in connection with L₁ in claim 1,
b19 and c19 are each as defined in connection with b1 and c1 in claim 1, respectively,
R₁₉, R₁₉ₐ, and R_{19b} are each as defined in connection with R₁ in claim 1,
*′ indicates a binding site to X₁ or M in Formula 1, and
indicates a binding site to ring CY₅ in Formula 1.

10. The organometallic compound of claim 1, wherein the group represented by 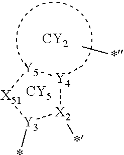
in Formula 1 is a group represented by one of Formulae CY2-1 to CY2-20: 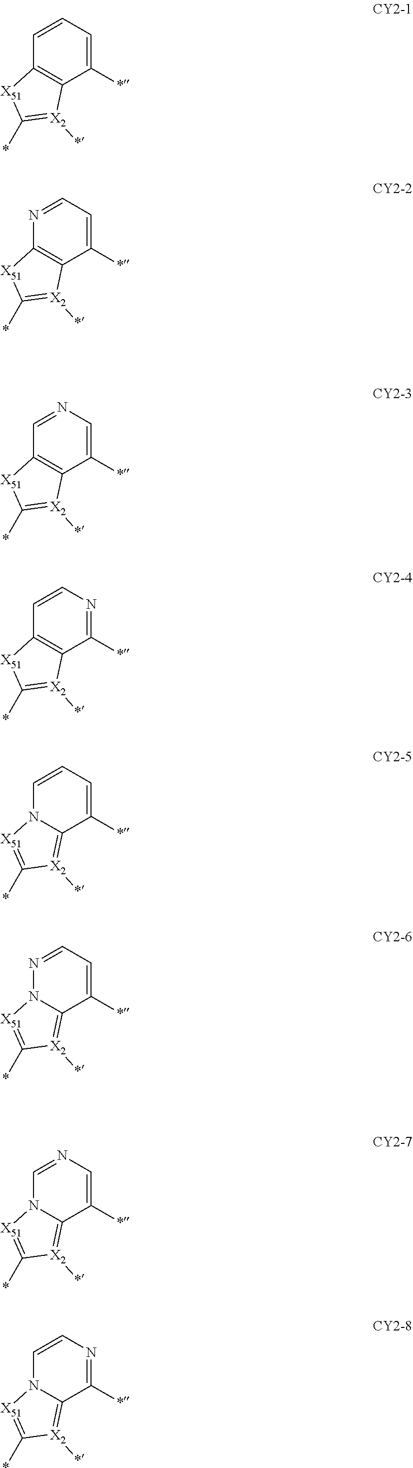 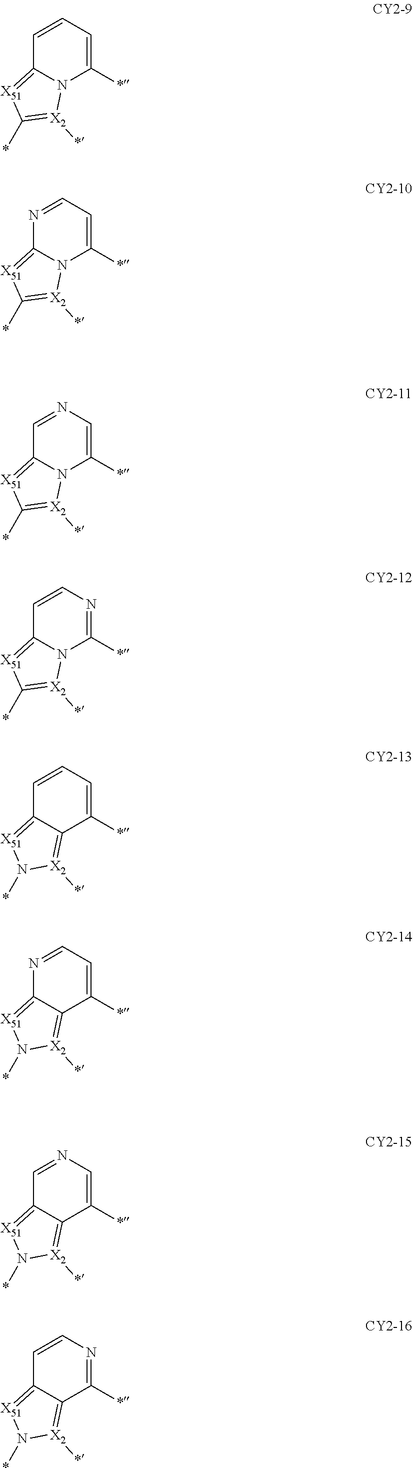 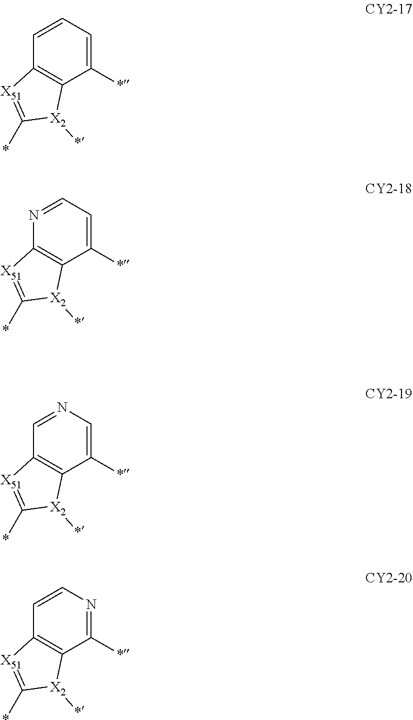
wherein, in Formulae CY2-1 to CY2-20,
X₂ and X₅₁ are each as defined in claim 1,
* indicates a binding site to ring CY₁ in Formula 1,
*′ indicates a binding site to M in Formula 1, and
*″ indicates a binding site to T₁ in Formula 1.

11. The organometallic compound of claim 1, wherein the group represented by 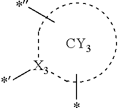
in Formula 1 is a group represented by one of Formulae CY3-1 to CY3-14,
the group represented by 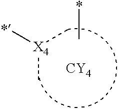
in Formula 1 is a group represented by one of Formulae CY4-1 to CY4-26: 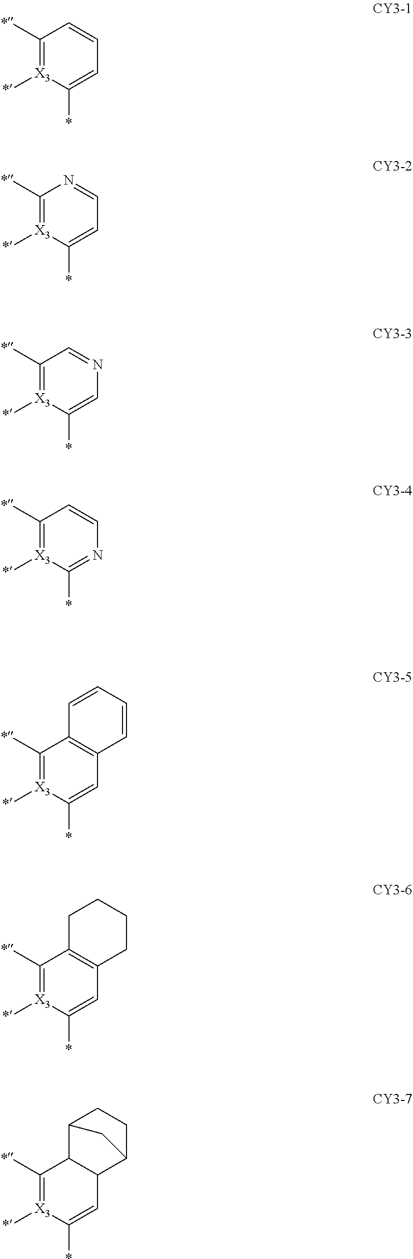 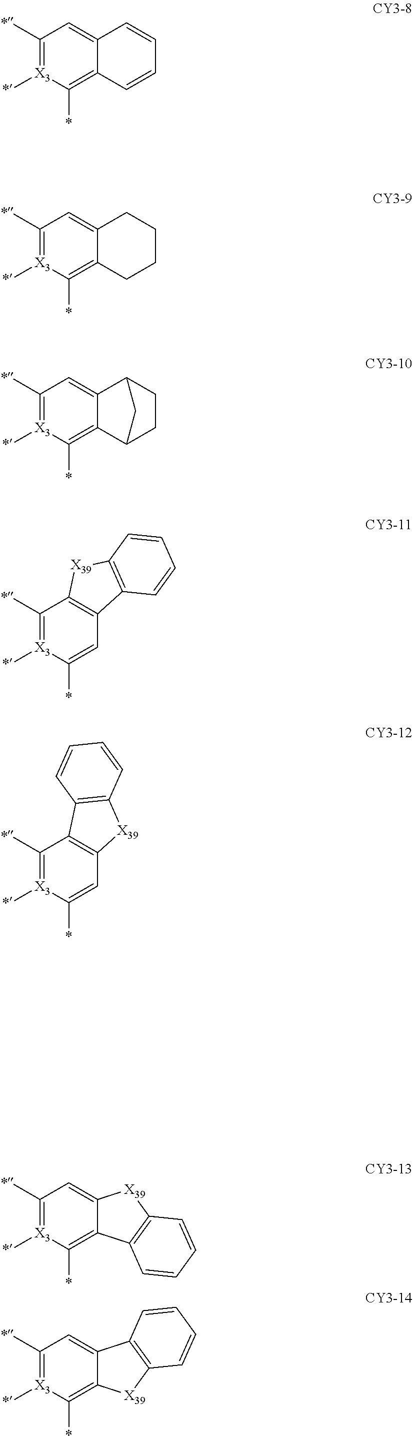
wherein, in Formulae CY3-1 to 3-14,
X₃ is as defined in claim 1,
X₃₉ is C(R₃₉ₐ)(R_{39b}), N[(L₃₉)_{b39}-(R₃₉)_{c39}], O, S, or Si(R₃₉ₐ)(R_{39b}),
L₃₉ is as defined in connection with L₃ in claim 1,
b39 and c39 are each as defined in connection with b3 and c3 in claim 1, respectively,
R₃₉, R₃₉ₐ, and R_{39b} are each as defined in connection with R₃ in claim 1,
* indicates a binding site to T₂ in Formula 1,
*′ indicates a binding site to M in Formula 1, and
*″ indicates a binding site to T₁ in Formula 1, 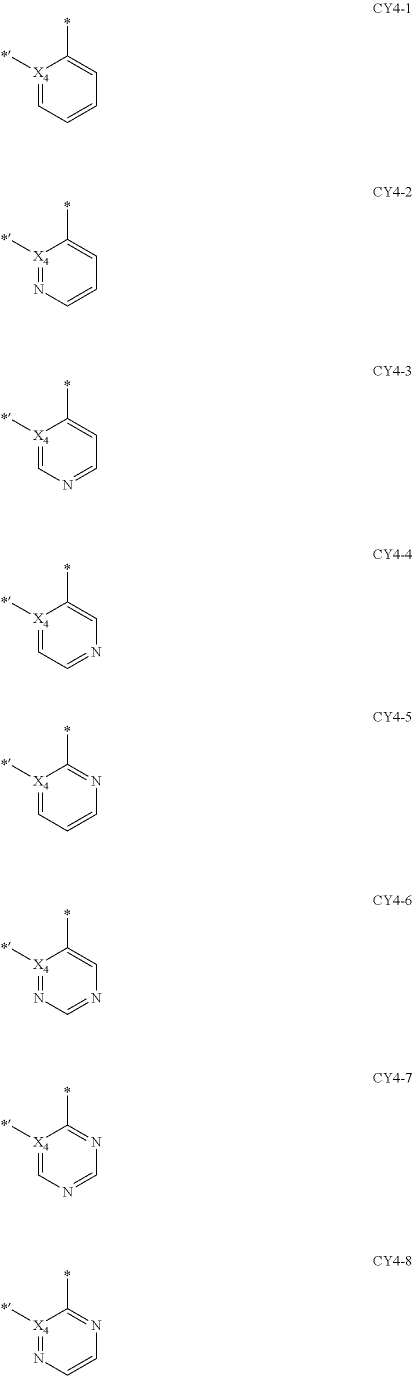 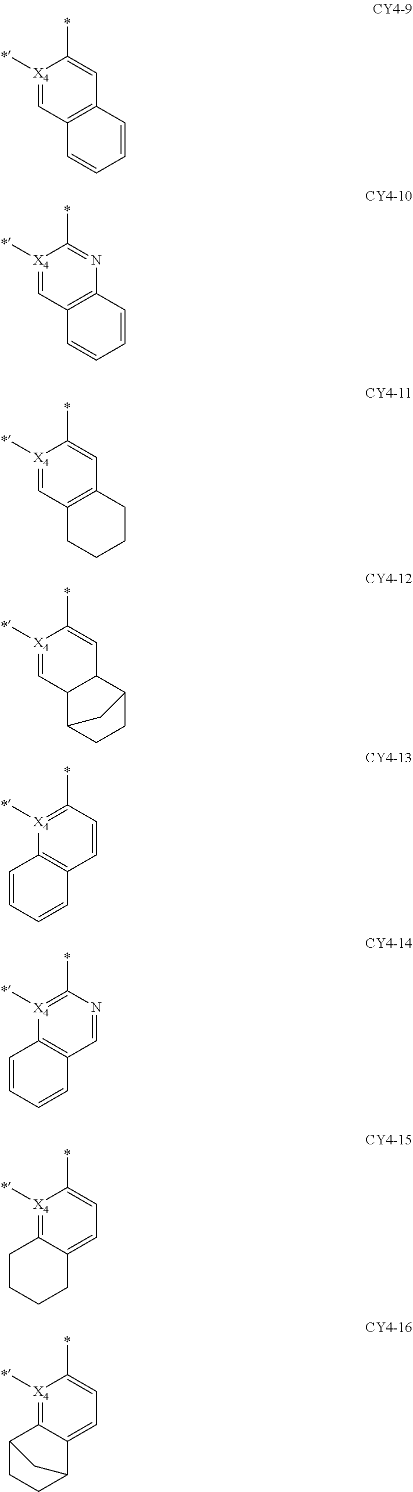 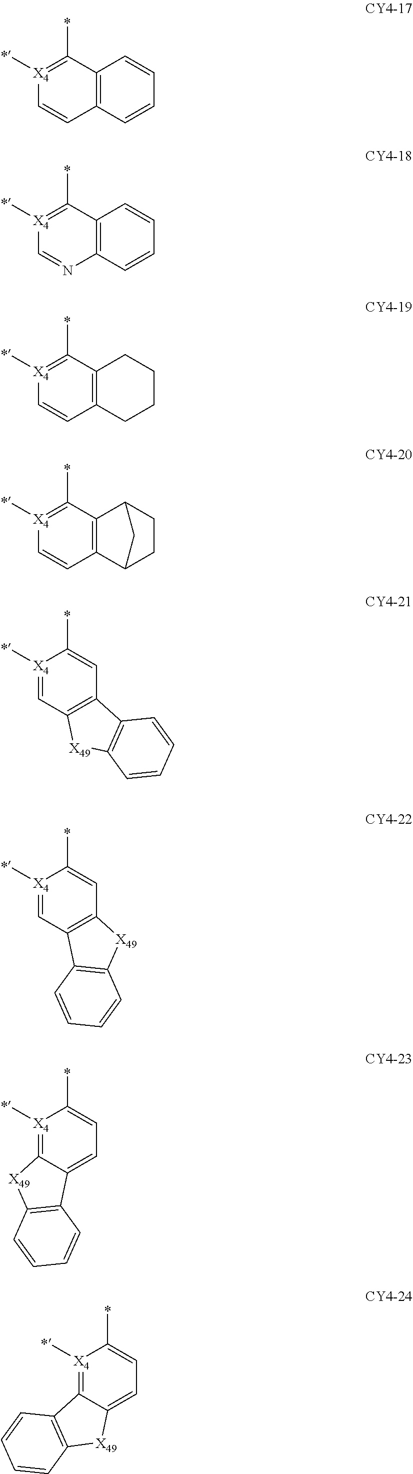 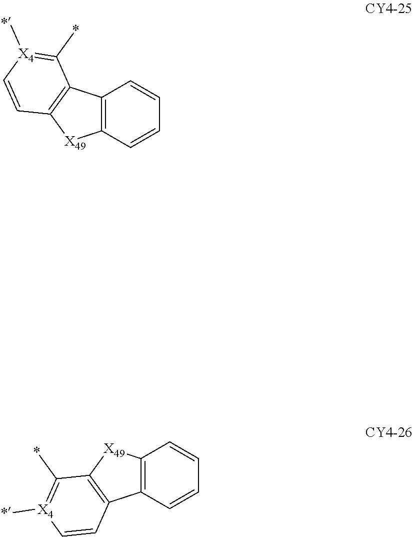
wherein, in Formulae CY4-1 to 4-26,
X₄ is as defined in claim 1,
X₄₉ is C(R₄₉ₐ)(R_{49b}), N[(L₄₉)_{b49}-(R⁴⁹)_{c49}], O, S, or Si(R₄₉ₐ)(R_{49b}),
L₄₉ is as defined in connection with L₄ in claim 1,
b49 and c49 are each as defined in connection with b4 and c4 in claim 1, respectively,
R₄₉, R₄₉ₐ, and R_{49b} are each as defined in connection with R₄ in claim 1,
* indicates a binding site to T₂ in Formula 1, and
*′ indicates a binding site to M in Formula 1.

12. The organometallic compound of claim 1, wherein
the group represented by 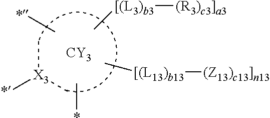
in Formula 1 is a group represented by one of Formulae CY3(1) to CY3(12) or CY3(1)F to CY3(12)F;
the group represented by 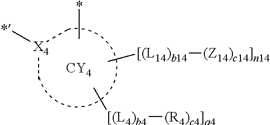
in Formula 1 is a group represented by one of Formulae CY4(1) to CY4(16) or CY4(1)F to CY4(32)F; and
at least one of Condition 3-1 to Condition 4-1 is satisfied:
Condition 3-1
the group represented by 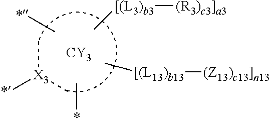
in Formula 1 is a group represented by one of Formulae CY3(1)F to CY3(12)F
Condition 4-1
the group represented by 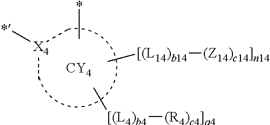
in Formula 1 is a group represented by one of Formulae CY4(1)F to CY4(32)F: 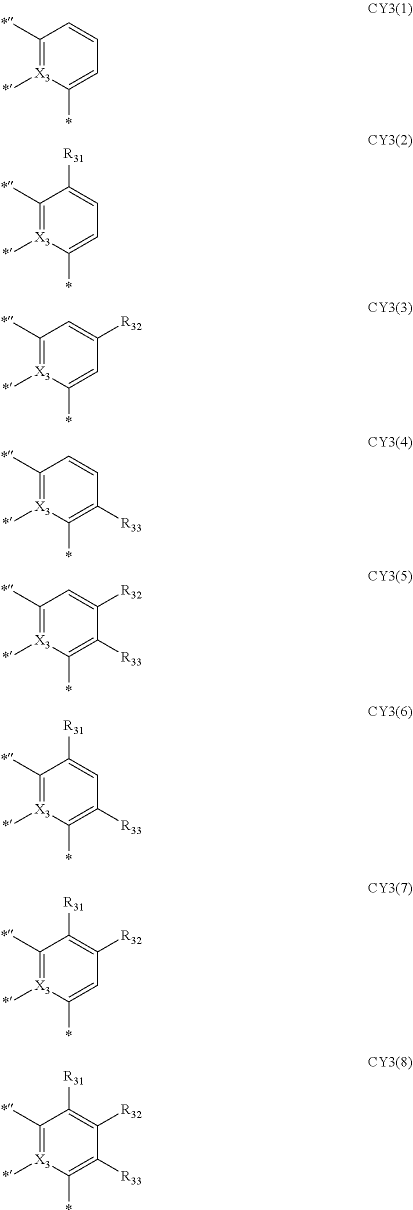 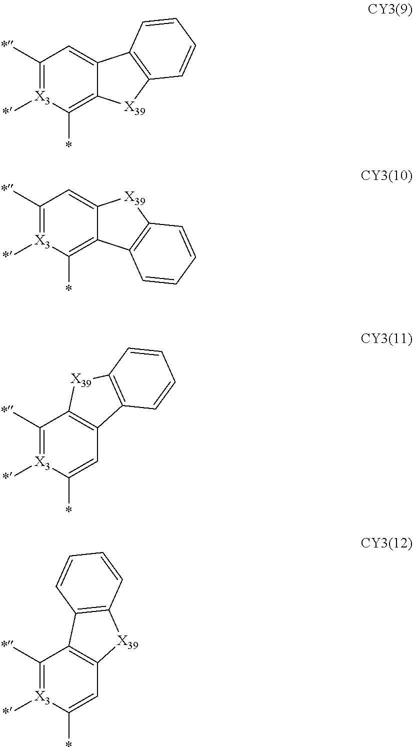 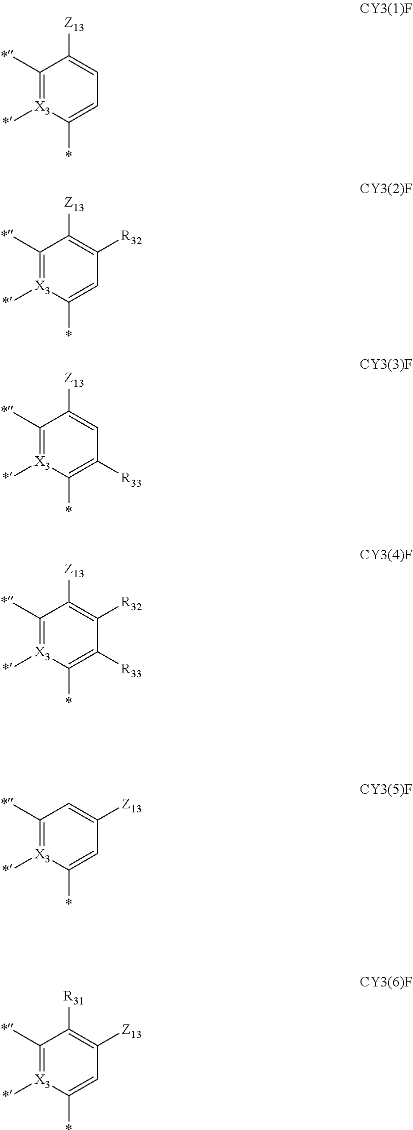 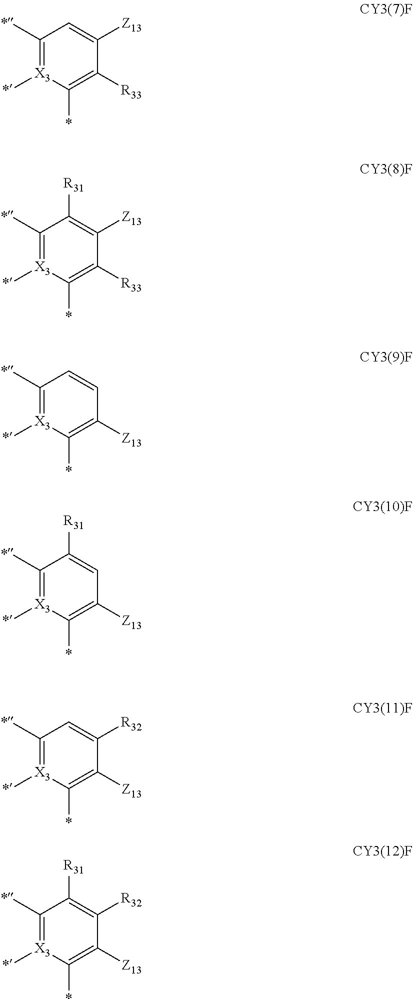
wherein, in Formulae CY3(1) to CY3(12) and CY3(1)F to CY3(12)F,
X₃ and Z₁₃ are each as defined in claim 1,
R₃₁ to R₃₃ are each as defined in connection with R₃ in claim 1, and provided that each of R₃₁ to R₃₃ is not hydrogen,
X₃₉ is C(R₃₉ₐ)(R_{39b}), N[(L₃₉)_{b39}-(R₃₉)_{c39}], O, S, or Si(R₃₉ₐ)(R_{39b}),
L₃₉ is as defined in connection with L₃ in claim 1,
b39 and c39 are each as defined in connection with b3 and c3 in claim 1, respectively,
R₃₉, R₃₉ₐ, and R_{39b} are each as defined in connection with R₃ in claim 1,
* indicates a binding site to T₂ in Formula 1,
*′ indicates a binding site to M in Formula 1, and
*″ indicates a binding site to T₁ in Formula 1, 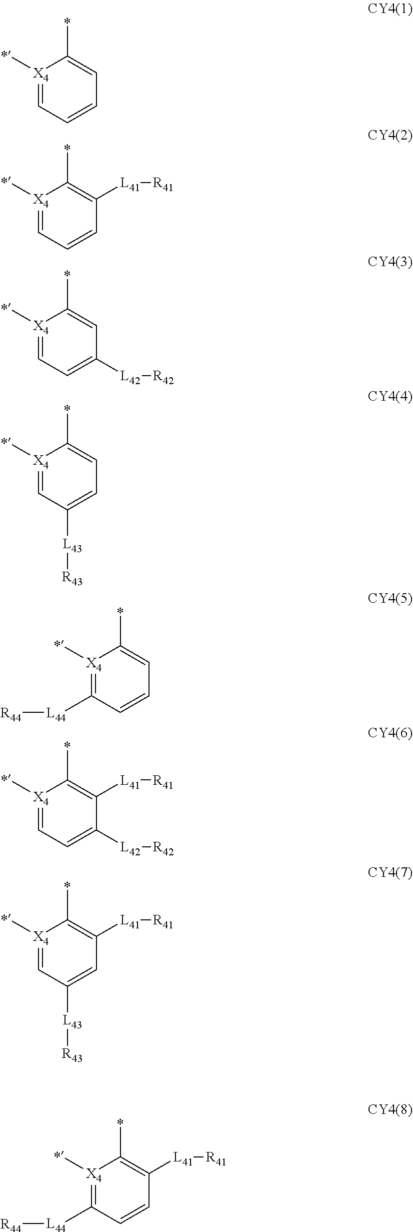 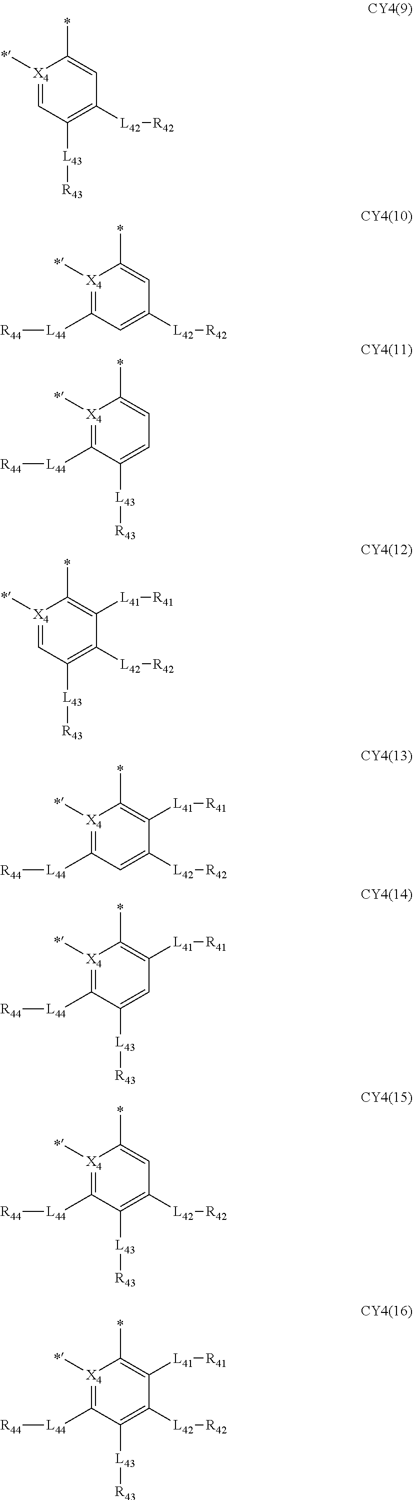 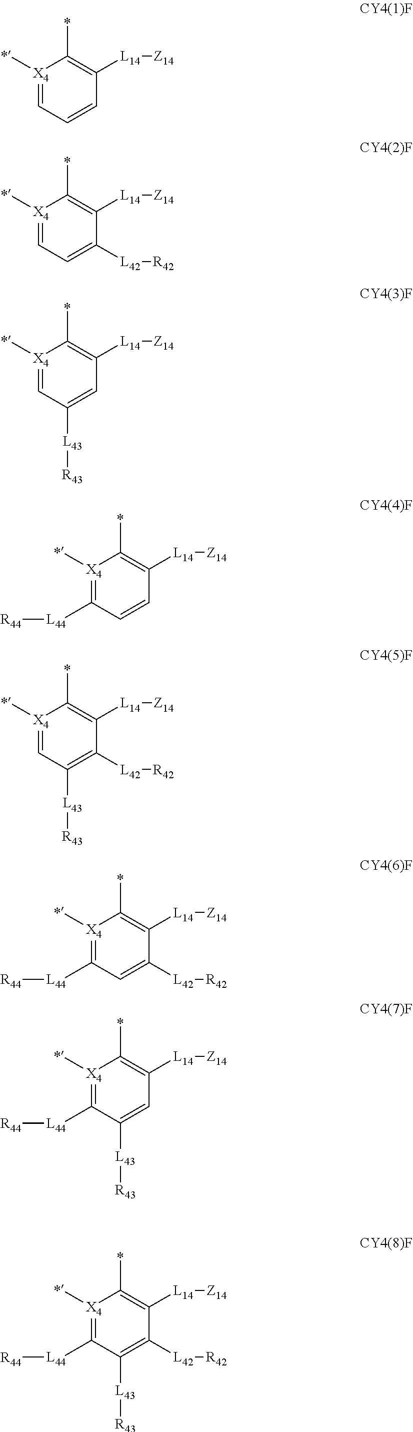 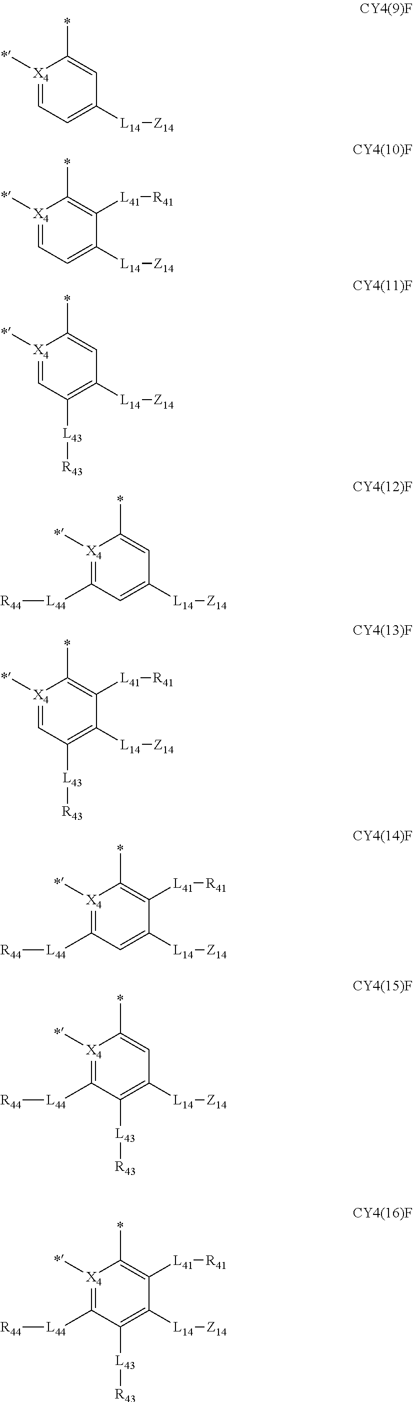 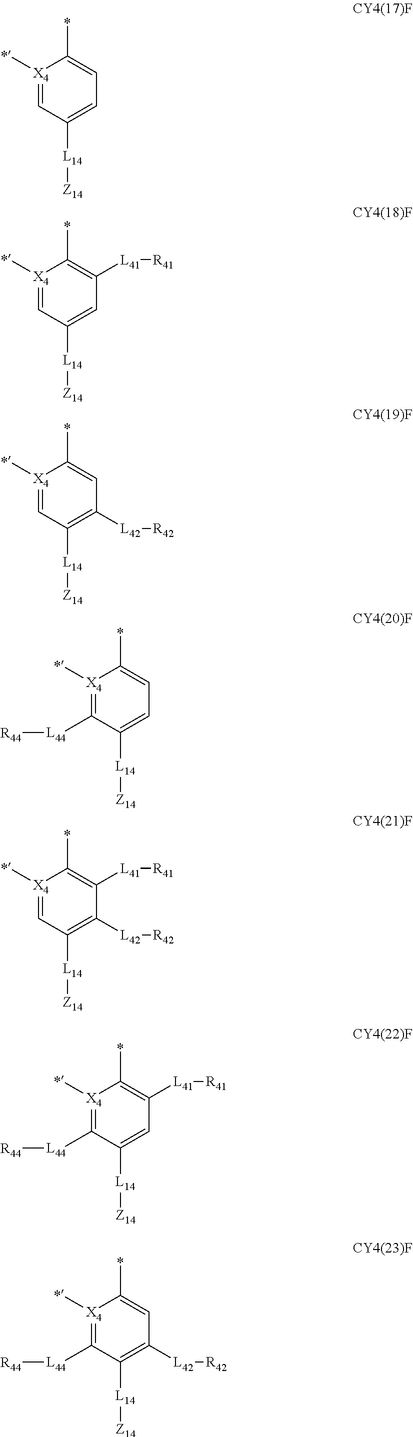 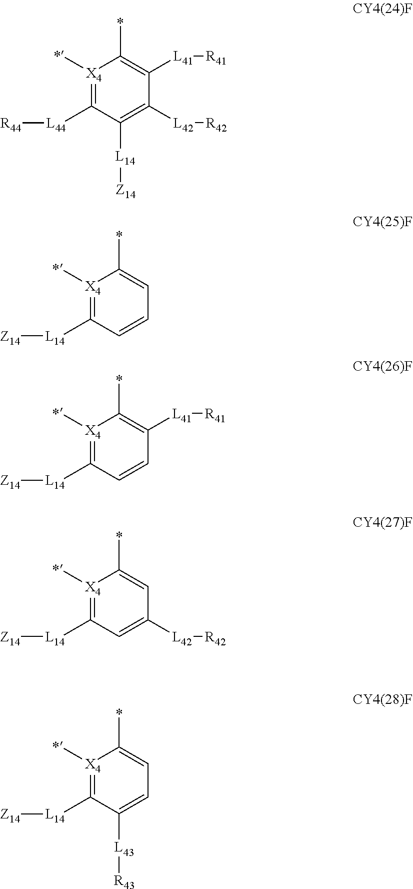 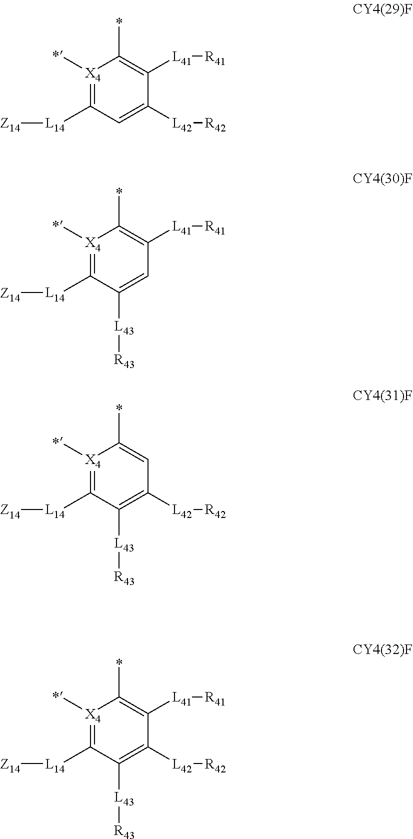
wherein, in Formulae CY4(1) to CY4(16) and CY4(1)F to CY4(32)F,
X₄, L₁₄, and Z₁₄ are each as defined in claim 1,
L₄₁ to L₄₄ are each as defined in connection with L₄ in claim 1,
R₄₁ to R₄₄ are each as defined in connection with R₄ in claim 1, and provided
that each of R₄₁ to R₄₄ is not hydrogen,
* indicates a binding site to T₂ in Formula 1, and
*′ indicates a binding site to M in Formula 1.

13. The organometallic compound of claim 1, wherein the organometallic compound is represented by Formula 1A: 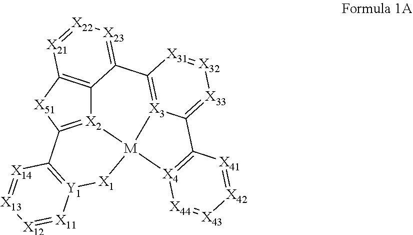
wherein, in Formula 1A,
M, X₁ to X₄, Y₁, and X₅₁ are each as defined in claim 1,
X₁₁ is C(R₁₁) or N; X₁₂ is C(R₁₂) or N; X₁₃ is C(R₁₃) or N; X₁₄ is C(R₁₄) or N; and R¹¹ to R₁₄ are each as defined in connection with R¹ in claim 1,
X₂₁ is C(R₂₁) or N; X₂₂ is C(R₂₂) or N; X₂₃ is C(R₂₃) or N; and R₂₁ to R₂₃ are each as defined in connection with R₂ in claim 1,
X₃₁ is C(R₃₁), C(Z₁₃) or N; X₃₂ is C(R₃₂), C(Z₁₃), or N; X₃₃ is C(R₃₃), C(Z₁₃) or N; R₃₁ to R₃₃ are each the same as described in connection with R₃ in claim 1; and Z₁₃ is as defined in claim 1,
X₄₁ is C-[(L₄₁)-(R₄₁)], C-[(L₁₄)-(Z₁₄)], or N, X₄₂ is C-[(L₄₂)-(R₄₂)], C-[(L₁₄)-(Z₁₄)], or N, X₄₃ is C-[(L₄₃)-(R₄₃)], C-[(L₁₄)-(Z₁₄)], or N, X₄₄ is C-[(L₄₄)-(R₄₄)], C-[(L₁₄)-(Z₁₄)], or N; L₄₁ to L₄₄ are each as defined in connection with L₄ in claim 1; R₄₁ to R₄₄ are each as defined in connection with R₄ in claim 1; L₁₄ and Z₁₄ are each as defined in claim 1,
two or more of R₁₁ to R₁₄ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of R₂₁ to R₂₃ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of R₃₁ to R₃₃ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
two or more of R₄₁ to R₄₄ are optionally linked to form a C₅-C₃₀ carbocyclic group unsubstituted or substituted with at least one R₁₀ₐ, or a C₁-C₃₀ heterocyclic group unsubstituted or substituted with at least one R₁₀ₐ,
R₁₀ₐ is as defined in connection with R₁ in claim 1, and
at least one of Condition (1) to Condition (7) is satisfied:
Condition (1)
X₃₁ is C(Z₁₃)
Condition (2)
X₃₂ is C(Z₁₃)
Condition (3)
X₃₃ is C(Z₁₃)
Condition (4)
X₄₁ is C-[(L₁₄)-(Z₁₄)]
Condition (5)
X₄₂ is C-[(L₁₄)-(Z₁₄)]
Condition (6)
X₄₃ is C-[(L₁₄)-(Z₁₄)]
Condition (7)
X₄₄ is C-[(L₁₄)-(Z₁₄)]

14. The organometallic compound of claim 13, wherein the organometallic compound satisfies at least one of Condition (1) to Condition (3).

15. The organometallic compound of claim 13, wherein the organometallic compound satisfies at least one of Condition (4) to Condition (7).

16. An organic light-emitting device, comprising:
a first electrode;
a second electrode; and
an organic layer located between the first electrode and the second electrode;
wherein the organic layer comprises an emission layer, and
wherein the organic layer comprises at least one of the organometallic compound of claim 1.

17. The organic light-emitting device of claim 16, wherein
the first electrode is an anode,
the second electrode is a cathode,
the organic layer further comprises a hole transport region located between the first electrode and the emission layer and an electron transport region located between the emission layer and the second electrode,
the hole transport region comprises a hole injection layer, a hole transport layer, an electron blocking layer, a buffer layer, or a combination thereof, and
the electron transport region comprises a hole blocking layer, an electron transport layer, an electron injection layer, or a combination thereof.

18. The organic light-emitting device of claim 16, wherein the emission layer comprises the at least one organometallic compound.

19. The organic light-emitting device of claim 18, wherein
the emission layer further comprises a host, and
an amount of the host in the emission layer is greater than an amount of the at least one organometallic compound in the emission layer.

20. An electronic apparatus, comprising the organic light-emitting device of claim 16.
